(19) United States
(12) Patent Application Publication
(10) Pub. No.: US 2015/0179949 A1
(43) Pub. Date: Jun. 25, 2015

(54) MATERIAL FOR ORGANIC ELECTROLUMINESCENCE DEVICE AND ORGANIC ELECTROLUMINESCENCE DEVICE USING THE SAME

(71) Applicant: SAMSUNG DISPLAY CO., LTD., Yongin-City (KR)

(72) Inventor: Yasuo MIYATA, Yokohama (JP)

(21) Appl. No.: 14/577,592

(22) Filed: Dec. 19, 2014

(30) Foreign Application Priority Data
Dec. 20, 2013 (JP) 2013-264637

(51) Int. Cl. H01L 51/00; H01L 51/50

(52) U.S. Cl. CPC H01L 51/0054; H01L 51/0072; H01L 51/0052; H01L 51/0055; H01L 51/0073; H01L 51/0074; H01L 51/0094; H01L 51/5012; H01L 51/5056

(57) ABSTRACT

A material for an organic electroluminescence (EL) device includes a compound represented by the following Formula 1:

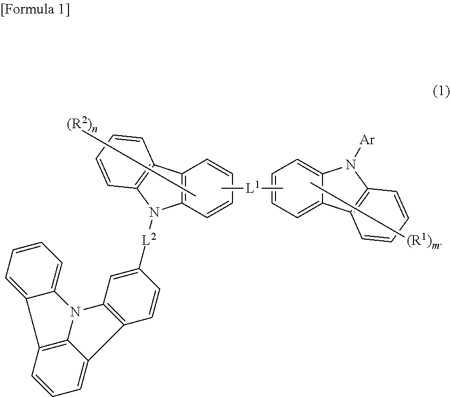

### CROSS-REFERENCE TO RELATED APPLICATION

Japanese Patent Application No. 2013-264637, filed on Dec. 20, 2013, in the Japanese Patent Office, and entitled: “Material for Organic Electroluminescence Device and Organic Electroluminescence Device Using the Same,” is incorporated by reference herein in its entirety.

### BACKGROUND

1. Field

Embodiments relate to a material for an organic electroluminescence device and an organic electroluminescence device using the same.

2. Description of the Related Art

Organic electroluminescence (EL) displays are one type of image displays that have been actively developed. Unlike a liquid crystal display and the like, the organic EL display is so-called a self-luminescent display that recombines holes and electrons injected from an anode and a cathode in an emission layer to thus emit light from a light-emitting material that include an organic compound of the emission layer, thereby performing display.

### SUMMARY

Embodiments are directed to a material for an organic electroluminescence (EL) device, the material including a compound represented by the following Formula 1:

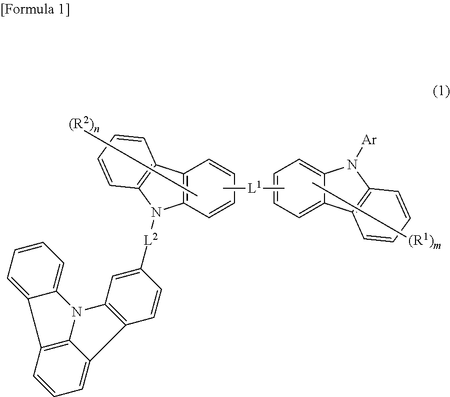

In Formula 1, Ar may be a substituted or unsubstituted alkyl group, a substituted or unsubstituted aryl group, or a substituted or unsubstituted heteroaryl group, L¹ and L² may independently be a single bond, a substituted or unsubstituted arylene group, or a substituted or unsubstituted heteroarylene group, R¹ and R² may independently be hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and m and n may independently be an integer from 1 to 7.

Ar may be a substituted or unsubstituted aryl group having 6 to 24 ring carbon atoms.

Ar may be a substituted or unsubstituted carbazolyl group, a substituted or unsubstituted dibenzofuryl group, or a substituted or unsubstituted dibenzothienyl group.

L¹ and L² may independently be a single bond, or a substituted or unsubstituted arylene group having 6 to 18 ring carbon atoms.

R¹ and R² may independently be hydrogen, or a substituted or unsubstituted aryl group.

Embodiments are also directed to an organic electroluminescence (EL) device. The device may include a material that includes a compound represented by Formula 1.

The material may be a hole transport material.

The hole transport material may be in a layer disposed between an emission layer and an anode.

The material may be a host material.

The host material may be in an emission layer.

### BRIEF DESCRIPTION OF THE DRAWINGS

Features will become apparent to those of skill in the art by describing in detail example embodiments with reference to the attached drawings in which:

FIG. 1 illustrates a schematic diagram of an organic EL device 100 according to an example embodiment; and

FIG. 2 illustrates a schematic diagram of an organic EL device 200 according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary embodiments to those skilled in the art.

In the drawing figures, the dimensions of layers and regions may be exaggerated for clarity of illustration. Like reference numerals refer to like elements throughout.

According to an example embodiment, a material for an organic EL device includes a compound having carbazole moieties and an indolocarbazolyl moiety. According to the present example embodiment, the compound is represented by the following Formula 1.

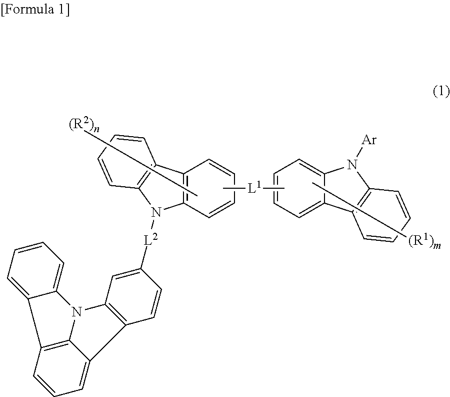

According to the present example embodiment, in Formula 1, Ar is a substituted or unsubstituted alkyl group, a substituted or unsubstituted aryl group, or a substituted or unsubstituted heteroaryl group.

As Ar, the alkyl group may be, for example, a substituted or unsubstituted alkyl group having 1 to 30 carbon atoms and may particularly include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldocecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, 2-butylhexadecyl group, a 2-hexylhexadecyl group, a 2-octylhexadecyl group, an n-heptadecyl group, an n-octadecyl group, an n-nanodecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc.

In addition, the aryl group as Ar may be, for example, a substituted or unsubstituted aryl group having 6 to 24 ring carbon atoms, and particularly, may be a phenyl group, a naphthyl group, an anthracenyl group, a phenanthryl group, a biphenyl group, a terphenyl group, a quaterphenyl group, a fluorenyl group, a triphenylene group, a biphenylene group, a pyrenyl group, a benzofluoranthenyl group, a chrysenyl group, etc.

In addition, the heteroaryl group as Ar may be, for example, a substituted or unsubstituted heteroaryl group having 4 to 30 carbon atoms (5 to 35 ring carbon atoms), and particularly, may be a benzothiazolyl group, a thiophenyl group, a thienothiophenyl group, a thienothienothiophenyl group, a benzothiophenyl group, a benzofuryl group, a dibenzothiophenyl group, a dibenzofuryl group, an N-arylcarbazolyl group, an N-heteroarylcarbazolyl group, an N-alkylcarbazolyl group, a phenoxazyl group, a phenothiazyl group, a pyridyl group, a pyrimidyl group, a triazile group, a quinolinyl group, a quinoxalyl group, etc.

According to the present example embodiment, in Formula 1, L¹ and L² are independently a single bond, a substituted or unsubstituted arylene group, or a substituted or unsubstituted heteroarylene group. In the case that L² is a substituted or unsubstituted arylene group or a substituted or unsubstituted heteroarylene group, the electron tolerance of the material for an organic EL device according to an embodiment may be improved. Thus, L² may be the substituted or unsubstituted arylene group, or the substituted or unsubstituted heteroarylene group.

The arylene group as L¹ and L² may be, for example, a substituted or unsubstituted arylene group having 6 to 18 ring carbon atoms. For example, L¹ and L² may independently be a phenylene group, a naphthylene group, an anthracene group, a phenanthrylene group, a biphenylene group, a terphenylene group, a fluorenylene group, a triphenylene group, a biphenylene group, a pyrenylene group, a chrysenylene group, etc.

The heteroarylene group as L¹ and L² may be, for example, a substituted or unsubstituted heteroarylene group having 4 to 20 carbon atoms, or 5 to 25 ring carbon atoms. For example, L¹ and L² may independently be a benzothiazolylene group, a thiophenylene group, a thienothiophenylene group, a thienothienothiophenylene group, a benzothiophenylene group, a benzofurylene group, a dibenzothiophenylene group, a dibenzofurylene group, an N-carbazolylene group, an N-heteroarylcarbazolylene group, an N-alkylcarbazolylene group, a phenoxazylene group, a phenothiazylene group, a pyridylene group, a pyrimidylene group, a triazilene group, a quinolinylene group, a quinoxalylene group, etc.

According to the present example embodiment, in Formula 1, R¹ and R² are independently (each of R¹ may be the same or different; each of R² may be the same or different) hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group.

The alkyl group as R¹ and R² may be, for example, a substituted or unsubstituted alkyl group having 1 to 30 carbon atoms. For example, the alkyl group as R¹ and R² may be a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldocecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, 2-butylhexadecyl group, a 2-hexylhexadecyl group, a 2-octylhexadecyl group, an n-heptadecyl group, an n-octadecyl group, an n-nanodecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc.

The alkoxy group as R¹ and R² may be, for example, a substituted or unsubstituted alkoxy group having 1 to 30 carbon atoms. For example, the alkoxy group as R¹ and R² may be a methoxy group, an ethoxy group, an n-propoxy group, an i-propoxy group, an n-butoxy group, an s-butoxy group, a t-butoxy group, an i-butoxy group, a 2-ethylbutoxy group, a 3,3-dimethylbutoxy group, an n-pentyloxy group, an i-pentyloxy group, a neopentyloxy group, a t-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a cyclohexyloxy group, a 4-methylcyclohexyloxy group, a 4-t-butylcyclohexyloxy group, an n-heptyloxy group, a 1-methylheptyloxy group, a 2,2-dimethylheptyloxy group, a 2-ethylheptyloxy group, 2-butylheptyloxy group, an n-octyloxy group, a t-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, an adamantyloxy group, a 2-ethyldecyloxy group, a 2-butyldecyloxy group, a 2-hexyldecyloxy group, a 2-octyldecyloxy group, an n-undecyloxy group, an n-dodecyloxy group, a 2-ethyldodecyloxy group, a 2-butyldodecyloxy group, a 2-hexyldodecyloxy group, a 2-octyldodecyloxy group, an n-tridecyloxy group, an n-tetradecyloxy group, an n-pentadecyloxy group, an n-hexadecyloxy group, a 2-ethylhexadecyloxy group, a 2-butylhexadecyloxy group, a 2-hexylhexadecyloxy group, a 2-octylhexadecyloxy group, an n-heptadecyloxy group, an n-octadecyloxy group, an n-nonadecyloxy group, an n-icosyloxy group, a 2-ethylicosyloxy group, a 2-butylicosyloxy group, a 2-hexylicosyloxy group, a 2-octylicosyloxy group, an n-henicosyloxy group, an n-docosyloxy group, an n-tricosyloxy group, an n-tetracosyloxy group, an n-pentacosyloxy group, an n-hexacosyloxy group, an n-heptacosyloxy group, an n-octacosyloxy group, an n-nonacosyloxy group, an n-triacontyloxy group, etc.

The aryl group as R¹ and R² may be, for example, a substituted or unsubstituted aryl group having 6 to 24 ring carbon atoms. For example, the aryl group as R¹ and R² may be a phenyl group, a naphthyl group, an anthracenyl group, a phenanthryl group, a biphenyl group, a terphenyl group, a quaterphenyl group, a fluorenyl group, a triphenylene group, a biphenylene group, a pyrenyl group, a benzofluoranthenyl group, a chrysenyl group, etc.

The heteroaryl group as R¹ and R² may be, for example, a substituted or unsubstituted heteroaryl group having 4 to 30 carbon atoms, or 5 to 35 ring carbon atoms. For example, the heteroaryl group as R¹ and R² may be a benzothiazolyl group, a thiophenyl group, a thienothiophenyl group, a thienothienothiophenyl group, a benzothiophenyl group, a benzofuryl group, a dibenzothiophenyl group, a dibenzofuryl group, an N-carbazolyl group, an N-heteroarylcarbazolyl group, an N-alkylcarbazolyl group, a phenoxazyl group, a phenothiazyl group, a pyridyl group, a pyrimidyl group, a triazile group, a quinolinyl group, a quinoxalyl group, etc.

The material for an organic EL device according to an embodiment may include compounds having the following structures.

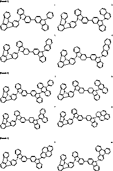

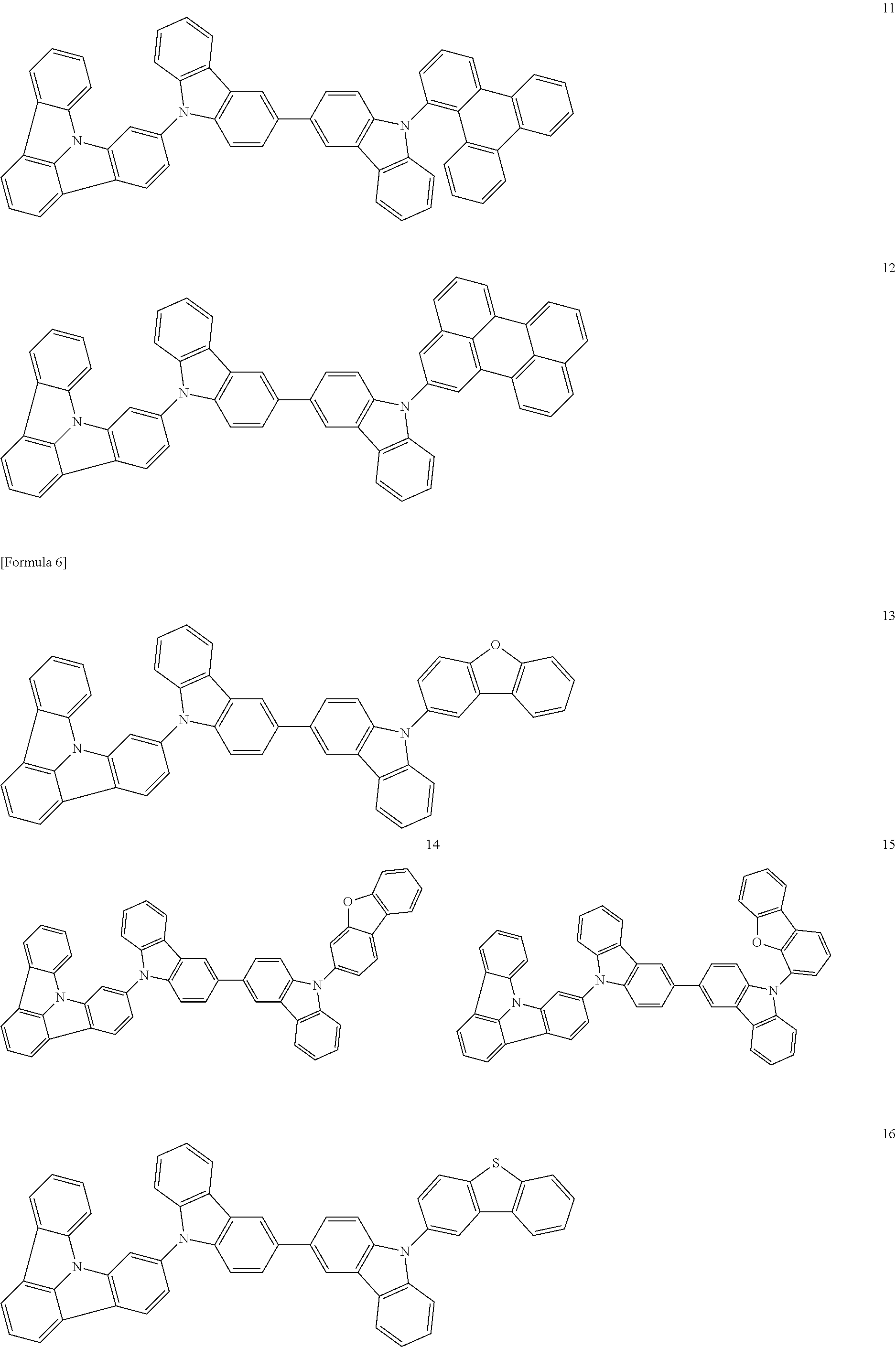

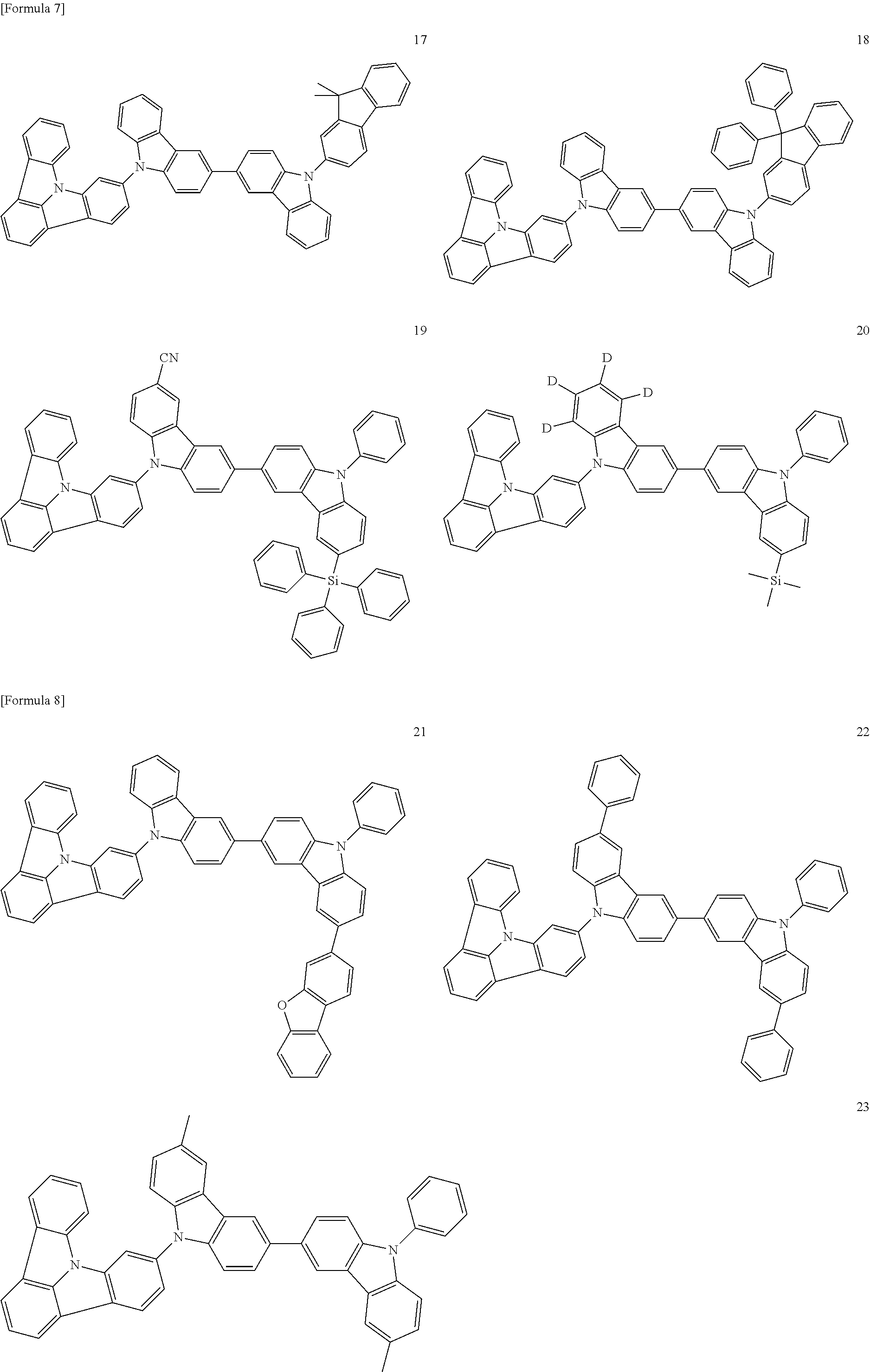

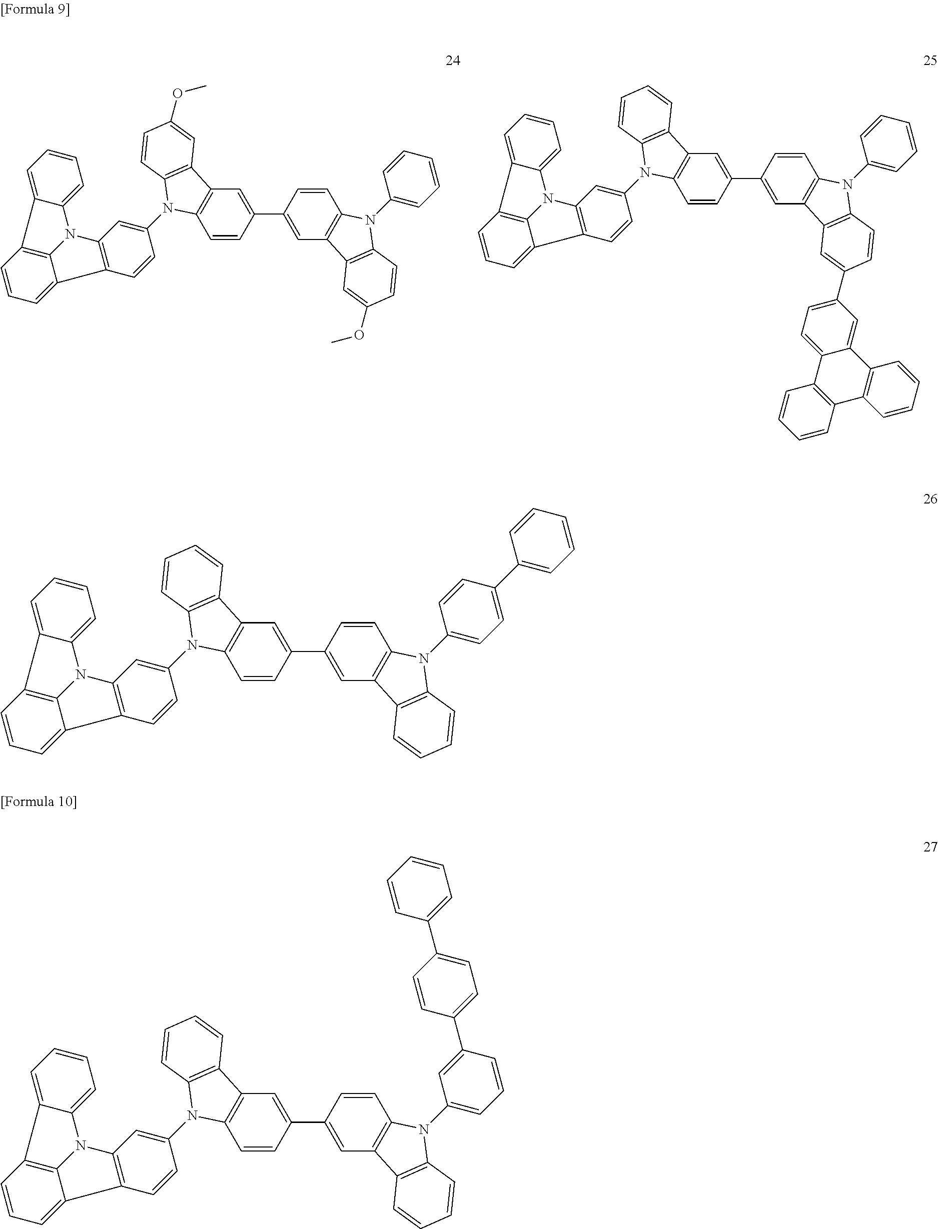 [SMILES: COc1ccc2c(c1)c1cc(-c3ccc4c(c3)c3cc(OC)ccc3n4-c3ccc4c5cccc6c7ccccc7n(c4c3)c65)ccc1n2-c1ccccc1 ; c1ccc(-n2c3ccc(-c4ccc5c6ccccc6c6ccccc6c5c4)cc3c3cc(-c4ccc5c(c4)c4ccccc4n5-c4ccc5c6cccc7c8ccccc8n(c5c4)c76)ccc32)cc1 ; c1ccc(-c2ccc(-n3c4ccccc4c4cc(-c5ccc6c(c5)c5ccccc5n6-c5ccc6c7cccc8c9ccccc9n(c6c5)c87)ccc43)cc2)cc1 ; c1ccc(-c2ccc(-c3cccc(-n4c5ccccc5c5cc(-c6ccc7c(c6)c6ccccc6n7-c6ccc7c8cccc9c%10ccccc%10n(c7c6)c98)ccc54)c3)cc2)cc1]

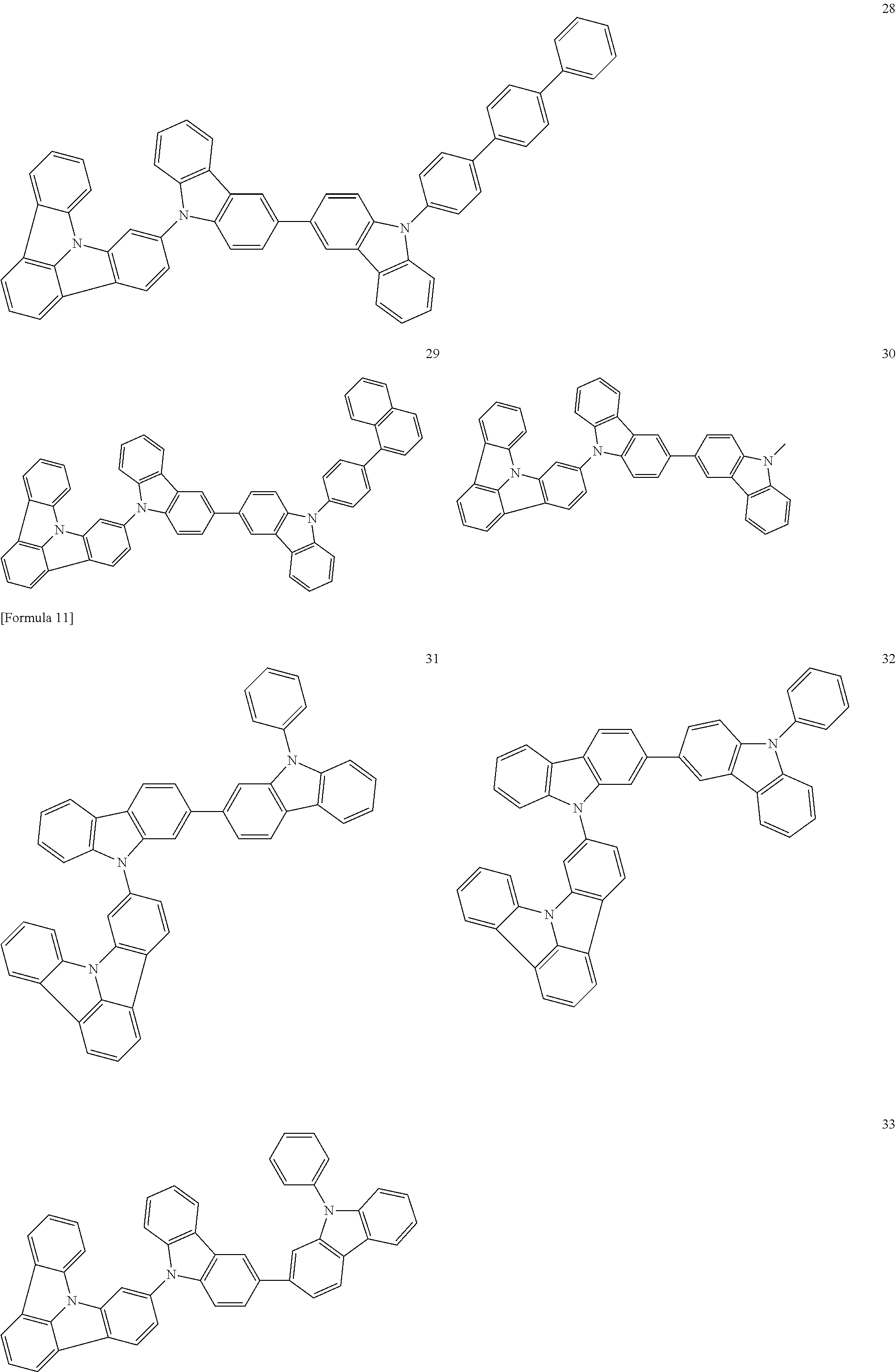

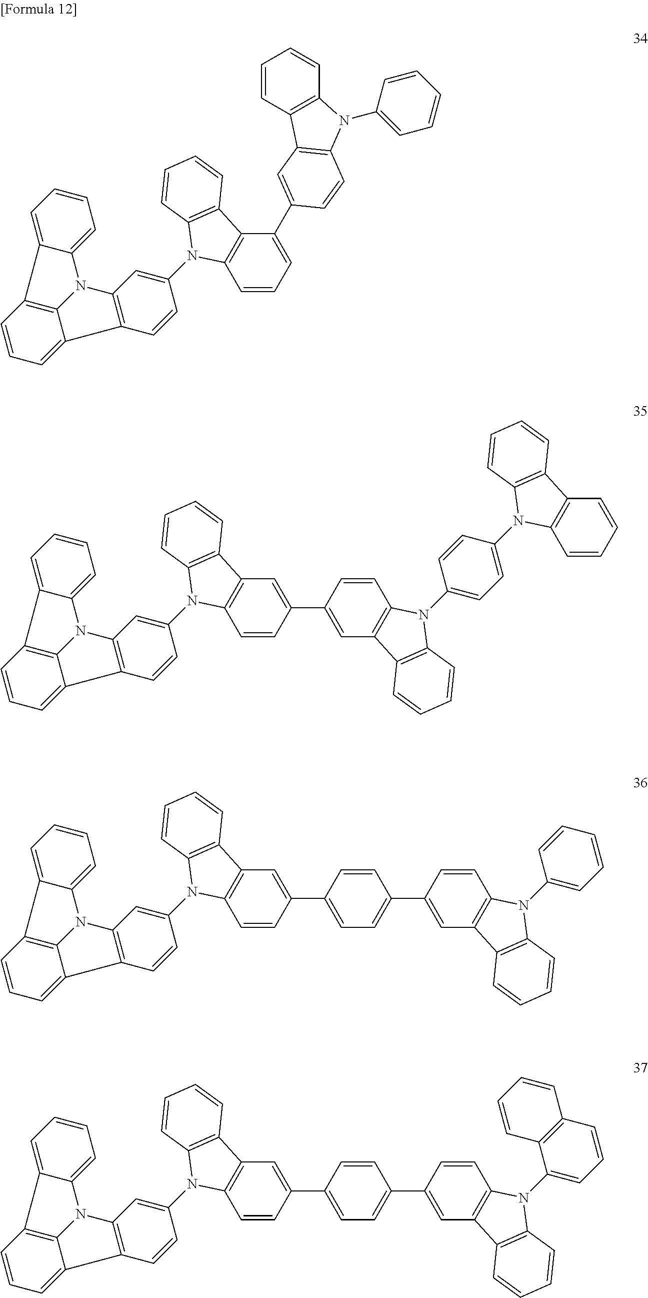 [SMILES: c1ccc(-n2c3ccccc3c3cc(-c4cccc5c4c4ccccc4n5-c4ccc5c6cccc7c8ccccc8n(c5c4)c76)ccc32)cc1 ; c1ccc2c(c1)c1ccccc1n2-c1ccc(-n2c3ccccc3c3cc(-c4ccc5c(c4)c4ccccc4n5-c4ccc5c6cccc7c8ccccc8n(c5c4)c76)ccc32)cc1 ; c1ccc(-n2c3ccccc3c3cc(-c4ccc(-c5ccc6c(c5)c5ccccc5n6-c5ccc6c7cccc8c9ccccc9n(c6c5)c87)cc4)ccc32)cc1 ; c1ccc2c(-n3c4ccccc4c4cc(-c5ccc(-c6ccc7c(c6)c6ccccc6n7-c6ccc7c8cccc9c%10ccccc%10n(c7c6)c98)cc5)ccc43)cccc2c1]

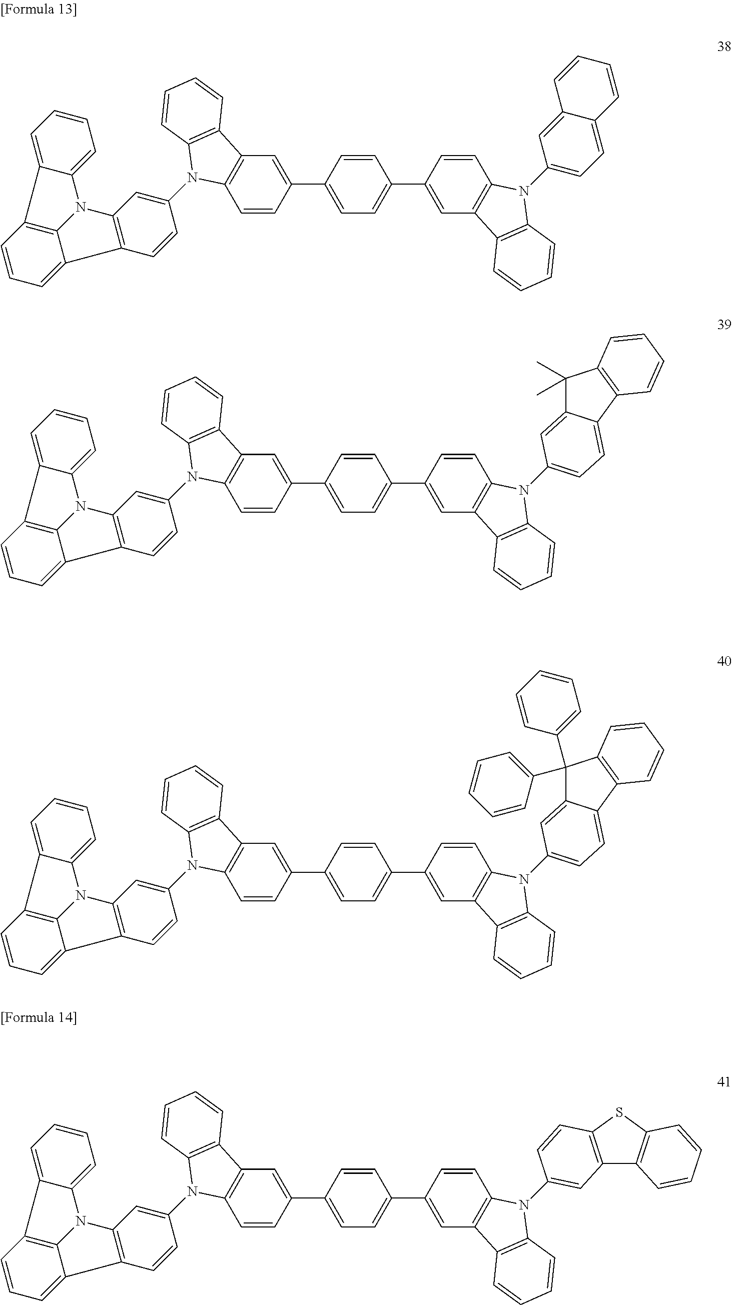 [SMILES: c1ccc2cc(-n3c4ccccc4c4cc(-c5ccc(-c6ccc7c(c6)c6ccccc6n7-c6ccc7c8cccc9c%10ccccc%10n(c7c6)c98)cc5)ccc43)ccc2c1 ; CC1(C)c2ccccc2-c2ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc21 ; c1ccc(C2(c3ccccc3)c3ccccc3-c3ccc(-n4c5ccccc5c5cc(-c6ccc(-c7ccc8c(c7)c7ccccc7n8-c7ccc8c9cccc%10c%11ccccc%11n(c8c7)c%109)cc6)ccc54)cc32)cc1 ; c1ccc2c(c1)sc1ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc12]

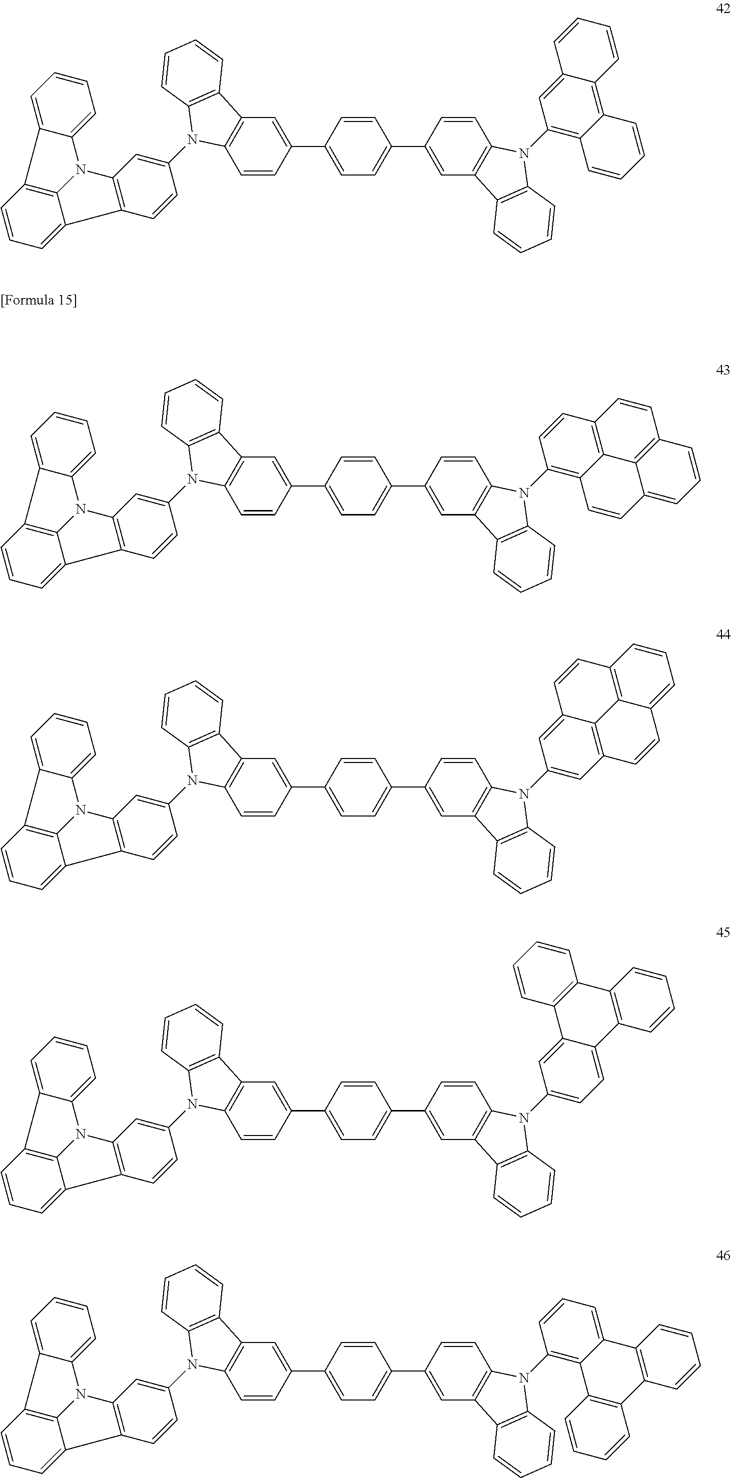

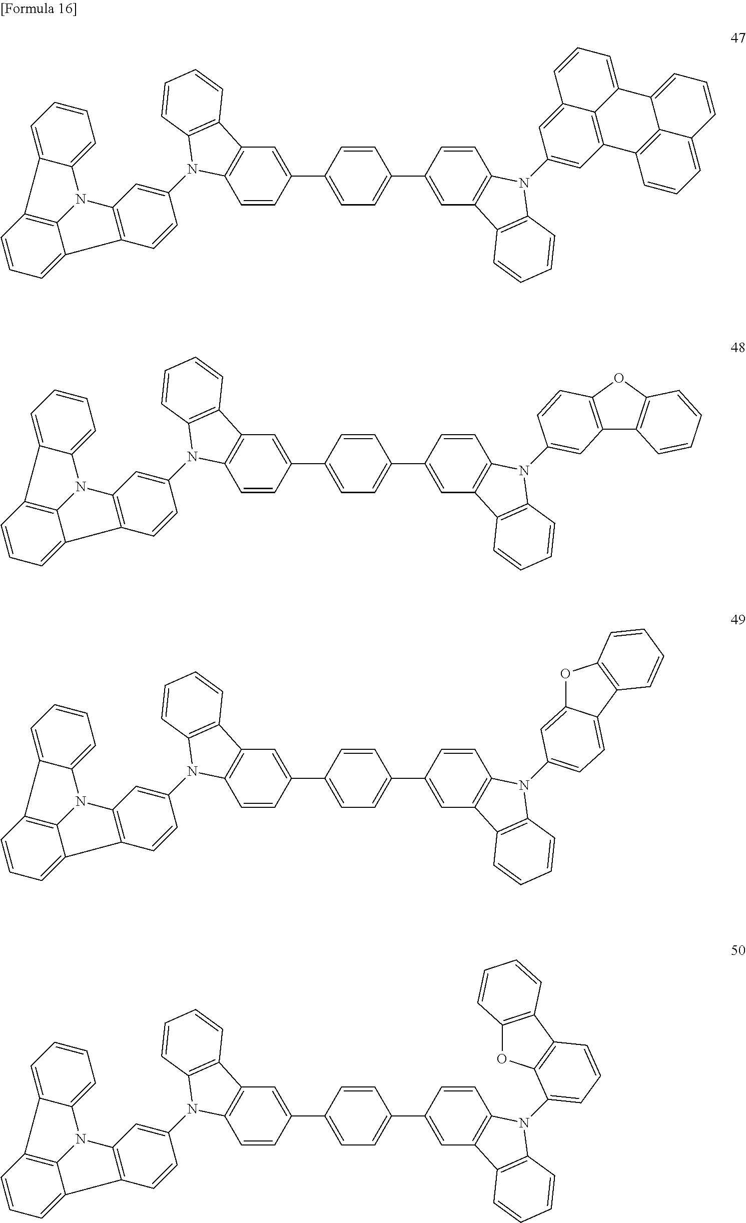 [SMILES: c1cc2cccc3c4cc(-n5c6ccccc6c6cc(-c7ccc(-c8ccc9c(c8)c8ccccc8n9-c8ccc9c%10cccc%11c%12ccccc%12n(c9c8)c%11%10)cc7)ccc65)cc5cccc(c(c1)c23)c54 ; c1ccc2c(c1)oc1ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc12 ; c1ccc2c(c1)oc1cc(-n3c4ccccc4c4cc(-c5ccc(-c6ccc7c(c6)c6ccccc6n7-c6ccc7c8cccc9c%10ccccc%10n(c7c6)c98)cc5)ccc43)ccc12 ; c1ccc2c(c1)oc1c(-n3c4ccccc4c4cc(-c5ccc(-c6ccc7c(c6)c6ccccc6n7-c6ccc7c8cccc9c%10ccccc%10n(c7c6)c98)cc5)ccc43)cccc12]

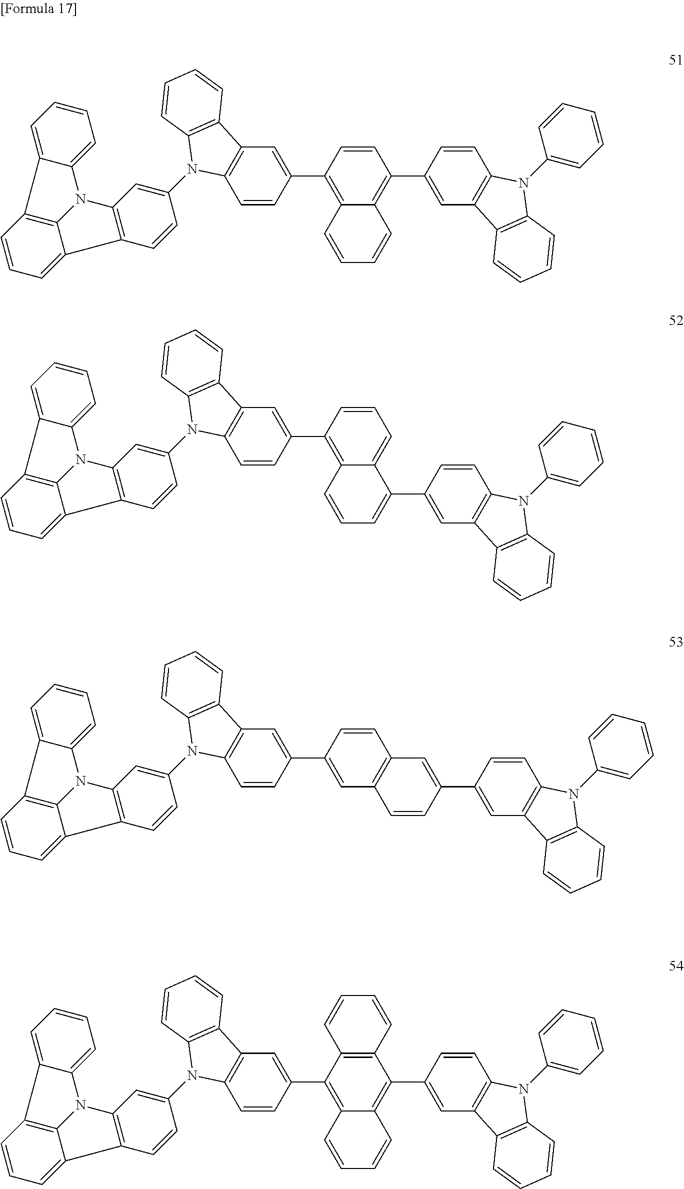 [SMILES: c1ccc(-n2c3ccccc3c3cc(-c4ccc(-c5ccc6c(c5)c5ccccc5n6-c5ccc6c7cccc8c9ccccc9n(c6c5)c87)c5ccccc45)ccc32)cc1 ; c1ccc(-n2c3ccccc3c3cc(-c4cccc5c(-c6ccc7c(c6)c6ccccc6n7-c6ccc7c8cccc9c%10ccccc%10n(c7c6)c98)cccc45)ccc32)cc1 ; c1ccc(-n2c3ccccc3c3cc(-c4ccc5cc(-c6ccc7c(c6)c6ccccc6n7-c6ccc7c8cccc9c%10ccccc%10n(c7c6)c98)ccc5c4)ccc32)cc1 ; c1ccc(-n2c3ccccc3c3cc(-c4c5ccccc5c(-c5ccc6c(c5)c5ccccc5n6-c5ccc6c7cccc8c9ccccc9n(c6c5)c87)c5ccccc45)ccc32)cc1]

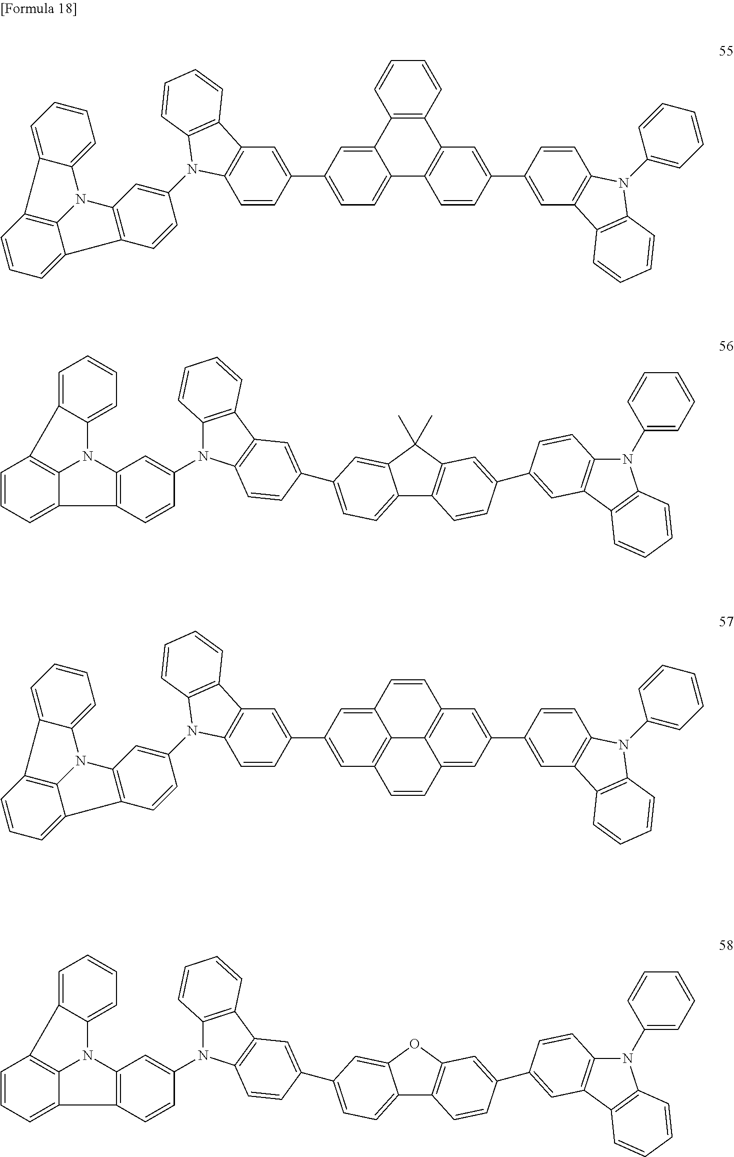 [SMILES: c1ccc(-n2c3ccccc3c3cc(-c4ccc5c6ccc(-c7ccc8c(c7)c7ccccc7n8-c7ccc8c9cccc%10c%11ccccc%11n(c8c7)c%109)cc6c6ccccc6c5c4)ccc32)cc1 ; CC1(C)c2cc(-c3ccc4c(c3)c3ccccc3n4-c3ccccc3)ccc2-c2ccc(-c3ccc4c(c3)c3ccccc3n4-c3ccc4c5cccc6c7ccccc7n(c4c3)c65)cc21 ; c1ccc(-n2c3ccccc3c3cc(-c4cc5ccc6cc(-c7ccc8c(c7)c7ccccc7n8-c7ccc8c9cccc%10c%11ccccc%11n(c8c7)c%109)cc7ccc(c4)c5c67)ccc32)cc1 ; c1ccc(-n2c3ccccc3c3cc(-c4ccc5c(c4)oc4cc(-c6ccc7c(c6)c6ccccc6n7-c6ccc7c8cccc9c%10ccccc%10n(c7c6)c98)ccc45)ccc32)cc1]

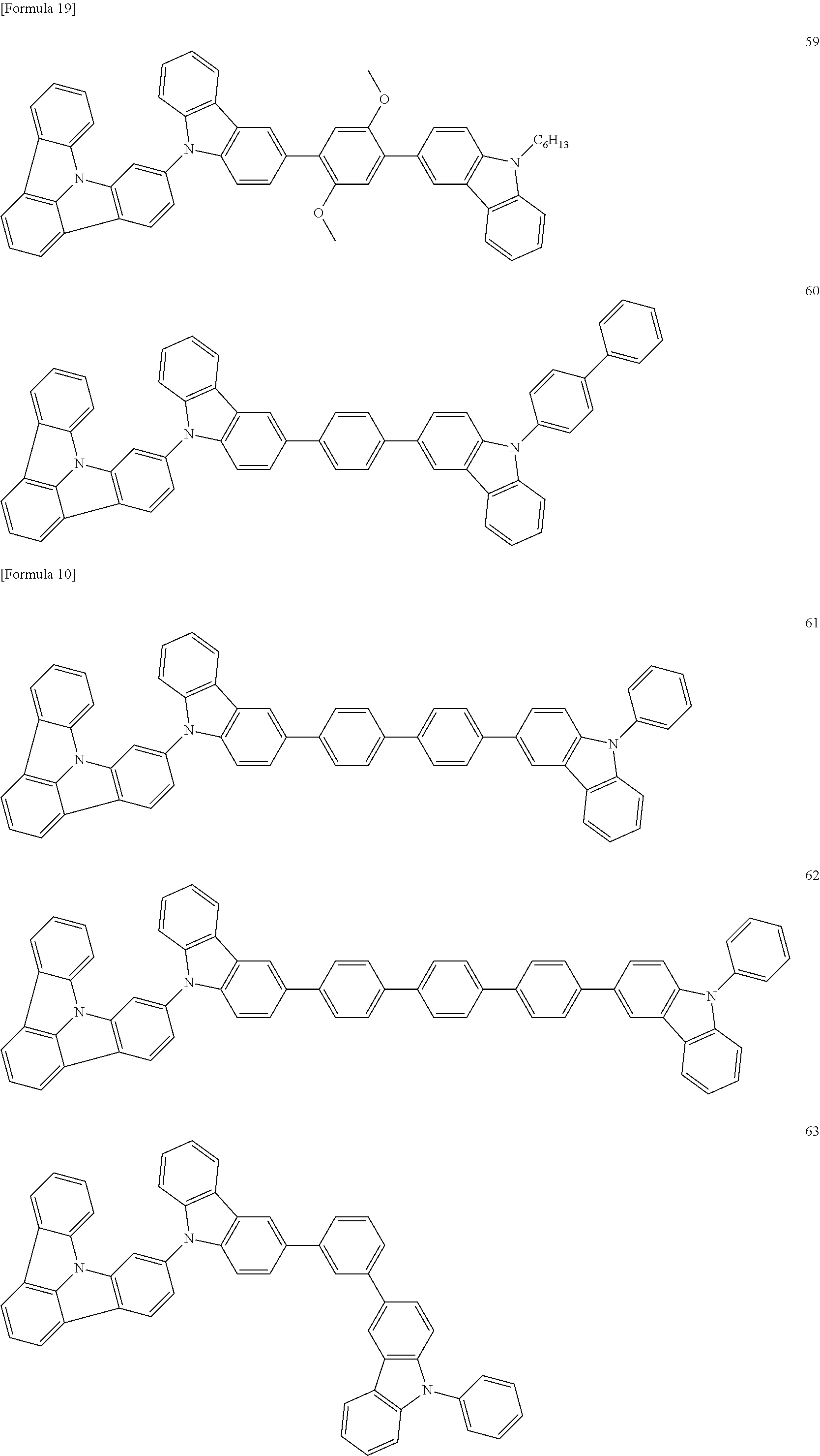

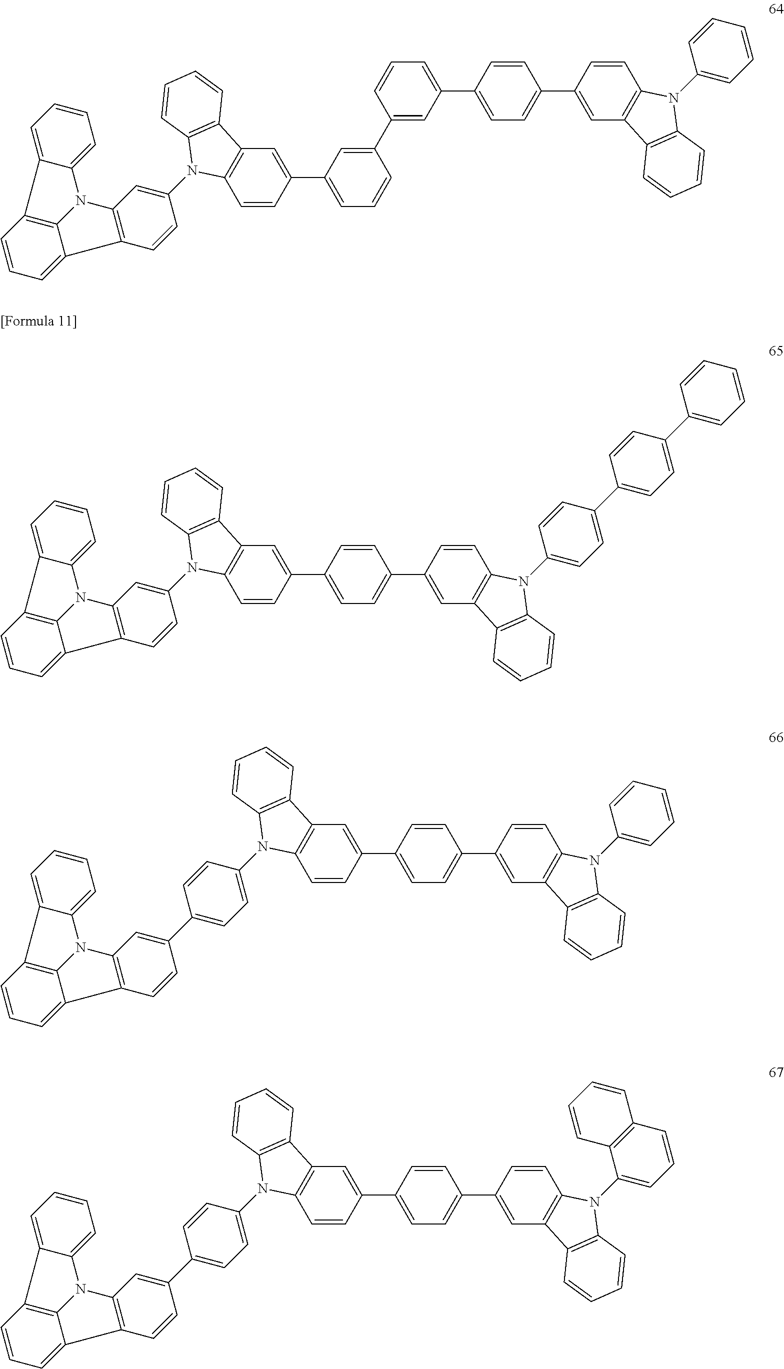 [SMILES: c1ccc(-n2c3ccccc3c3cc(-c4ccc(-c5cccc(-c6cccc(-c7ccc8c(c7)c7ccccc7n8-c7ccc8c9cccc%10c%11ccccc%11n(c8c7)c%109)c6)c5)cc4)ccc32)cc1 ; c1ccc(-c2ccc(-c3ccc(-n4c5ccccc5c5cc(-c6ccc(-c7ccc8c(c7)c7ccccc7n8-c7ccc8c9cccc%10c%11ccccc%11n(c8c7)c%109)cc6)ccc54)cc3)cc2)cc1 ; c1ccc(-n2c3ccccc3c3cc(-c4ccc(-c5ccc6c(c5)c5ccccc5n6-c5ccc(-c6ccc7c8cccc9c%10ccccc%10n(c7c6)c98)cc5)cc4)ccc32)cc1 ; c1ccc2c(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cccc2c1]

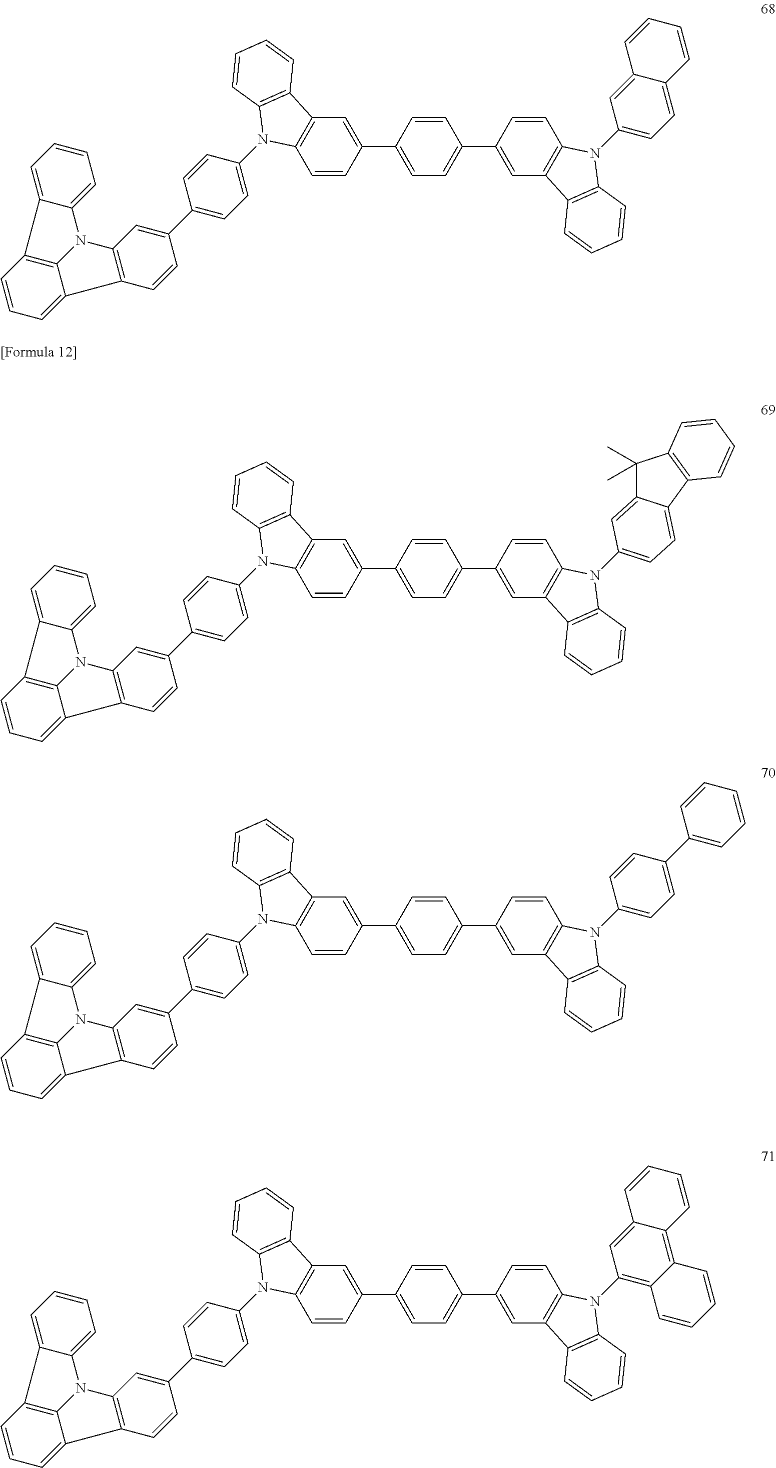

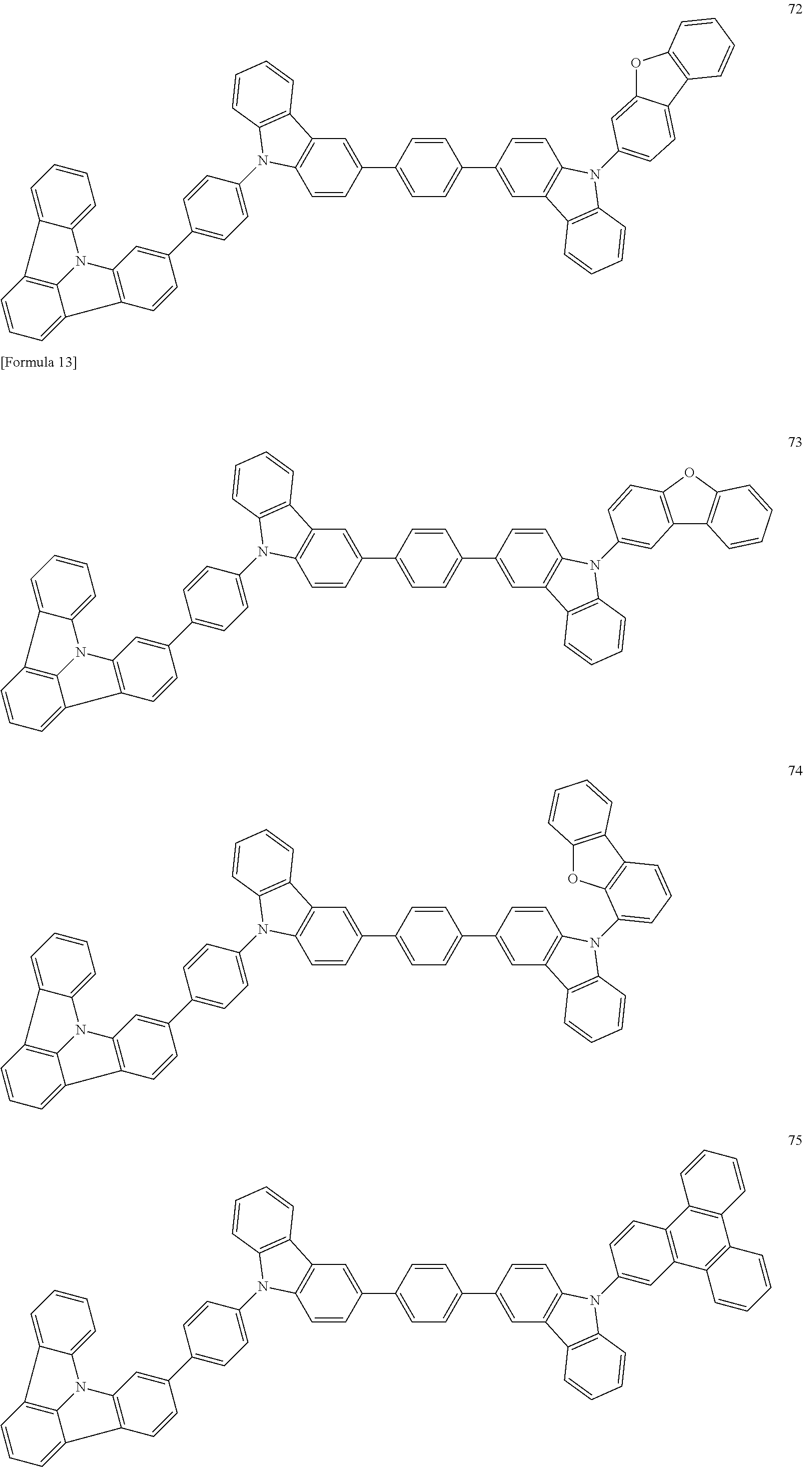

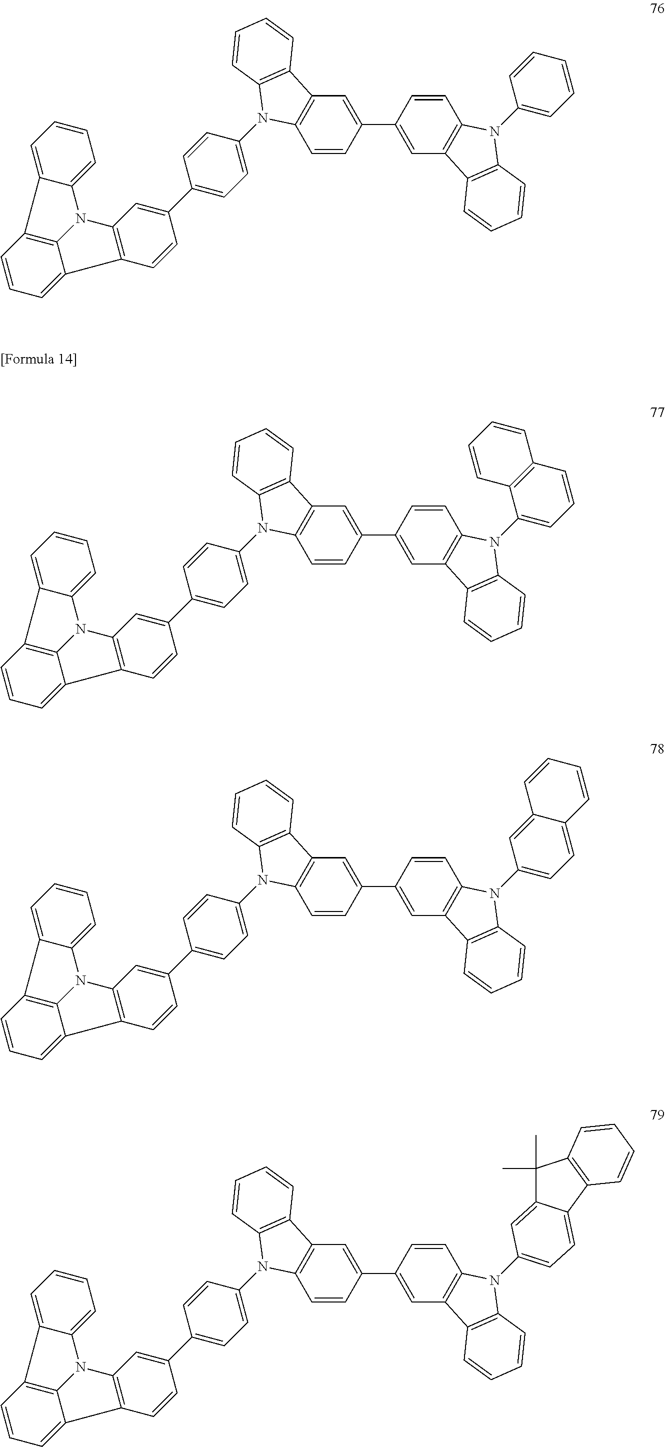 [SMILES: c1ccc(-n2c3ccccc3c3cc(-c4ccc5c(c4)c4ccccc4n5-c4ccc(-c5ccc6c7cccc8c9ccccc9n(c6c5)c87)cc4)ccc32)cc1 ; c1ccc2c(-n3c4ccccc4c4cc(-c5ccc6c(c5)c5ccccc5n6-c5ccc(-c6ccc7c8cccc9c%10ccccc%10n(c7c6)c98)cc5)ccc43)cccc2c1 ; c1ccc2cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc2c1 ; CC1(C)c2ccccc2-c2ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc21]

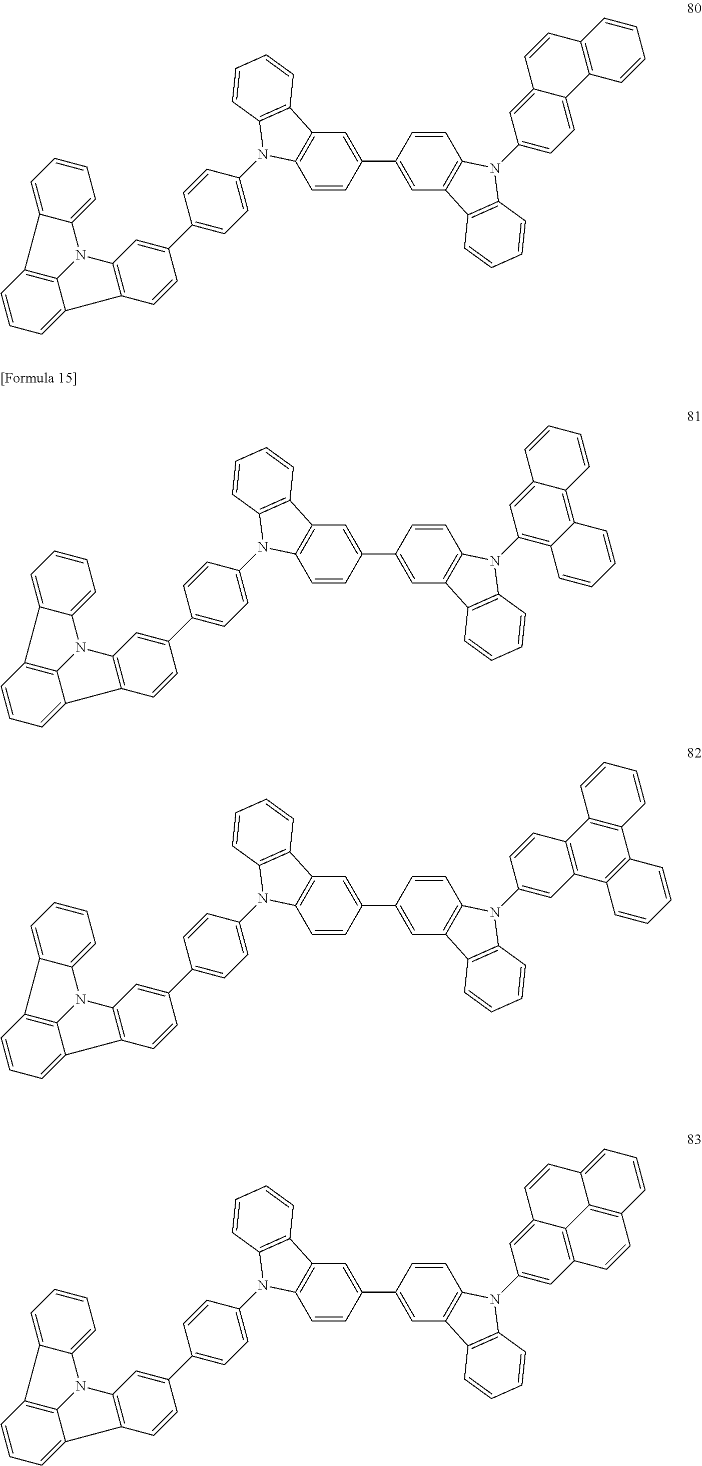 [SMILES: c1ccc2c(c1)ccc1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc12 ; c1ccc2c(c1)cc(-n1c3ccccc3c3cc(-c4ccc5c(c4)c4ccccc4n5-c4ccc(-c5ccc6c7cccc8c9ccccc9n(c6c5)c87)cc4)ccc31)c1ccccc12 ; c1ccc2c(c1)c1ccccc1c1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc21 ; c1cc2ccc3cc(-n4c5ccccc5c5cc(-c6ccc7c(c6)c6ccccc6n7-c6ccc(-c7ccc8c9cccc%10c%11ccccc%11n(c8c7)c%109)cc6)ccc54)cc4ccc(c1)c2c34]

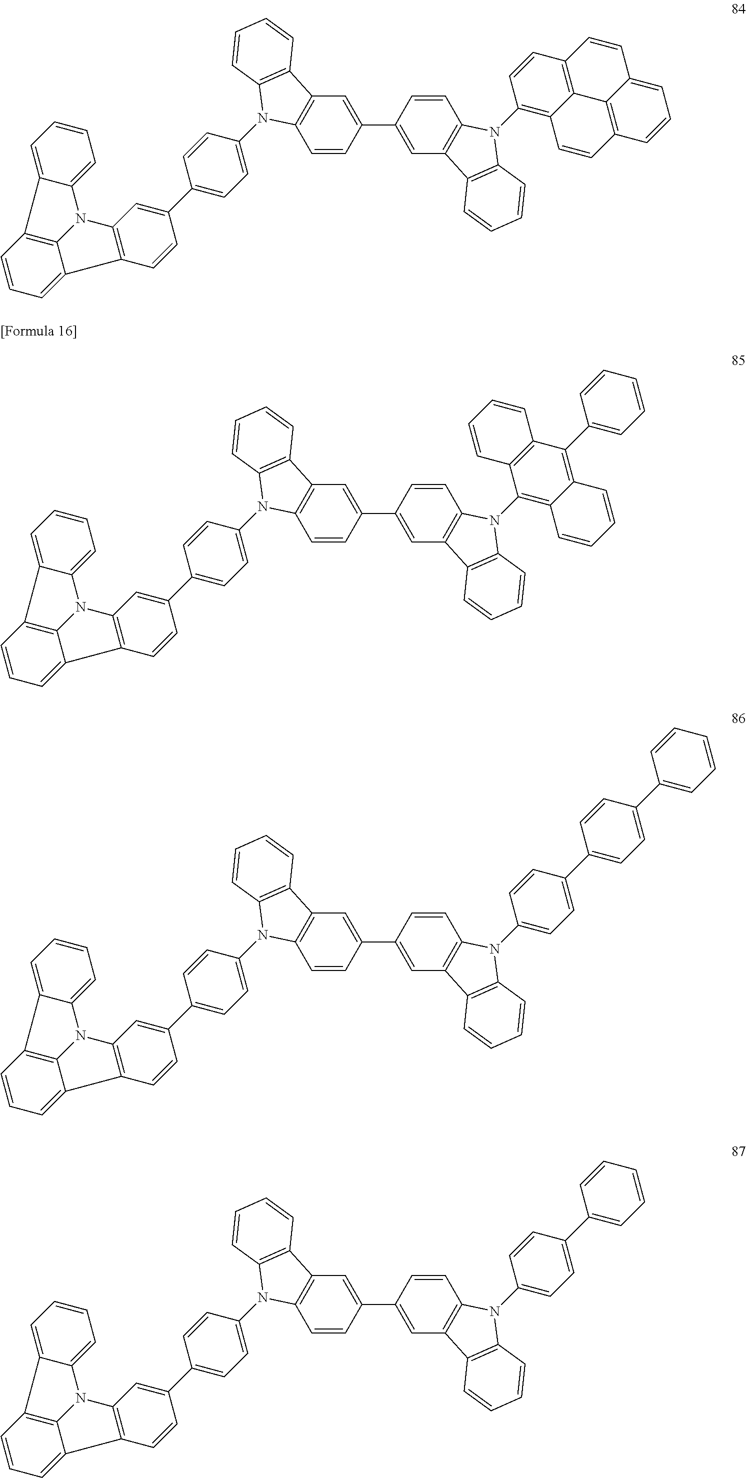 [SMILES: c1cc2ccc3ccc(-n4c5ccccc5c5cc(-c6ccc7c(c6)c6ccccc6n7-c6ccc(-c7ccc8c9cccc%10c%11ccccc%11n(c8c7)c%109)cc6)ccc54)c4ccc(c1)c2c34 ; c1ccc(-c2c3ccccc3c(-n3c4ccccc4c4cc(-c5ccc6c(c5)c5ccccc5n6-c5ccc(-c6ccc7c8cccc9c%10ccccc%10n(c7c6)c98)cc5)ccc43)c3ccccc23)cc1 ; c1ccc(-c2ccc(-c3ccc(-n4c5ccccc5c5cc(-c6ccc7c(c6)c6ccccc6n7-c6ccc(-c7ccc8c9cccc%10c%11ccccc%11n(c8c7)c%109)cc6)ccc54)cc3)cc2)cc1 ; c1ccc(-c2ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc2)cc1]

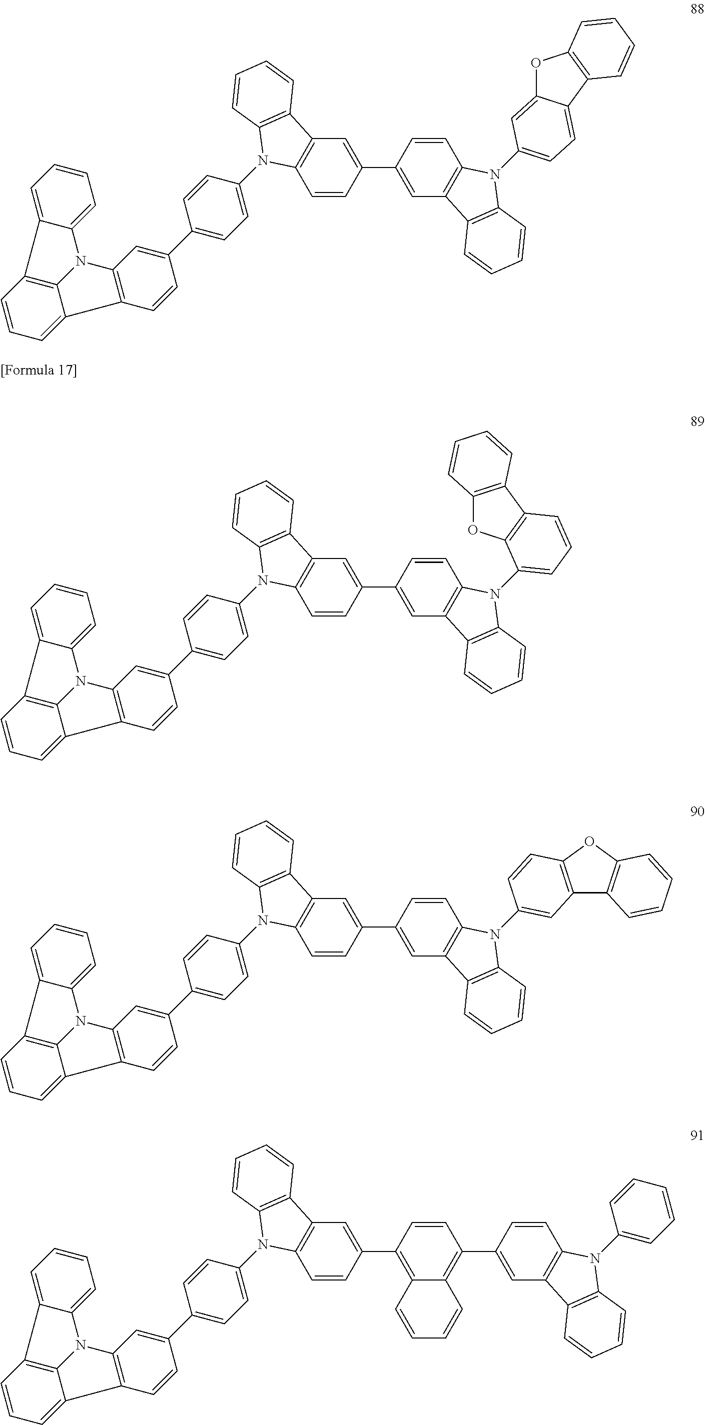 [SMILES: c1ccc2c(c1)oc1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc12 ; c1ccc2c(c1)oc1c(-n3c4ccccc4c4cc(-c5ccc6c(c5)c5ccccc5n6-c5ccc(-c6ccc7c8cccc9c%10ccccc%10n(c7c6)c98)cc5)ccc43)cccc12 ; c1ccc2c(c1)oc1ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc12 ; c1ccc(-n2c3ccccc3c3cc(-c4ccc(-c5ccc6c(c5)c5ccccc5n6-c5ccc(-c6ccc7c8cccc9c%10ccccc%10n(c7c6)c98)cc5)c5ccccc45)ccc32)cc1]

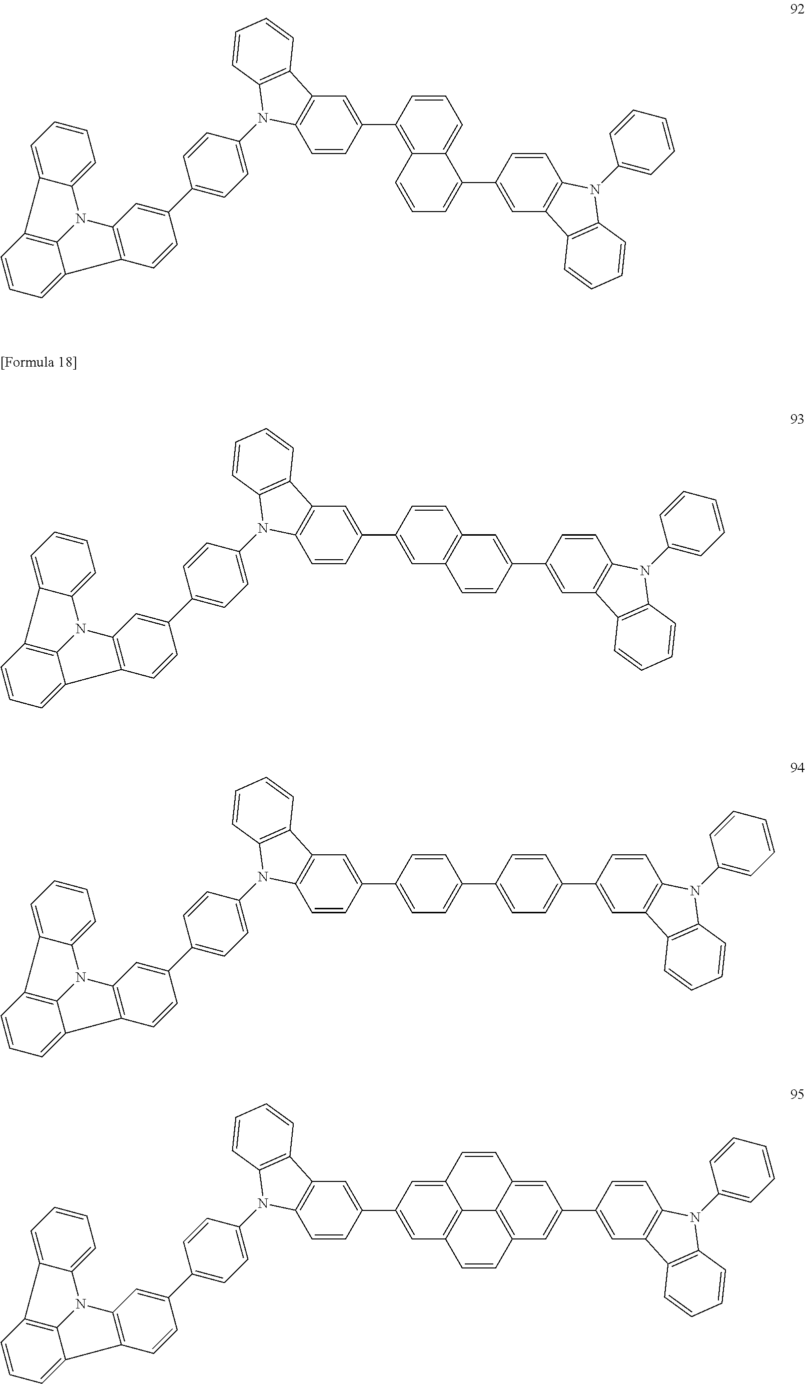

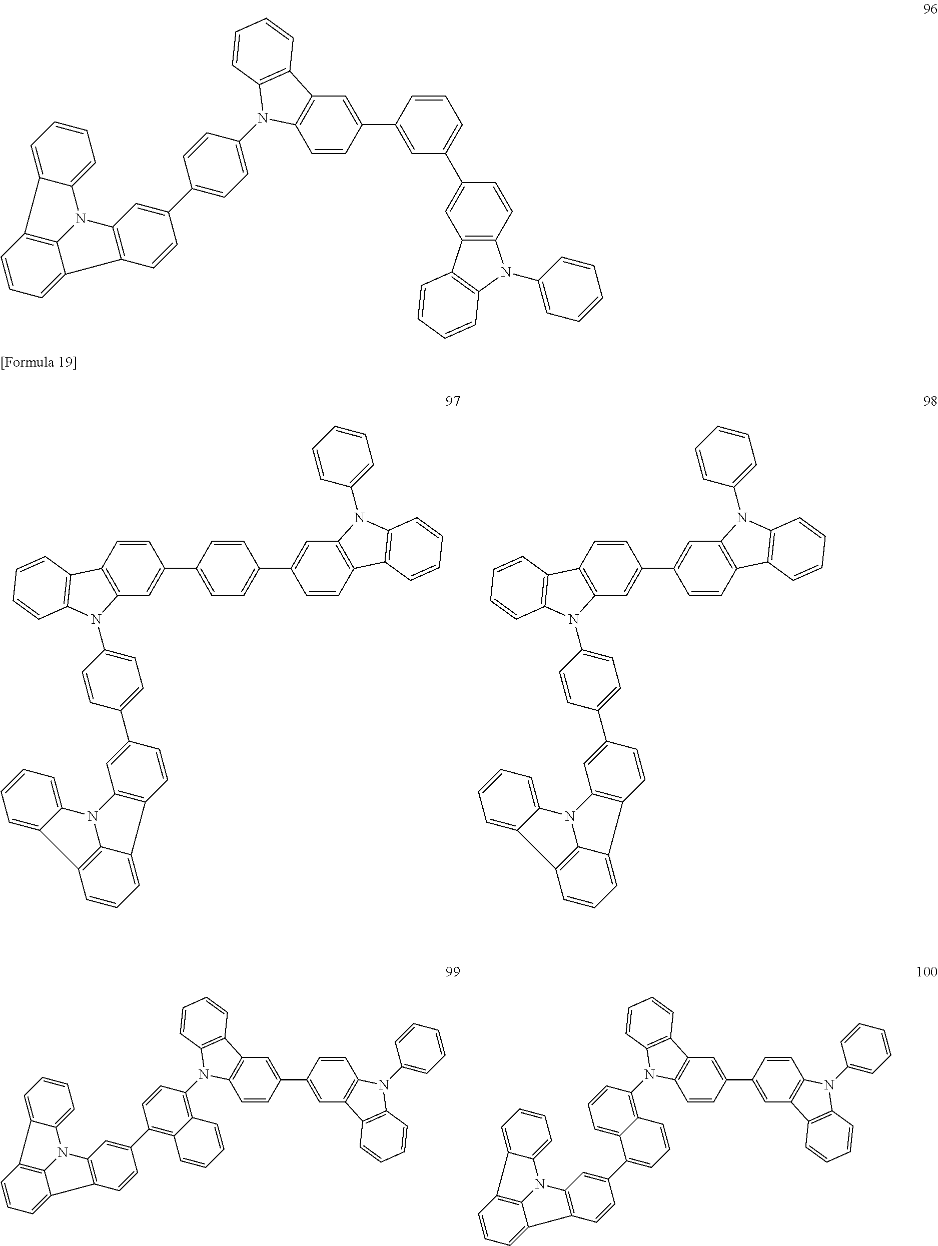

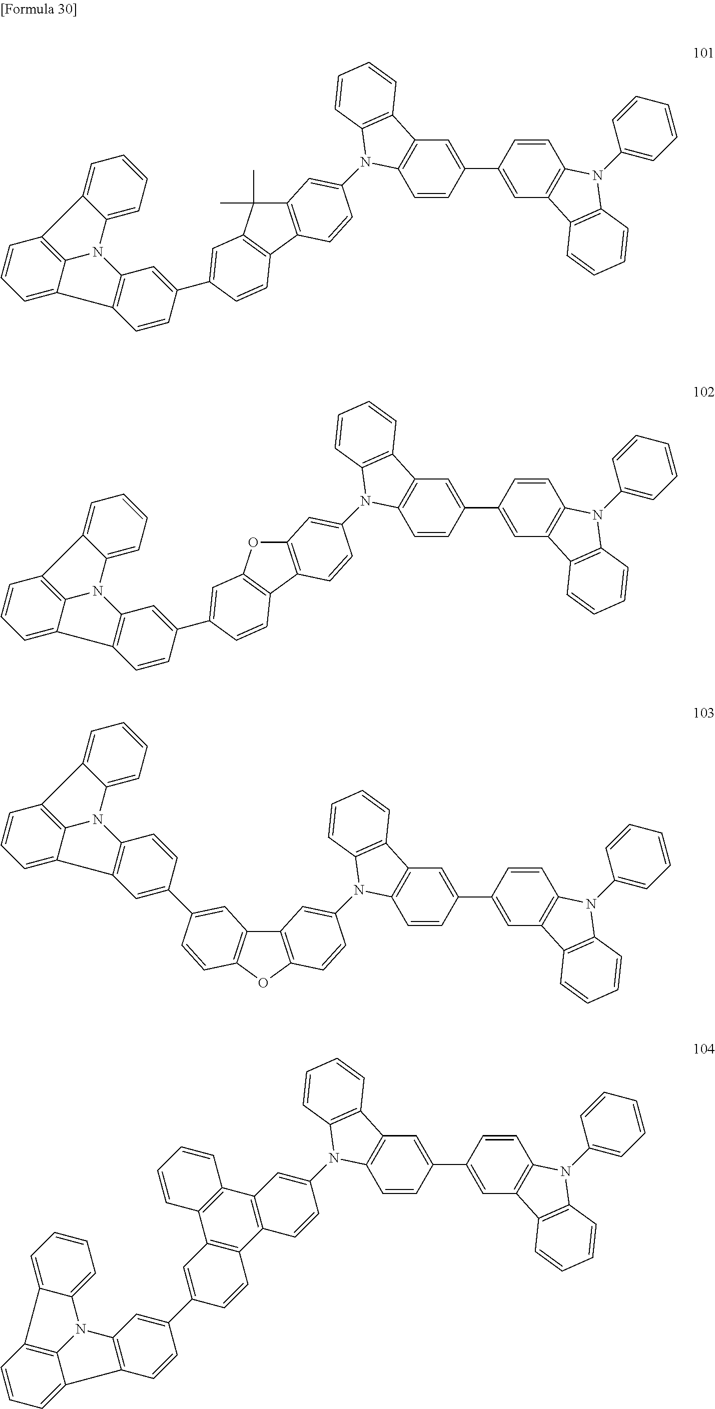 [SMILES: CC1(C)c2cc(-c3ccc4c5cccc6c7ccccc7n(c4c3)c65)ccc2-c2ccc(-n3c4ccccc4c4cc(-c5ccc6c(c5)c5ccccc5n6-c5ccccc5)ccc43)cc21 ; c1ccc(-n2c3ccccc3c3cc(-c4ccc5c(c4)c4ccccc4n5-c4ccc5c(c4)oc4cc(-c6ccc7c8cccc9c%10ccccc%10n(c7c6)c98)ccc45)ccc32)cc1 ; c1ccc(-n2c3ccccc3c3cc(-c4ccc5c(c4)c4ccccc4n5-c4ccc5oc6ccc(-c7ccc8c(c7)c7cccc9c%10ccccc%10n8c97)cc6c5c4)ccc32)cc1 ; c1ccc(-n2c3ccccc3c3cc(-c4ccc5c(c4)c4ccccc4n5-c4ccc5c6ccc(-c7ccc8c9cccc%10c%11ccccc%11n(c8c7)c%109)cc6c6ccccc6c5c4)ccc32)cc1]

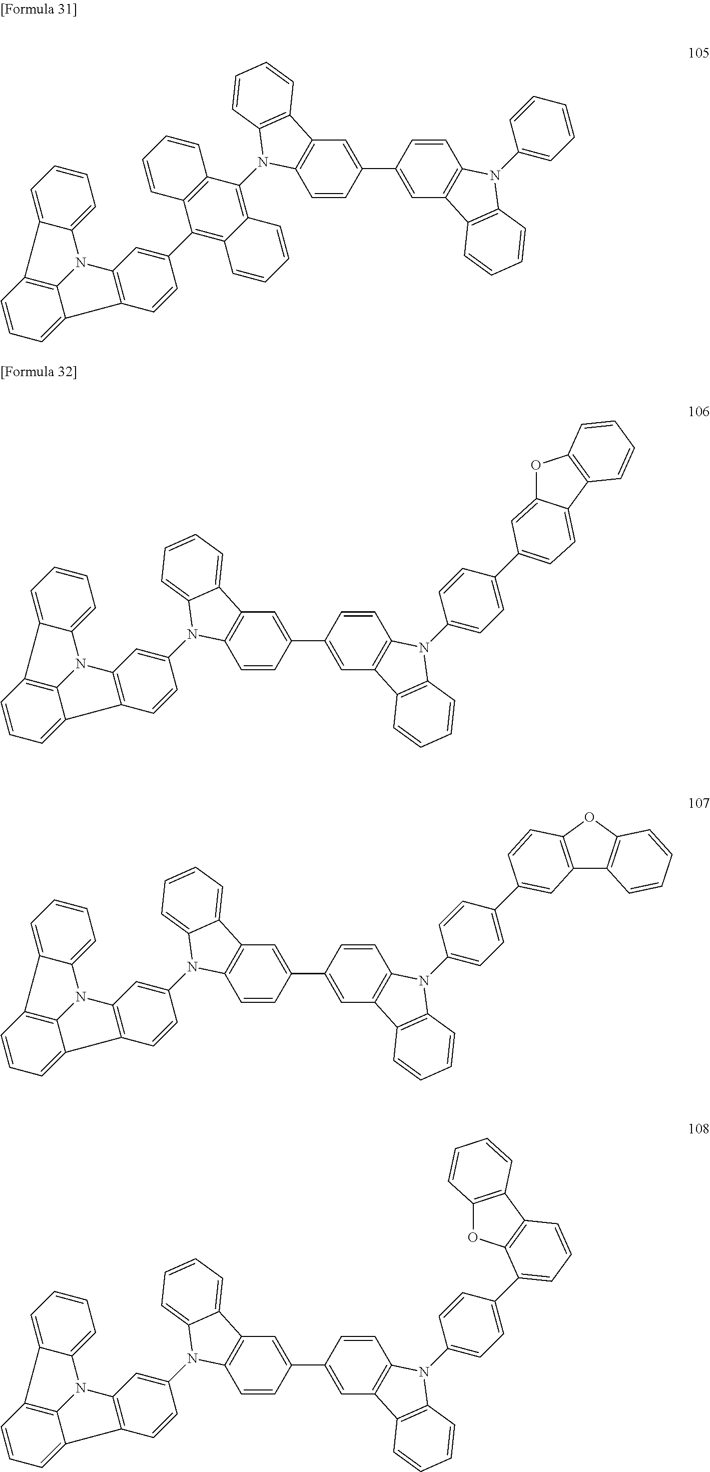 [SMILES: c1ccc(-n2c3ccccc3c3cc(-c4ccc5c(c4)c4ccccc4n5-c4c5ccccc5c(-c5ccc6c7cccc8c9ccccc9n(c6c5)c87)c5ccccc45)ccc32)cc1 ; c1ccc2c(c1)oc1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc12 ; c1ccc2c(c1)oc1ccc(-c3ccc(-n4c5ccccc5c5cc(-c6ccc7c(c6)c6ccccc6n7-c6ccc7c8cccc9c%10ccccc%10n(c7c6)c98)ccc54)cc3)cc12 ; c1ccc2c(c1)oc1c(-c3ccc(-n4c5ccccc5c5cc(-c6ccc7c(c6)c6ccccc6n7-c6ccc7c8cccc9c%10ccccc%10n(c7c6)c98)ccc54)cc3)cccc12]

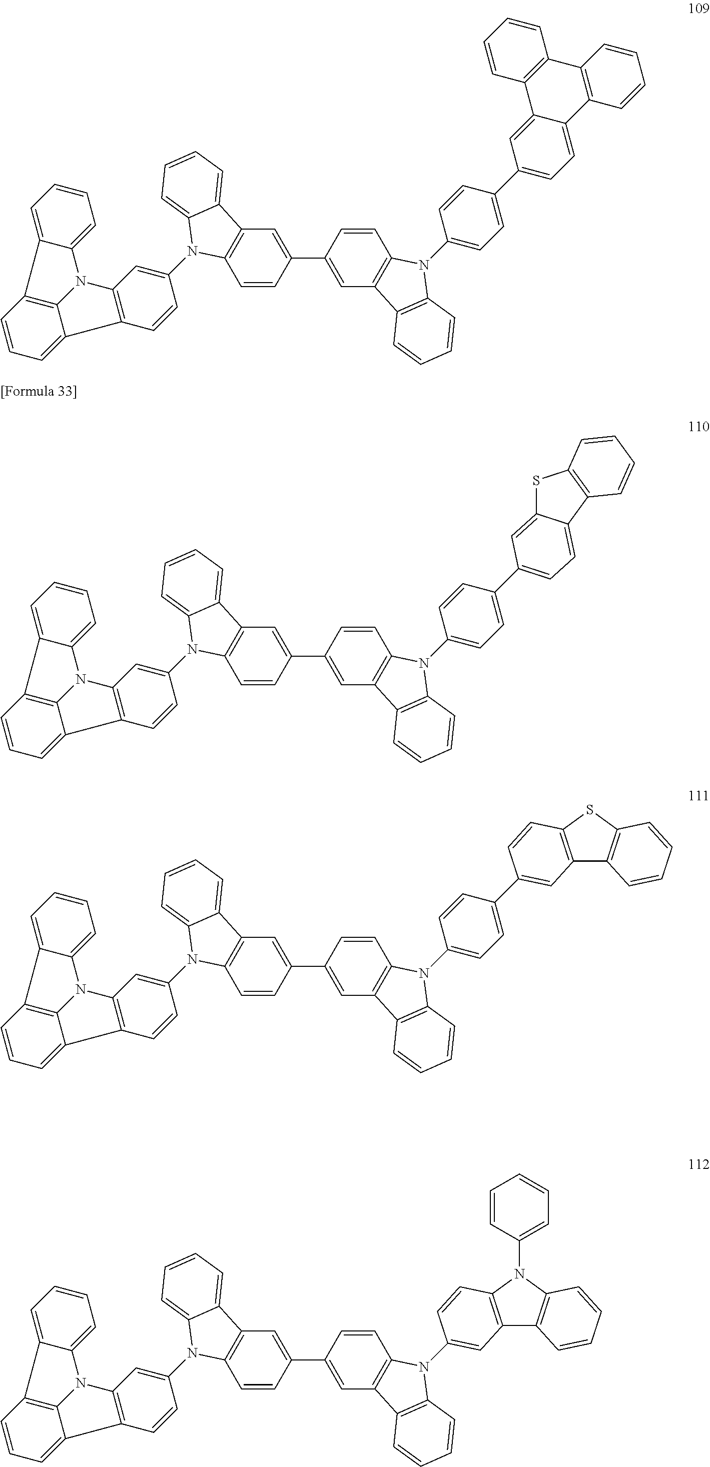 [SMILES: c1ccc2c(c1)c1ccccc1c1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc21 ; c1ccc2c(c1)sc1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc12 ; c1ccc2c(c1)sc1ccc(-c3ccc(-n4c5ccccc5c5cc(-c6ccc7c(c6)c6ccccc6n7-c6ccc7c8cccc9c%10ccccc%10n(c7c6)c98)ccc54)cc3)cc12 ; c1ccc(-n2c3ccccc3c3cc(-n4c5ccccc5c5cc(-c6ccc7c(c6)c6ccccc6n7-c6ccc7c8cccc9c%10ccccc%10n(c7c6)c98)ccc54)ccc32)cc1]

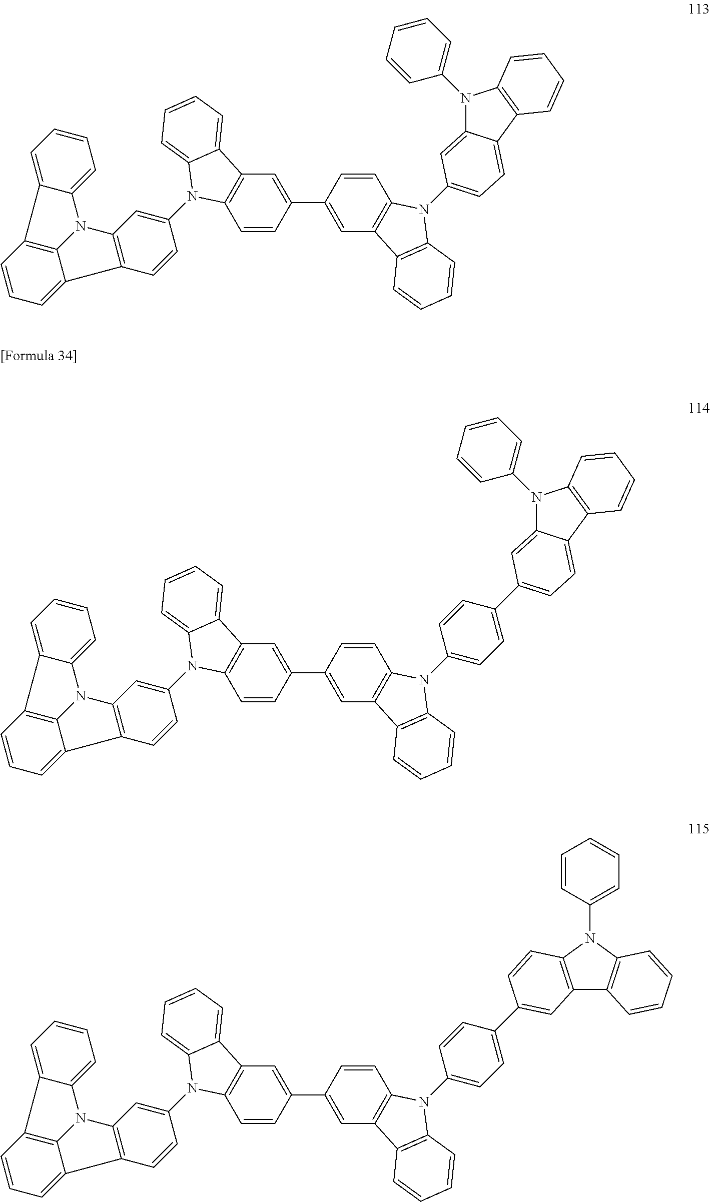 [SMILES: c1ccc(-n2c3ccccc3c3ccc(-n4c5ccccc5c5cc(-c6ccc7c(c6)c6ccccc6n7-c6ccc7c8cccc9c%10ccccc%10n(c7c6)c98)ccc54)cc32)cc1 ; c1ccc(-n2c3ccccc3c3ccc(-c4ccc(-n5c6ccccc6c6cc(-c7ccc8c(c7)c7ccccc7n8-c7ccc8c9cccc%10c%11ccccc%11n(c8c7)c%109)ccc65)cc4)cc32)cc1 ; c1ccc(-n2c3ccccc3c3cc(-c4ccc(-n5c6ccccc6c6cc(-c7ccc8c(c7)c7ccccc7n8-c7ccc8c9cccc%10c%11ccccc%11n(c8c7)c%109)ccc65)cc4)ccc32)cc1]

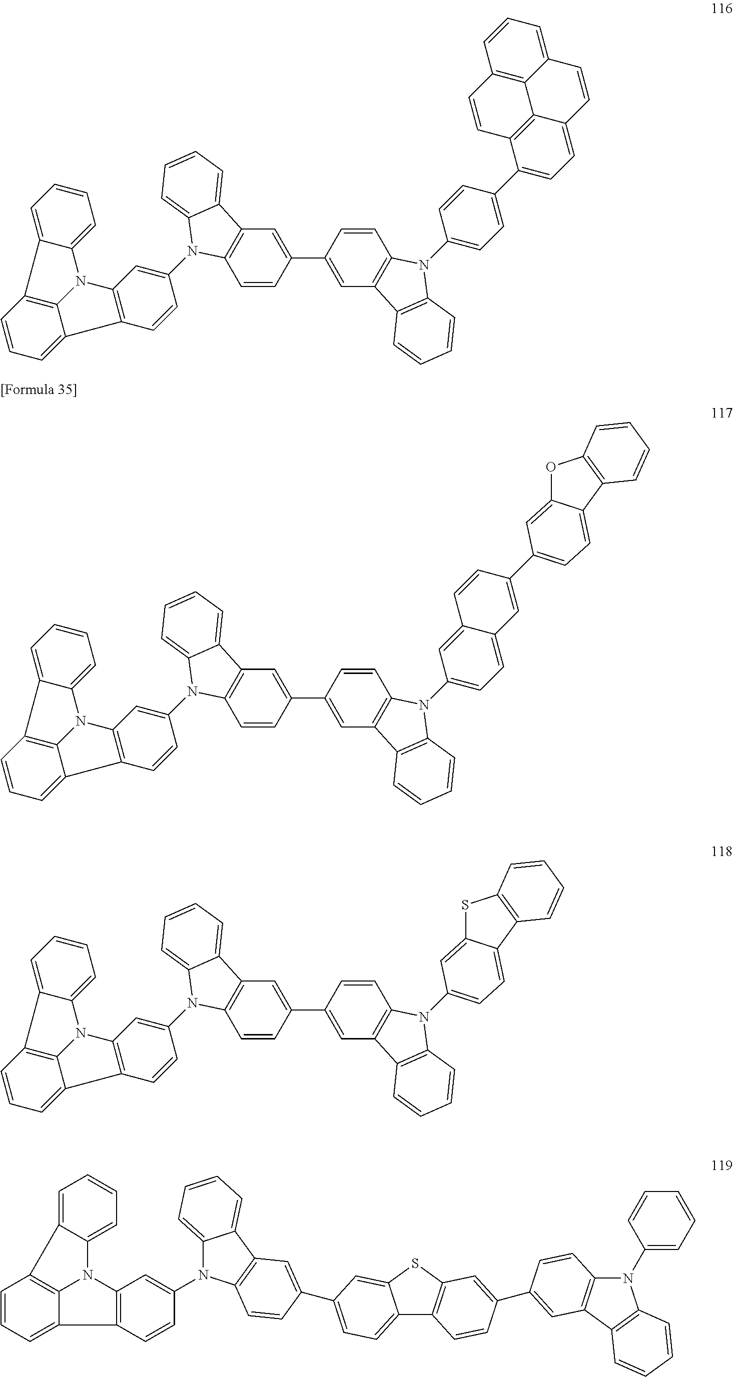 [SMILES: c1cc2ccc3ccc(-c4ccc(-n5c6ccccc6c6cc(-c7ccc8c(c7)c7ccccc7n8-c7ccc8c9cccc%10c%11ccccc%11n(c8c7)c%109)ccc65)cc4)c4ccc(c1)c2c34 ; c1ccc2c(c1)oc1cc(-c3ccc4cc(-n5c6ccccc6c6cc(-c7ccc8c(c7)c7ccccc7n8-c7ccc8c9cccc%10c%11ccccc%11n(c8c7)c%109)ccc65)ccc4c3)ccc12 ; c1ccc2c(c1)sc1cc(-n3c4ccccc4c4cc(-c5ccc6c(c5)c5ccccc5n6-c5ccc6c7cccc8c9ccccc9n(c6c5)c87)ccc43)ccc12 ; c1ccc(-n2c3ccccc3c3cc(-c4ccc5c(c4)sc4cc(-c6ccc7c(c6)c6ccccc6n7-c6ccc7c8cccc9c%10ccccc%10n(c7c6)c98)ccc45)ccc32)cc1]

The material for an organic EL device according to an embodiment may be used in a layer, for example, one of a plurality of stacked layers, disposed between an emission layer and an anode. In an embodiment, the material for an organic EL device may be used in the emission layer of an organic EL device. Thus, the electron tolerance of a layer including the material for an organic EL device may be improved, and an organic EL device having high efficiency and long life may be manufactured.

In an embodiment, the material for an organic EL device according to an embodiment may be selected for use in an emission layer, or a layer disposed between an emission layer and an anode, of an organic EL device of a blue emission region.

(Organic EL Device)

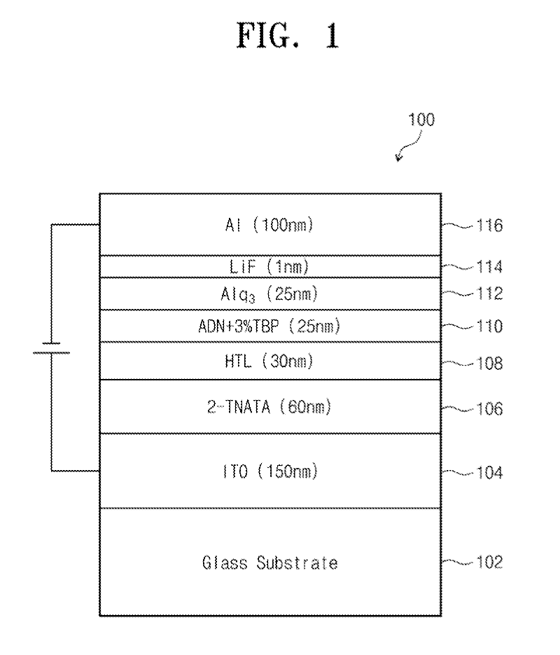

An organic EL device using the material for an organic EL device according to an embodiment will now be explained in connection with FIG. 1.

FIG. 1 is a schematic diagram illustrating a configuration of an organic EL device 100 according to an example embodiment.

Referring to FIG. 1, the organic EL device 100 may include, for example, a substrate 102, an anode 104, a hole injection layer 106, a hole transport layer 108, an emission layer 110, an electron transport layer 112, an electron injection layer 114, and a cathode 116. In an embodiment, the material for an organic EL device according to an embodiment may be used in a layer of stacked layers disposed between an emission layer and an anode. In another embodiment, the material for an organic EL device according to an embodiment may be used in an emission layer.

An embodiment using the material for an organic EL device according to an embodiment in the hole transport layer 108 will now be explained. The substrate 102 may be, for example, a transparent glass substrate, a semiconductor substrate formed by using silicon, etc., or a flexible substrate of a resin, etc. The anode 104 is disposed on the substrate 102 and may be formed by using, for example, indium tin oxide (ITO), indium zinc oxide (IZO), etc. The hole injection layer 106 is disposed on the anode 104 and may include, for example, 4,4′,4″-tris(N-1-naphthyl-N-phenylamino)triphenylamine (1-TNATA), 4,4′,4″-tris(N-(2-naphthyl)-N-phenylamino)triphenylamine (2-TNATA), N,N,N′,N′-tetrakis(3-methylphenyl)-3,3′-dimethylbenzidine (HMTPD), etc. The hole transport layer 108 is disposed on the hole injection layer 106 and is formed by using the material for an organic EL device according to an embodiment. The emission layer 110 is disposed on the hole transport layer 108 and may be formed by using, for example, a host material including 9,10-di(2-naphthyl)anthracene (ADN), etc. doped with 2,5,8,11-tetra-t-butylperylene (TBP). The electron transport layer 112 is disposed on the emission layer 110 and may be formed by using, for example, a material including tris(8-hydroxyquinolinato)aluminum (Alq₃). The electron injection layer 114 is disposed on the electron transport layer 112 and may be formed by using, for example, a material including lithium fluoride (LiF). The cathode 116 is disposed on the electron injection layer 114 and may be formed by using, for example, a metal such as Al, or a transparent material such as ITO, IZO, etc. The above-described thin layers may be formed by selecting an appropriate layer forming method such as vacuum deposition, sputtering, various coatings, etc.

In the organic EL device 100 according to the present example embodiment, a hole transport layer having high efficiency and long life may be formed by using the material for an organic EL device according to an embodiment. In addition, the material for an organic EL device according to an embodiment may be applied in an organic EL apparatus of an active matrix type using thin film transistors (TFT).

The organic EL device 100 according to an example embodiment includes the material for an organic EL device according to an embodiment in an emission layer or a layer of stacking layers disposed between the emission layer and an anode, which may help realize high efficiency and long life of the organic EL device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

(Preparation Method)

A compound for the above-described material for an organic EL device according to an embodiment may be synthesized, for example, by the following method.

(Synthesis of Compound 1 in Formula 36)

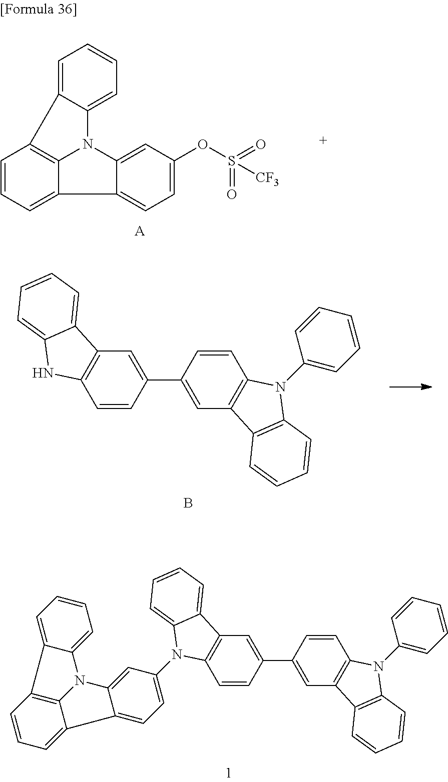

An indolocarbazole compound A (13 mmol), a carbazole compound B (13 mmol), a palladium catalyst (1.3 mol), a phosphine ligand (5.2 mol), an alkaline reagent (20 mmol), and toluene (500 mL) were added in a reaction vessel, followed by charging nitrogen in the vessel and stirring while refluxing for 30 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was recrystallized to produce Compound 1 in the above Formula 36 with yield of 5% as powder state solid (APCI+: C₄₈H₂₉N₃, measured value 647).

(Synthesis of Compound 14 of Formula 37)

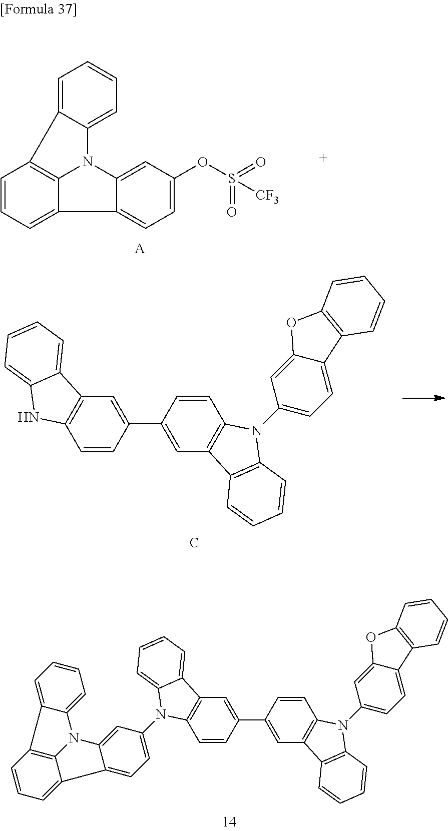

An indolocarbazole compound A (9 mmol), a carbazole compound C (9 mmol), a palladium catalyst (0.9 mol), a phosphine ligand (3.6 mol), an alkaline reagent (14 mmol), and toluene (500 mL) were added in a reaction vessel, followed by charging nitrogen in the vessel and stirring while refluxing for 29 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was re-precipitated to produce Compound 14 in the above Formula 37 with yield of 7% as powder state solid (APCI+: C₅₄H₃₁N₃O, measured value 737).

(Synthesis of Compound 16 in Formula 38)

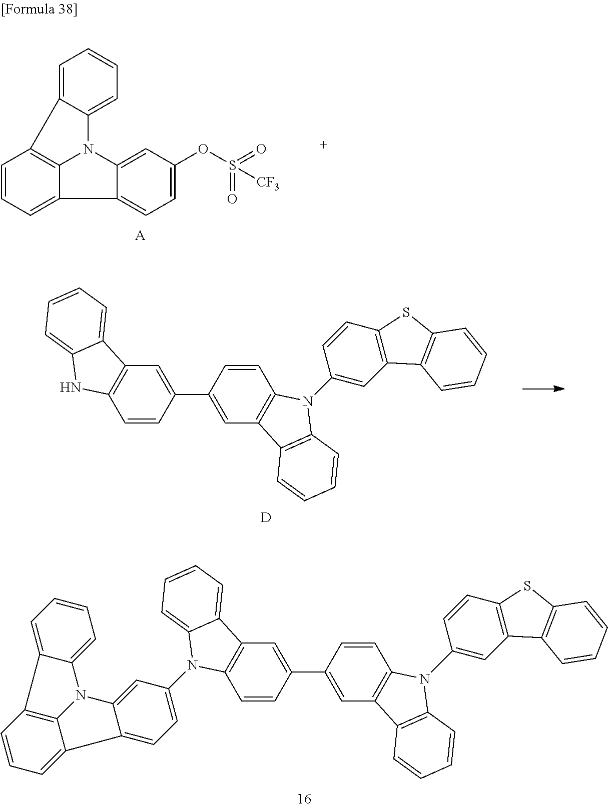

An indolocarbazole compound A (8 mmol), a carbazole compound D (8 mmol), a palladium catalyst (0.8 mol), a phosphine ligand (3.2 mol), an alkaline reagent (12 mmol), and toluene (500 mL) were added in a reaction vessel, followed by charging nitrogen in the vessel and stirring while refluxing for 25 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was re-precipitated to produce Compound 16 in the above Formula 38 with yield of 5% as powder state solid (APCI+: C₅₄H₃₁N₃S, measured value 753).

(Synthesis of Compound 35 of Formula 39)

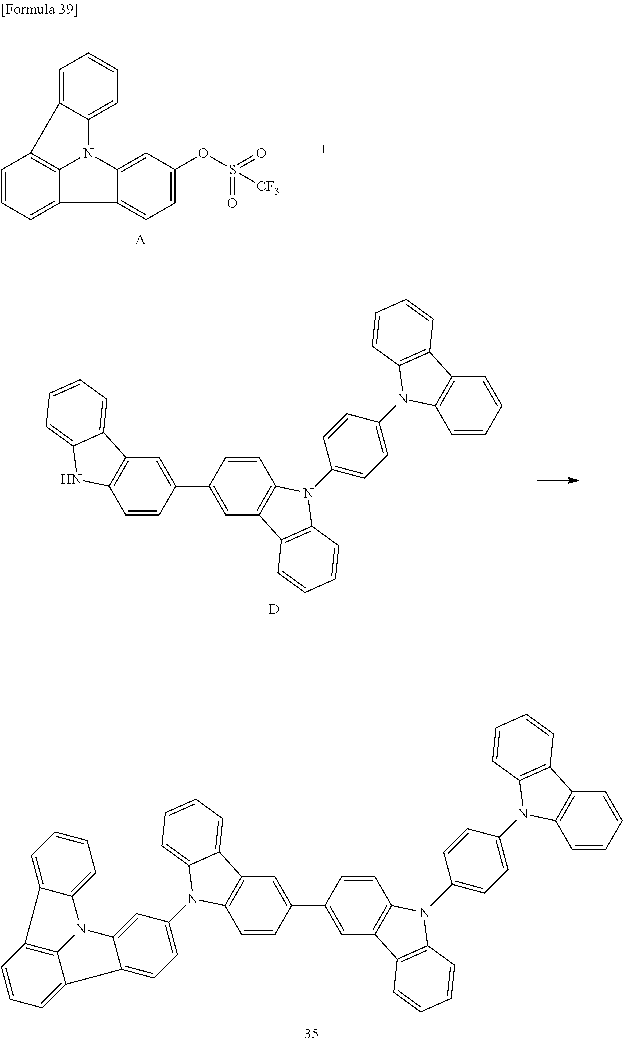

An indolocarbazole compound A (11 mmol), a carbazole compound E (11 mmol), a palladium catalyst (1.1 mol), a phosphine ligand (4.4 mol), an alkaline reagent (17 mmol), and toluene (500 mL) were added in a reaction vessel, followed by charging nitrogen in the vessel and stirring while refluxing for 27 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was re-precipitated to produce Compound 35 in the above Formula 39 with yield of 8% as powder state solid (APCI+: C₆₀H₃₆N₄, measured value 812).

(Synthesis of Compound 36 of Formula 40)

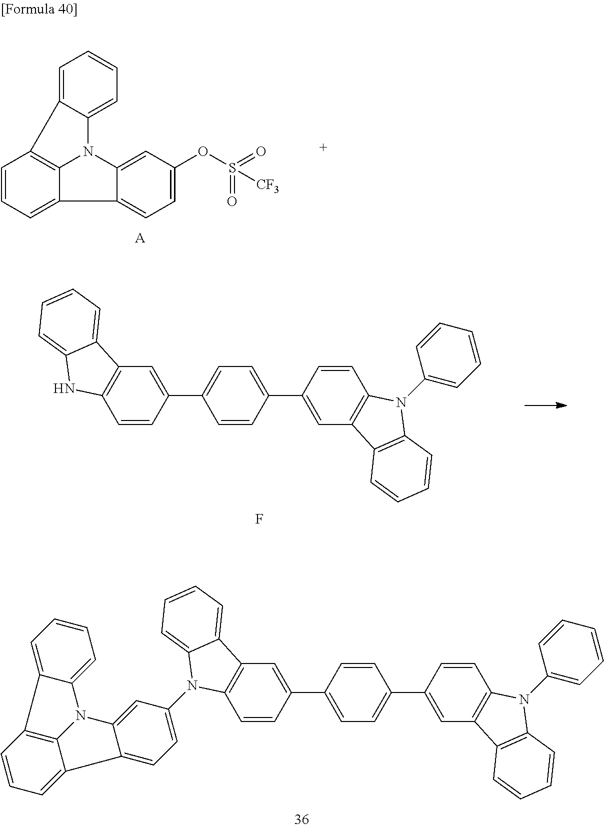

An indolocarbazole compound A (10 mmol), a carbazole compound F (10 mmol), a palladium catalyst (0.1 mol), a phosphine ligand (0.4 mol), an alkaline reagent (15 mmol), and toluene (500 mL) were added in a reaction vessel, followed by charging nitrogen in the vessel and stirring while refluxing for 25 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was re-precipitated to produce Compound 36 in the above Formula 40 with yield of 4% as powder state solid (APCI+: C₅₄H₃₃N₃, measured value 723).

(Synthesis of Compound 76 of Formula 41)

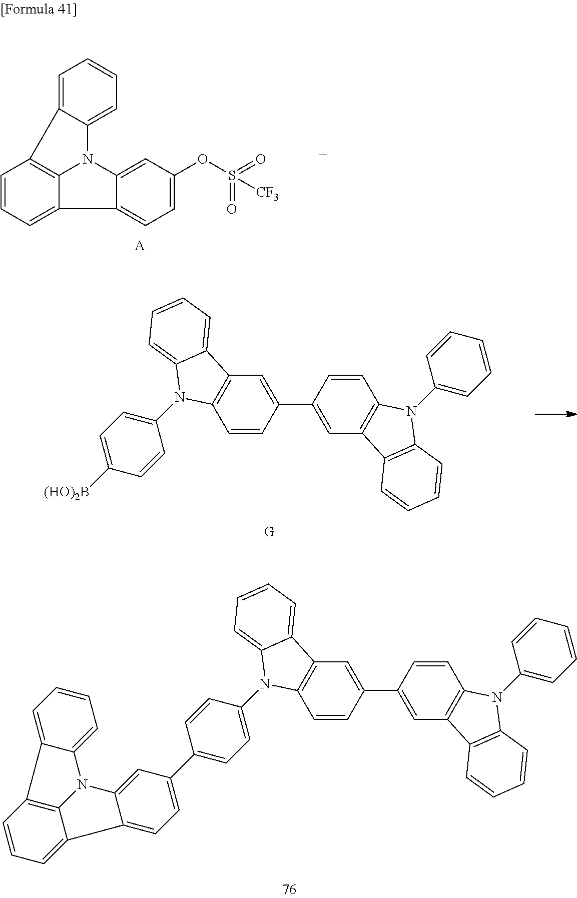

An indolocarbazole compound A (5 mmol), a carbazole compound G (5 mmol), a palladium catalyst (0.5 mol), a phosphine ligand (2.0 mol), an alkaline reagent (10 mmol), toluene (500 mL), water (30 mL), and ethanol (15 mL) were added in a reaction vessel, followed by charging nitrogen in the vessel and stirring while refluxing for 20 hours. After cooling, water was added in the reactant, and extraction of an organic layer was performed. The organic layer thus obtained was dried with magnesium sulfate and filtered, and the filtrate thus obtained was concentrated using a rotary evaporator. The crude product thus obtained was separated by silica gel column chromatography, and the solid thus obtained was recrystallized to produce Compound 76 in the above Formula 41 with yield of 40% as powder state solid (APCI+: C₅₄H₃₃N₃, measured value 723).

According to the above-described methods, Compounds 1, 14, 16, 35, 36, and 76 were prepared for materials for an organic EL device according to an embodiment. In addition, the following Comparative Compounds 1 and 2 were prepared for comparison.

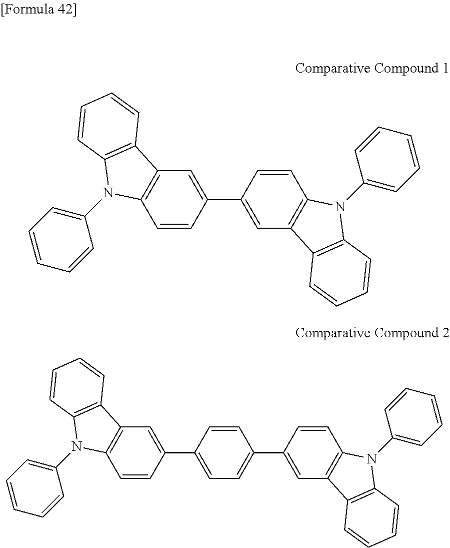 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc(-c5ccc6c(c5)c5ccccc5n6-c5ccccc5)cc4)ccc32)cc1]

Organic EL devices were manufactured using Compound 1, Compound 14,

Compound 16, Compound 35, Compound 36, and Compound 76, which were used in materials for an organic EL device according to an embodiment, and using Comparative Compound 1, and Comparative Compound 2, as hole transport materials of a hole transport layer.

In detail, the substrate 102 was formed by using a transparent glass substrate, the anode 104 was formed using ITO to a thickness of about 150 nm, the hole injection layer 106 was formed using 2-TNATA to a thickness of about 60 nm, the hole transport layer 108 was formed to a thickness of about 30 nm, the emission layer 110 was formed using ADN doped with 3% TBP to a thickness of about 25 nm, the electron transport layer 112 was formed using Alq₃ to a thickness of about 25 nm, the electron injection layer 114 was formed using LiF to a thickness of about 1 nm, and the cathode 116 was formed using Al to a thickness of about 100 nm.

With respect to the organic EL devices thus manufactured, the driving voltage, the emission efficiency, and the half life were evaluated. The values were measured and evaluated at current density of 10 mA/cm². The half life means luminance half life from an initial luminance of 1,000 cd/m². The evaluation results are illustrated in Table 1.

TABLE 1

| | Compound used | | Current | |
|---|---|---|---|---|
| | in hole transport | | efficiency | |
| | material | Voltage (V) | (cd/A) | Life (hr) |
| Example 1 | Compound 1 | 6.5 | 8.0 | 2,500 |
| Example 2 | Compound 14 | 6.6 | 8.1 | 2,700 |
| Example 3 | Compound 16 | 6.7 | 7.7 | 2,600 |
| Example 4 | Compound 35 | 6.4 | 7.8 | 2,900 |
| Example 5 | Compound 36 | 6.7 | 7.5 | 3,000 |
| Example 6 | Compound 76 | 6.3 | 7.9 | 2,800 |
| Comparative | Comparative | 8.0 | 5.0 | 1,300 |
| Example 1 | Compound 1 | | | |
| Comparative | Comparative | 7.8 | 5.0 | 1,200 |
| Example 2 | Compound 2 | | | |

As shown in Table 1, the material for an organic EL device according to an embodiment, i.e., using Compound 1, Compound 14, Compound 16, Compound 35, Compound 36, and Compound 76, could contribute to an organic EL device driven by a lower voltage when compared to Comparative Compound 1, and Comparative Compound 2. In addition, with respect to the current efficiency, the material for an organic EL device according to an embodiment, i.e., using Compound 1, Compound 14, Compound 16, Compound 35, Compound 36, and Compound 76, could realize higher current efficiency when compared to Comparative Compound 1, and Comparative Compound 2. With respect to the half life, quite long life was obtained for the material according to an embodiment. Thus, the high efficiency and the long life of an organic EL device may be realized by using the material for an organic EL device according to an embodiment as a hole transport material.

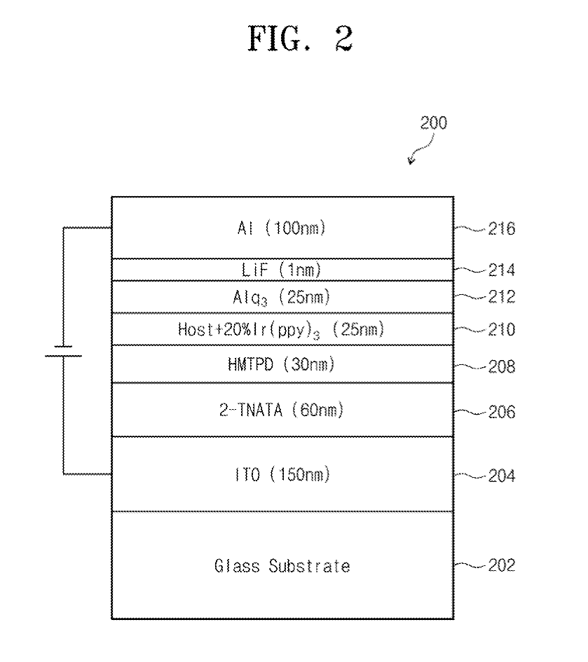

In addition, organic EL devices were manufactured by using Compound 1, Compound 14, Compound 16, Compound 35, Compound 36, and Compound 76, which were used in materials for an organic EL device according to an embodiment, and using Comparative Compound 1 and Comparative Compound 2, as host materials of emission layers by the above-described manufacturing method. An organic EL device 200 using Compound 1, Compound 14, Compound 16, Compound 35, Compound 36, or Compound 76, which were used in materials according to an embodiment, and using Comparative Compound 1 or Comparative Compound 2, as the host material of the emission layer is illustrated in FIG. 2.

In detail, in the organic EL device 200, a substrate 202 was formed using a transparent glass substrate, an anode 204 was formed using ITO to a thickness of about 150 nm, a hole injection layer 206 was formed using 2-TNATA to a thickness of about 60 nm, a hole transport layer 208 was formed using HMTPD to a thickness of about 30 nm, an emission layer 210 was formed using Compound 1, Compound 14, Compound 16, Compound 35, Compound 36, Compound 76, Comparative Compound 1, or Comparative Compound 2, respectively doped with 3% Ir(ppy)₃, to have a thickness of about 25 nm, an electron transport layer 212 was formed using Alq₃ to a thickness of about 25 nm, an electron injection layer 214 was formed using LiF to a thickness of about 1 nm, and a cathode 216 was formed using Al to a thickness of about 100 nm.

With respect to the organic EL devices thus manufactured, the driving voltage, the emission efficiency, and the half life were evaluated. The values were measured and evaluated at current density of 10 mA/cm². The half life means luminance half life from an initial luminance of 1,000 cd/m². The evaluation results are illustrated in Table 2.

TABLE 2

| | Compound used | | | |
|---|---|---|---|---|
| | as host of | Voltage | Current efficiency | |
| | emission material | (V) | (cd/A) | Life (hr) |
| Example 7 | Compound 1 | 4.4 | 30.2 | 1,900 |
| Example 8 | Compound 14 | 4.7 | 32.0 | 2,000 |
| Example 9 | Compound 16 | 4.9 | 29.5 | 1,800 |
| Example 10 | Compound 35 | 4.3 | 30.5 | 2,100 |
| Example 11 | Compound 36 | 4.5 | 31.1 | 2,200 |
| Example 12 | Compound 76 | 4.2 | 30.5 | 2,300 |
| Comparative | Comparative | 5.5 | 28.7 | 1,100 |
| Example 3 | Compound 1 | | | |
| Comparative | Comparative | 5.2 | 25.0 | 1,200 |
| Example 4 | Compound 2 | | | |

As shown in Table 2, the material for an organic EL device according to an embodiment, i.e., using Compound 1, Compound 14, Compound 16, Compound 35, Compound 36, and Compound 76, could contribute to an organic EL device driven at a lower voltage when compared to Comparative Compound 1, and Comparative Compound 2. In addition, with respect to the current efficiency, the material for an organic EL device according to an embodiment, i.e., using Compound 1, Compound 14, Compound 16, Compound 35, Compound 36, and Compound 76, could realize higher current efficiency when compared to Comparative Compound 1, and Comparative Compound 2. With respect to the half life, quite long life was obtained for the material according to an embodiment. Thus, the high efficiency and the long life of an organic EL device may be realized by using the material for an organic EL device according to an embodiment as the host material of the emission layer.

By way of summation and review, an example of an organic electroluminescence device (referred to as an organic EL device) is an organic EL device that includes an anode, a hole transport layer disposed on the anode, an emission layer disposed on the hole transport layer, an electron transport layer disposed on the emission layer, and a cathode disposed on the electron transport layer. Holes injected from the anode are injected into the emission layer via the hole transport layer. Meanwhile, electrons are injected from the cathode, and then injected into the emission layer via the electron transport layer. The holes and the electrons injected into the emission layer are recombined to generate excitons within the emission layer. The organic EL device emits light by using light generated by the radiation deactivation of the excitons. The organic EL device may have various forms.

In the application of the organic EL device in a display apparatus, driving at a low voltage, high efficiency, and long life of the organic EL device are desired, and the normalization and the stabilization of a hole transport layer have been studied to help realize the high efficiency and the long life of the organic EL device. As a material used in a hole transport layer, various compounds such as a carbazole derivative or an aromatic amine-based compound may be considered. As a material useful for the realization of the high efficiency and the long life of an organic EL device, a compound in which two carbazolyl groups are combined via a divalent group derived from fluorene, a compound in which two carbazolyl groups are combined via a divalent group derived from pyrene, an amine compound combined with a phenyl group via a divalent group derived from carbazole, a compound in which two carbazolyl groups are combined via a single bond or a divalent group derived from an aromatic ring compound, etc., have been considered. However, organic EL devices using those materials may be difficult to realize with high emission efficiency and emission life. In addition, emission efficiency of an organic EL device in a blue emission region may be low when compared to that in a red emission region or a green emission region. Thus, an increase of the emission efficiency in the blue emission region is desired.

As described above, embodiments relate to a material for an organic electroluminescence device that may have high efficiency and long life, and an organic electroluminescence device using the same. According to an embodiments, the high efficiency and the long life of the organic EL device may be attained.

According to embodiments, a material for an organic EL device having high efficiency and long life, and an organic EL device using the same may be provided. A material for an organic EL device having high efficiency and long life, and manufactured using the material in an emission layer or in a layer disposed between the emission layer and an anode, and an organic EL device using the same may be provided. An organic EL device having improved electron tolerance, high efficiency, and long life may be manufactured using a carbazole coupled compound with high hole transporting properties substituted with an indolocarbazolyl group with high electron tolerance according to an embodiment. A compound for use in a material according to an embodiment may include carbazole moieties with high hole transporting properties and an indolocarbazolyl moiety with high electron tolerance. The material may be used as, e.g., a hole transport material or an emission material, e.g., as a host.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A material for an organic electroluminescence (EL) device, the material including a compound represented by the following Formula 1: 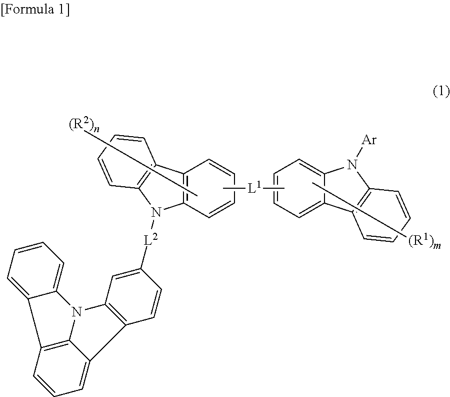
wherein Ar is a substituted or unsubstituted alkyl group, a substituted or unsubstituted aryl group, or a substituted or unsubstituted heteroaryl group, L¹ and L² are independently a single bond, a substituted or unsubstituted arylene group, or a substituted or unsubstituted heteroarylene group, R¹ and R² are independently hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and m and n are independently an integer from 1 to 7.

2. The material as claimed in claim 1, wherein Ar is a substituted or unsubstituted aryl group having 6 to 24 ring carbon atoms.

3. The material as claimed in claim 1, wherein Ar is a substituted or unsubstituted carbazolyl group, a substituted or unsubstituted dibenzofuryl group, or a substituted or unsubstituted dibenzothienyl group.

4. The material as claimed in claim 1, wherein L¹ and L² are independently a single bond, or a substituted or unsubstituted arylene group having 6 to 18 ring carbon atoms.

5. The material as claimed in claim 1, wherein R¹ and R² are independently hydrogen, or a substituted or unsubstituted aryl group.

6. An organic electroluminescence (EL) device comprising a material that includes a compound represented by the following Formula 1: 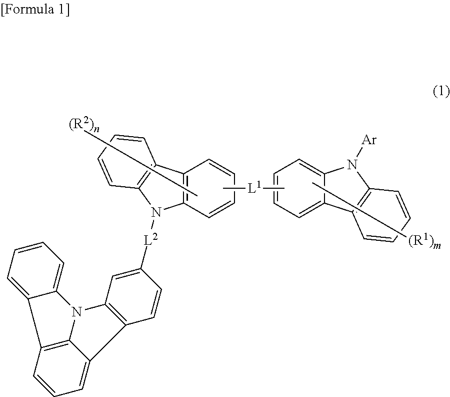
wherein Ar is a substituted or unsubstituted alkyl group, a substituted or unsubstituted aryl group, or a substituted or unsubstituted heteroaryl group, L¹ and L² are independently a single bond, a substituted or unsubstituted arylene group, or a substituted or unsubstituted heteroarylene group, R¹ and R² are independently hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and m and n are independently an integer from 1 to 7.

7. The organic EL device as claimed in claim 6, wherein Ar is a substituted or unsubstituted aryl group having 6 to 24 ring carbon atoms.

8. The organic EL device as claimed in claim 6, wherein L¹ and L² are independently a single bond, or a substituted or unsubstituted arylene group having 6 to 18 ring carbon atoms.

9. The organic EL device as claimed in claim 6, wherein the material is a hole transport material.

10. The organic EL device as claimed in claim 9, wherein the hole transport material is in a layer disposed between an emission layer and an anode.

11. The organic EL device as claimed in claim 6, wherein the material is a host material.

12. The organic EL device as claimed in claim 11, wherein the host material is in an emission layer.

13. The organic EL device as claimed in claim 6, wherein the compound represented by Formula 1 includes one or more compounds represented in the following Formula 3, Formula 4, Formula 5, and Formula 6:

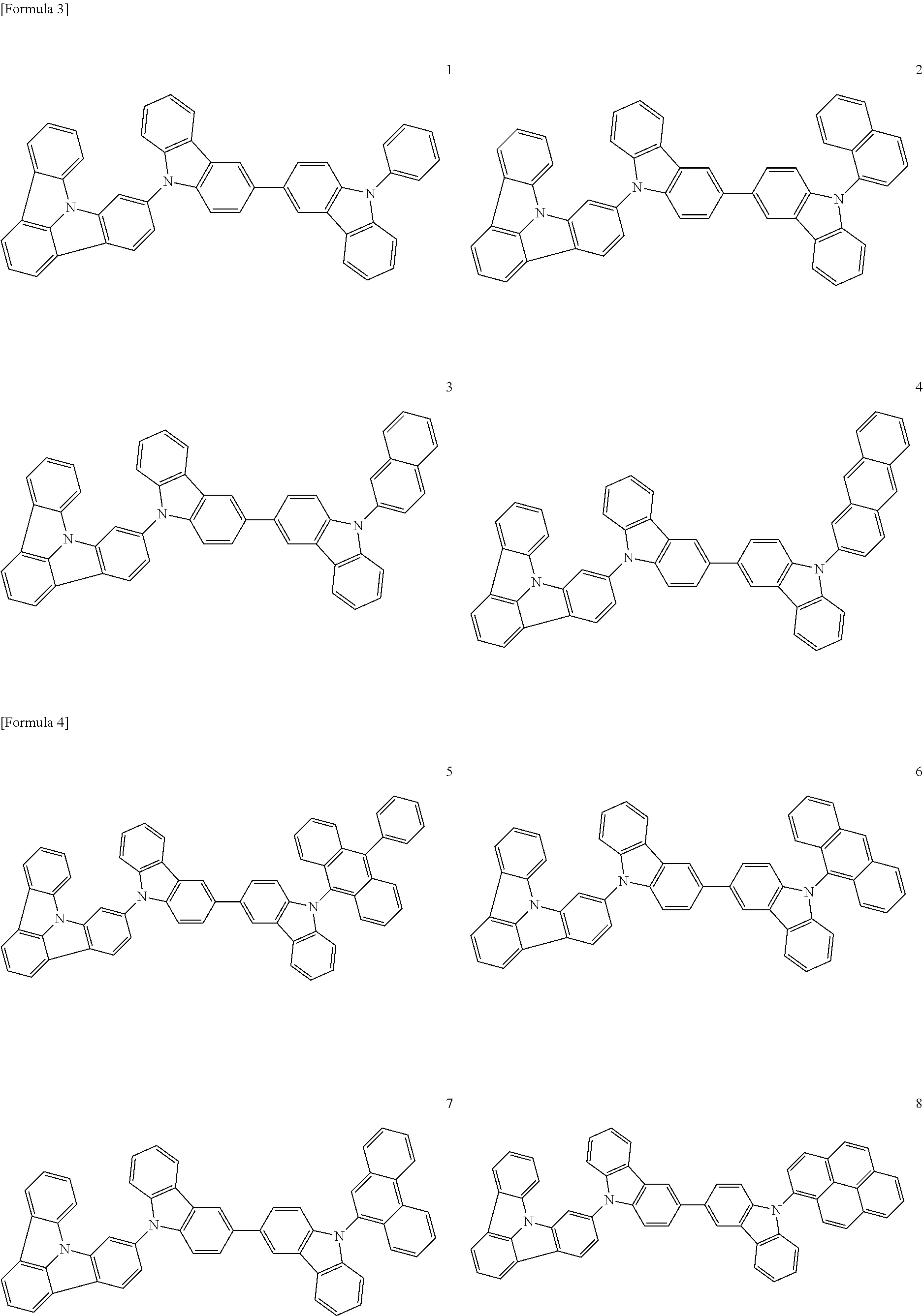

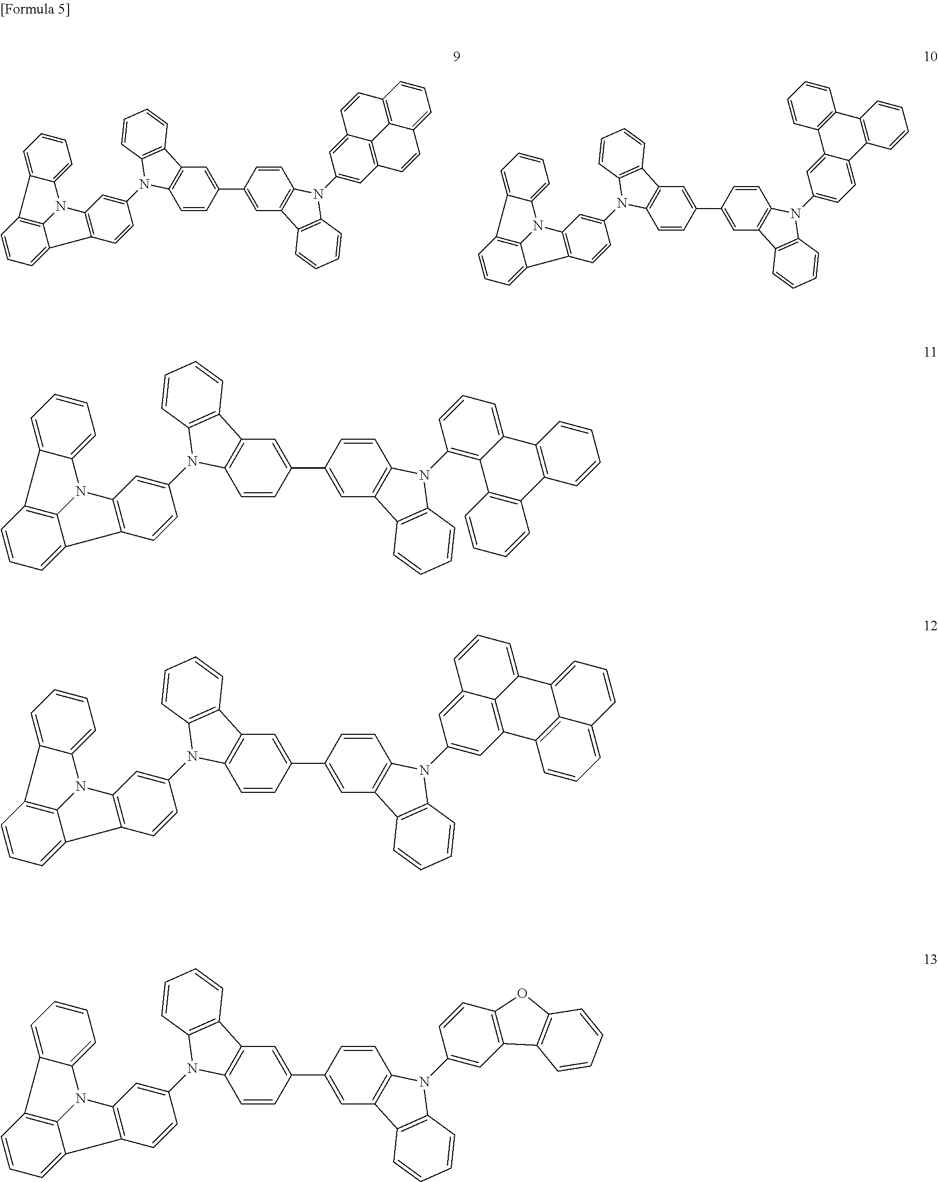

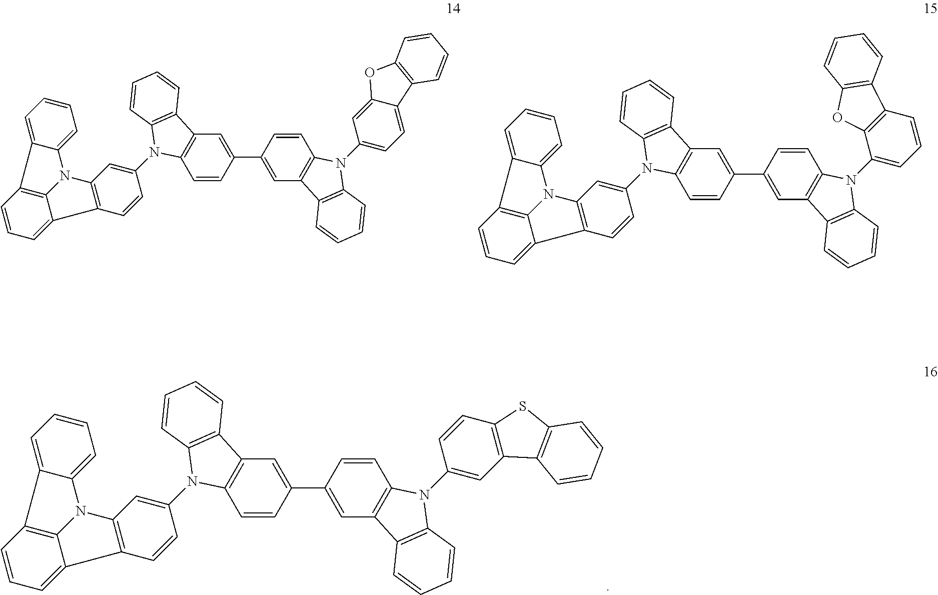 [SMILES: c1ccc2c(c1)oc1cc(-n3c4ccccc4c4cc(-c5ccc6c(c5)c5ccccc5n6-c5ccc6c7cccc8c9ccccc9n(c6c5)c87)ccc43)ccc12 ; c1ccc2c(c1)oc1c(-n3c4ccccc4c4cc(-c5ccc6c(c5)c5ccccc5n6-c5ccc6c7cccc8c9ccccc9n(c6c5)c87)ccc43)cccc12 ; c1ccc2c(c1)sc1ccc(-n3c4ccccc4c4cc(-c5ccc6c(c5)c5ccccc5n6-c5ccc6c7cccc8c9ccccc9n(c6c5)c87)ccc43)cc12]

14. The organic EL device as claimed in claim 6, wherein the compound represented by Formula 1 includes one or more compounds represented in the following Formula 7, Formula 8, Formula 9, and Formula 10:

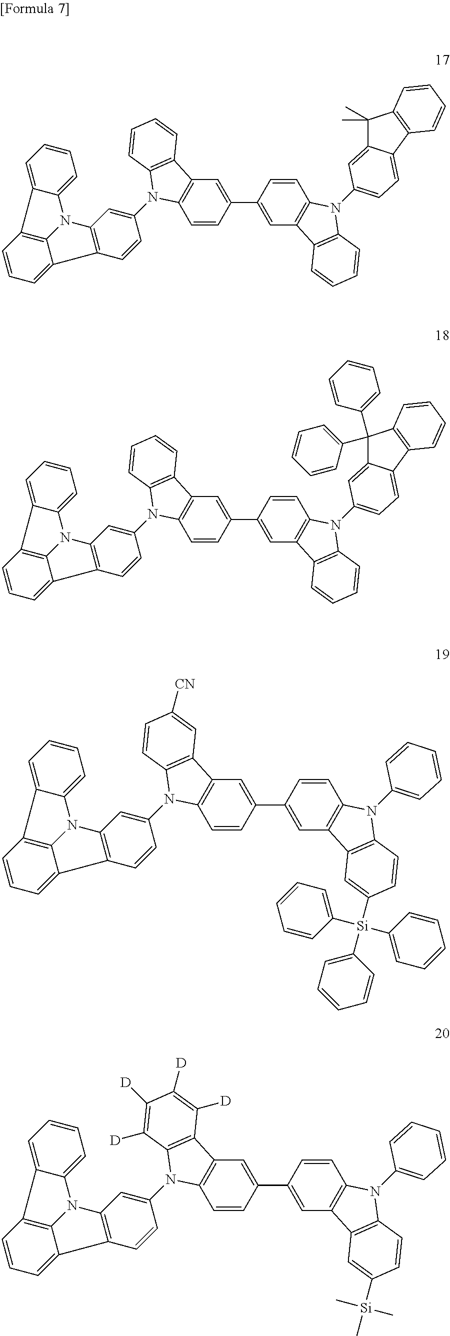 [SMILES: CC1(C)c2ccccc2-c2ccc(-n3c4ccccc4c4cc(-c5ccc6c(c5)c5ccccc5n6-c5ccc6c7cccc8c9ccccc9n(c6c5)c87)ccc43)cc21 ; c1ccc(C2(c3ccccc3)c3ccccc3-c3ccc(-n4c5ccccc5c5cc(-c6ccc7c(c6)c6ccccc6n7-c6ccc7c8cccc9c%10ccccc%10n(c7c6)c98)ccc54)cc32)cc1 ; N#Cc1ccc2c(c1)c1cc(-c3ccc4c(c3)c3cc([Si](c5ccccc5)(c5ccccc5)c5ccccc5)ccc3n4-c3ccccc3)ccc1n2-c1ccc2c3cccc4c5ccccc5n(c2c1)c43 ; [2H]c1c([2H])c([2H])c2c(c1[2H])c1cc(-c3ccc4c(c3)c3cc([Si](C)(C)C)ccc3n4-c3ccccc3)ccc1n2-c1ccc2c3cccc4c5ccccc5n(c2c1)c43]

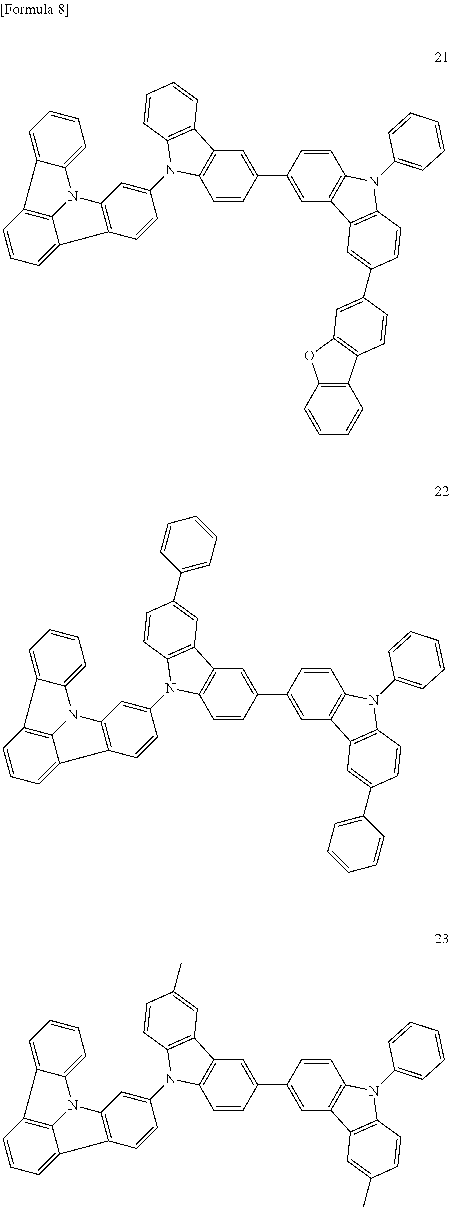 [SMILES: c1ccc(-n2c3ccc(-c4ccc5c(c4)oc4ccccc45)cc3c3cc(-c4ccc5c(c4)c4ccccc4n5-c4ccc5c6cccc7c8ccccc8n(c5c4)c76)ccc32)cc1 ; c1ccc(-c2ccc3c(c2)c2cc(-c4ccc5c(c4)c4cc(-c6ccccc6)ccc4n5-c4ccc5c6cccc7c8ccccc8n(c5c4)c76)ccc2n3-c2ccccc2)cc1 ; Cc1ccc2c(c1)c1cc(-c3ccc4c(c3)c3cc(C)ccc3n4-c3ccc4c5cccc6c7ccccc7n(c4c3)c65)ccc1n2-c1ccccc1]

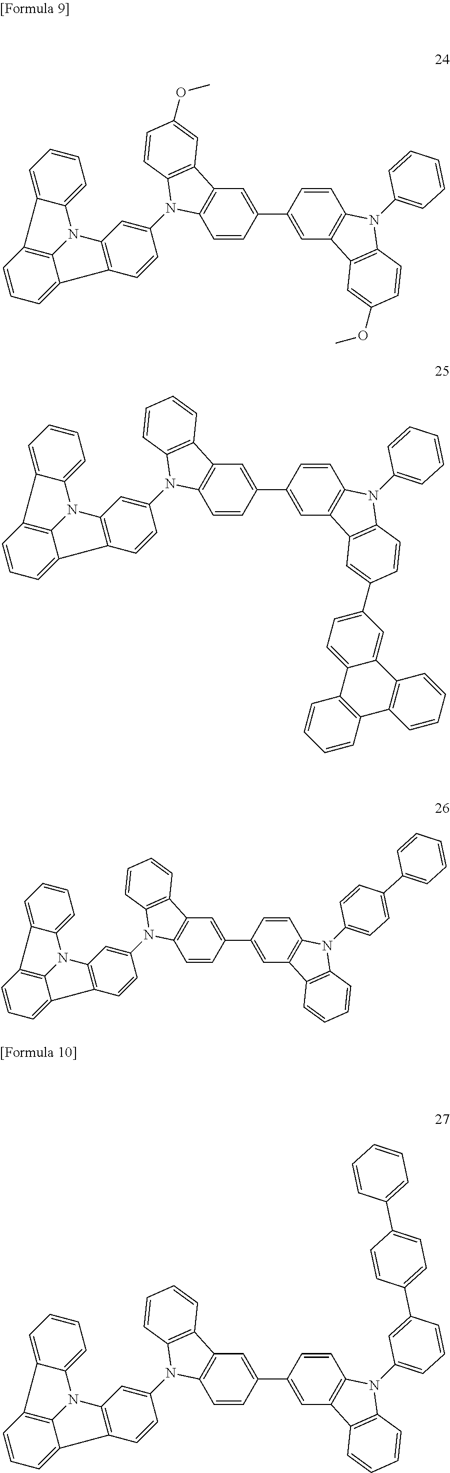 [SMILES: COc1ccc2c(c1)c1cc(-c3ccc4c(c3)c3cc(OC)ccc3n4-c3ccc4c5cccc6c7ccccc7n(c4c3)c65)ccc1n2-c1ccccc1 ; c1ccc(-n2c3ccc(-c4ccc5c6ccccc6c6ccccc6c5c4)cc3c3cc(-c4ccc5c(c4)c4ccccc4n5-c4ccc5c6cccc7c8ccccc8n(c5c4)c76)ccc32)cc1 ; c1ccc(-c2ccc(-n3c4ccccc4c4cc(-c5ccc6c(c5)c5ccccc5n6-c5ccc6c7cccc8c9ccccc9n(c6c5)c87)ccc43)cc2)cc1 ; c1ccc(-c2ccc(-c3cccc(-n4c5ccccc5c5cc(-c6ccc7c(c6)c6ccccc6n7-c6ccc7c8cccc9c%10ccccc%10n(c7c6)c98)ccc54)c3)cc2)cc1]

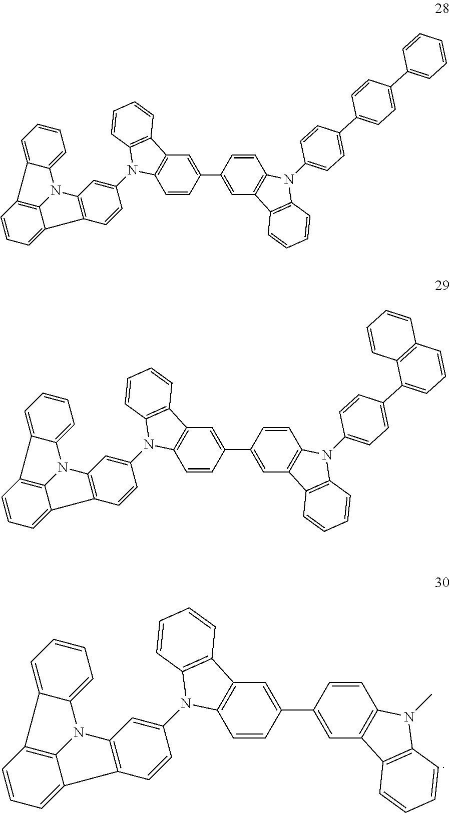 [SMILES: c1ccc(-c2ccc(-c3ccc(-n4c5ccccc5c5cc(-c6ccc7c(c6)c6ccccc6n7-c6ccc7c8cccc9c%10ccccc%10n(c7c6)c98)ccc54)cc3)cc2)cc1 ; c1ccc2c(-c3ccc(-n4c5ccccc5c5cc(-c6ccc7c(c6)c6ccccc6n7-c6ccc7c8cccc9c%10ccccc%10n(c7c6)c98)ccc54)cc3)cccc2c1 ; Cn1c2ccccc2c2cc(-c3ccc4c(c3)c3ccccc3n4-c3ccc4c5cccc6c7ccccc7n(c4c3)c65)ccc21]

15. The organic EL device as claimed in claim 6, wherein the compound represented by Formula 1 includes one or more compounds represented in the following Formula 11, Formula 12, Formula 13, and Formula 14:

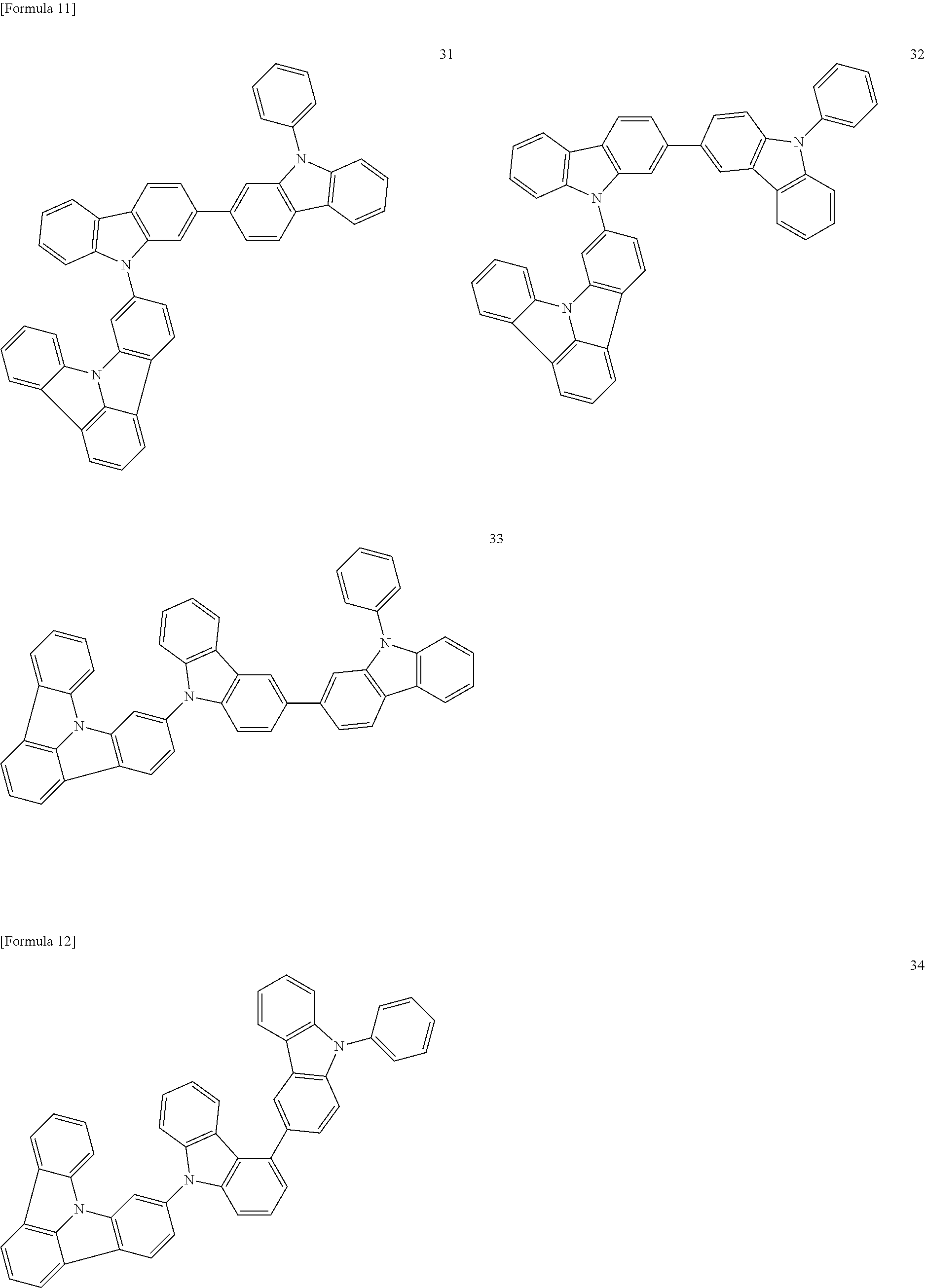 [SMILES: c1ccc(-n2c3ccccc3c3ccc(-c4ccc5c6ccccc6n(-c6ccc7c8cccc9c%10ccccc%10n(c7c6)c98)c5c4)cc32)cc1 ; c1ccc(-n2c3ccccc3c3cc(-c4ccc5c6ccccc6n(-c6ccc7c8cccc9c%10ccccc%10n(c7c6)c98)c5c4)ccc32)cc1 ; c1ccc(-n2c3ccccc3c3ccc(-c4ccc5c(c4)c4ccccc4n5-c4ccc5c6cccc7c8ccccc8n(c5c4)c76)cc32)cc1 ; c1ccc(-n2c3ccccc3c3cc(-c4cccc5c4c4ccccc4n5-c4ccc5c6cccc7c8ccccc8n(c5c4)c76)ccc32)cc1]

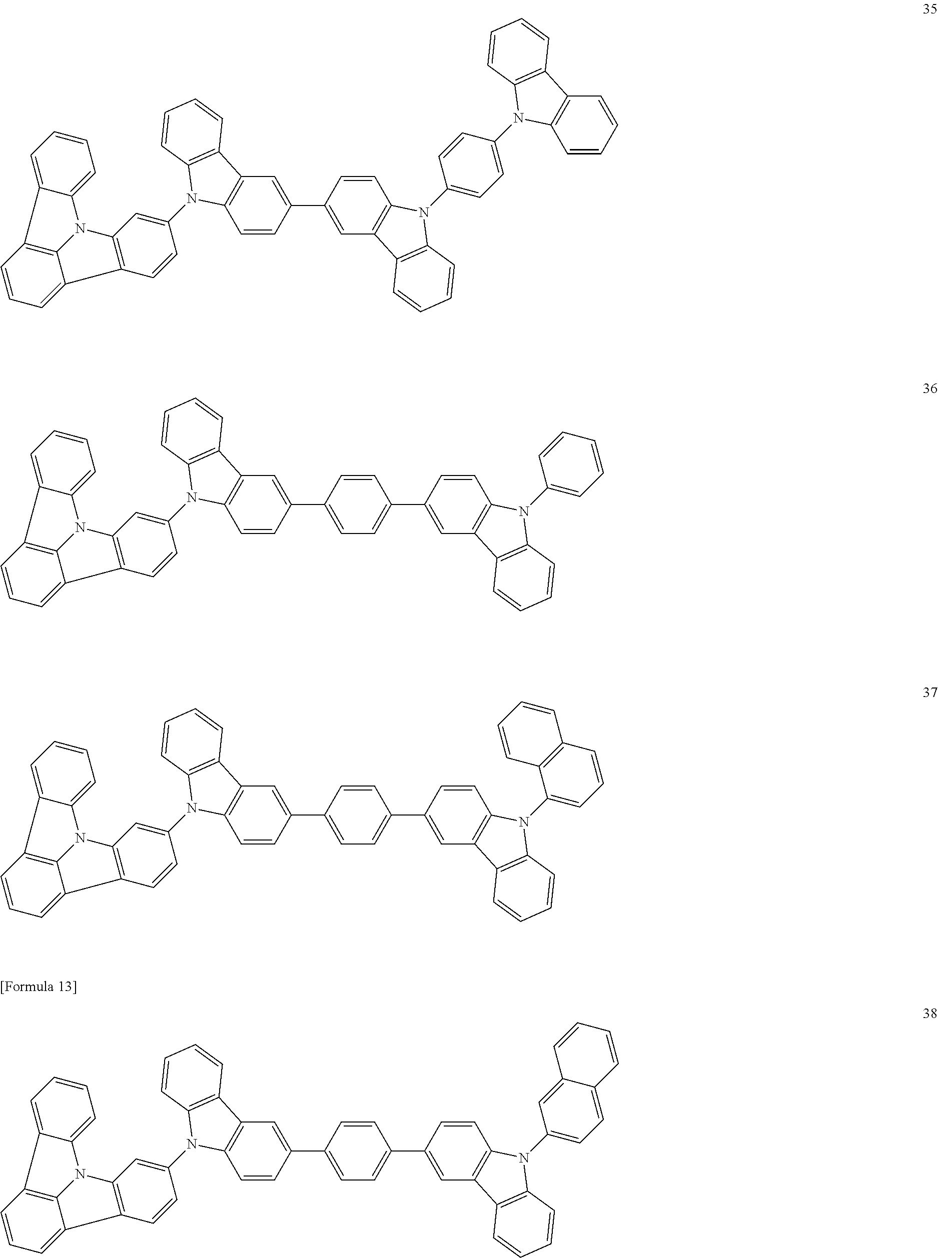 [SMILES: c1ccc2c(c1)c1ccccc1n2-c1ccc(-n2c3ccccc3c3cc(-c4ccc5c(c4)c4ccccc4n5-c4ccc5c6cccc7c8ccccc8n(c5c4)c76)ccc32)cc1 ; c1ccc(-n2c3ccccc3c3cc(-c4ccc(-c5ccc6c(c5)c5ccccc5n6-c5ccc6c7cccc8c9ccccc9n(c6c5)c87)cc4)ccc32)cc1 ; c1ccc2c(-n3c4ccccc4c4cc(-c5ccc(-c6ccc7c(c6)c6ccccc6n7-c6ccc7c8cccc9c%10ccccc%10n(c7c6)c98)cc5)ccc43)cccc2c1 ; c1ccc2cc(-n3c4ccccc4c4cc(-c5ccc(-c6ccc7c(c6)c6ccccc6n7-c6ccc7c8cccc9c%10ccccc%10n(c7c6)c98)cc5)ccc43)ccc2c1]

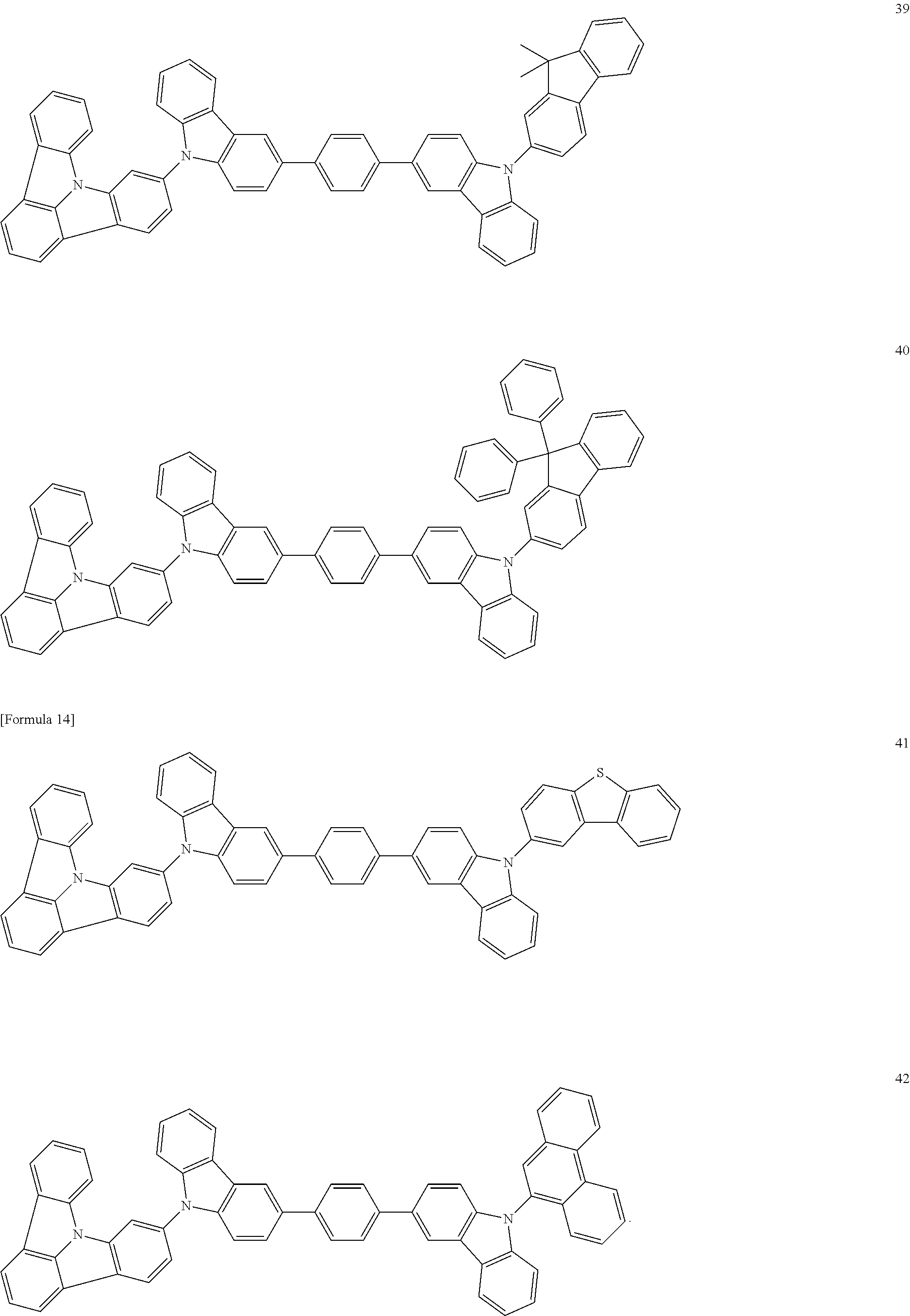 [SMILES: CC1(C)c2ccccc2-c2ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc21 ; c1ccc(C2(c3ccccc3)c3ccccc3-c3ccc(-n4c5ccccc5c5cc(-c6ccc(-c7ccc8c(c7)c7ccccc7n8-c7ccc8c9cccc%10c%11ccccc%11n(c8c7)c%109)cc6)ccc54)cc32)cc1 ; c1ccc2c(c1)sc1ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc12 ; c1ccc2c(c1)cc(-n1c3ccccc3c3cc(-c4ccc(-c5ccc6c(c5)c5ccccc5n6-c5ccc6c7cccc8c9ccccc9n(c6c5)c87)cc4)ccc31)c1ccccc12]

16. The organic EL device as claimed in claim 6, wherein the compound represented by Formula 1 includes one or more compounds represented in the following Formula 15, Formula 16, Formula 17, and Formula 18:

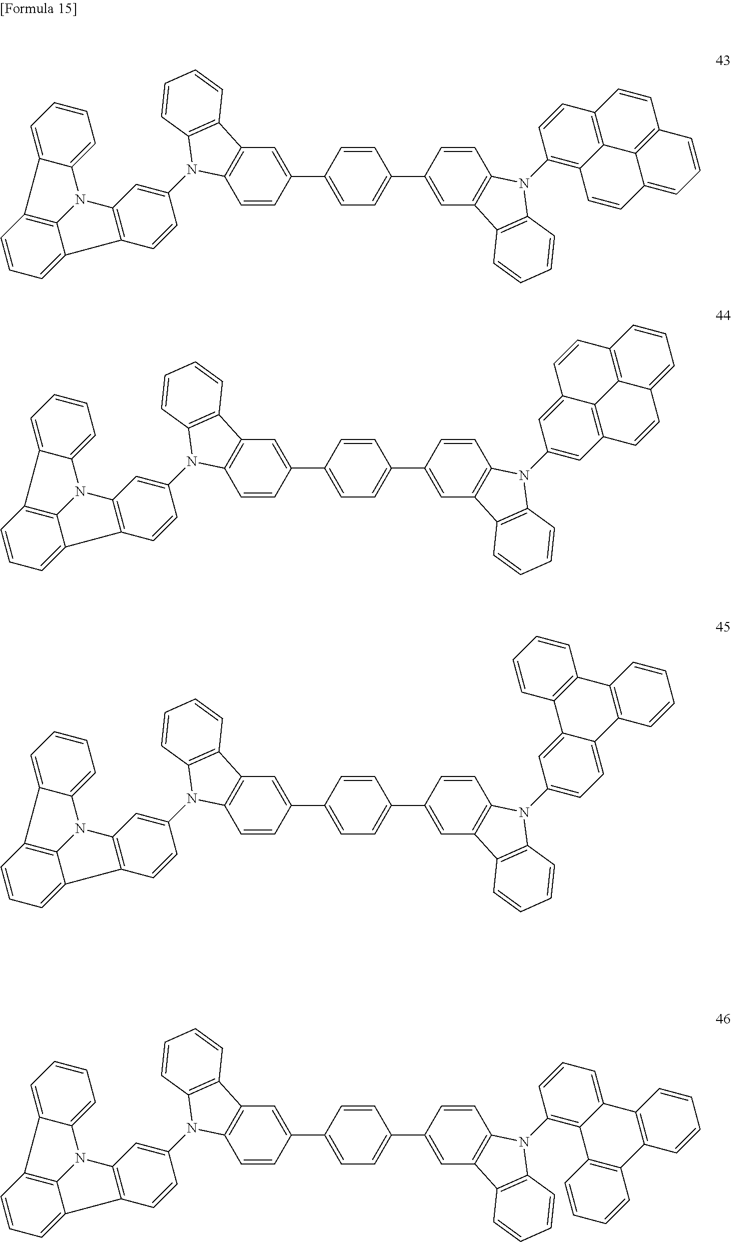 [SMILES: c1cc2ccc3ccc(-n4c5ccccc5c5cc(-c6ccc(-c7ccc8c(c7)c7ccccc7n8-c7ccc8c9cccc%10c%11ccccc%11n(c8c7)c%109)cc6)ccc54)c4ccc(c1)c2c34 ; c1cc2ccc3cc(-n4c5ccccc5c5cc(-c6ccc(-c7ccc8c(c7)c7ccccc7n8-c7ccc8c9cccc%10c%11ccccc%11n(c8c7)c%109)cc6)ccc54)cc4ccc(c1)c2c34 ; c1ccc2c(c1)c1ccccc1c1cc(-n3c4ccccc4c4cc(-c5ccc(-c6ccc7c(c6)c6ccccc6n7-c6ccc7c8cccc9c%10ccccc%10n(c7c6)c98)cc5)ccc43)ccc21 ; c1ccc2c(c1)c1ccccc1c1c(-n3c4ccccc4c4cc(-c5ccc(-c6ccc7c(c6)c6ccccc6n7-c6ccc7c8cccc9c%10ccccc%10n(c7c6)c98)cc5)ccc43)cccc21]

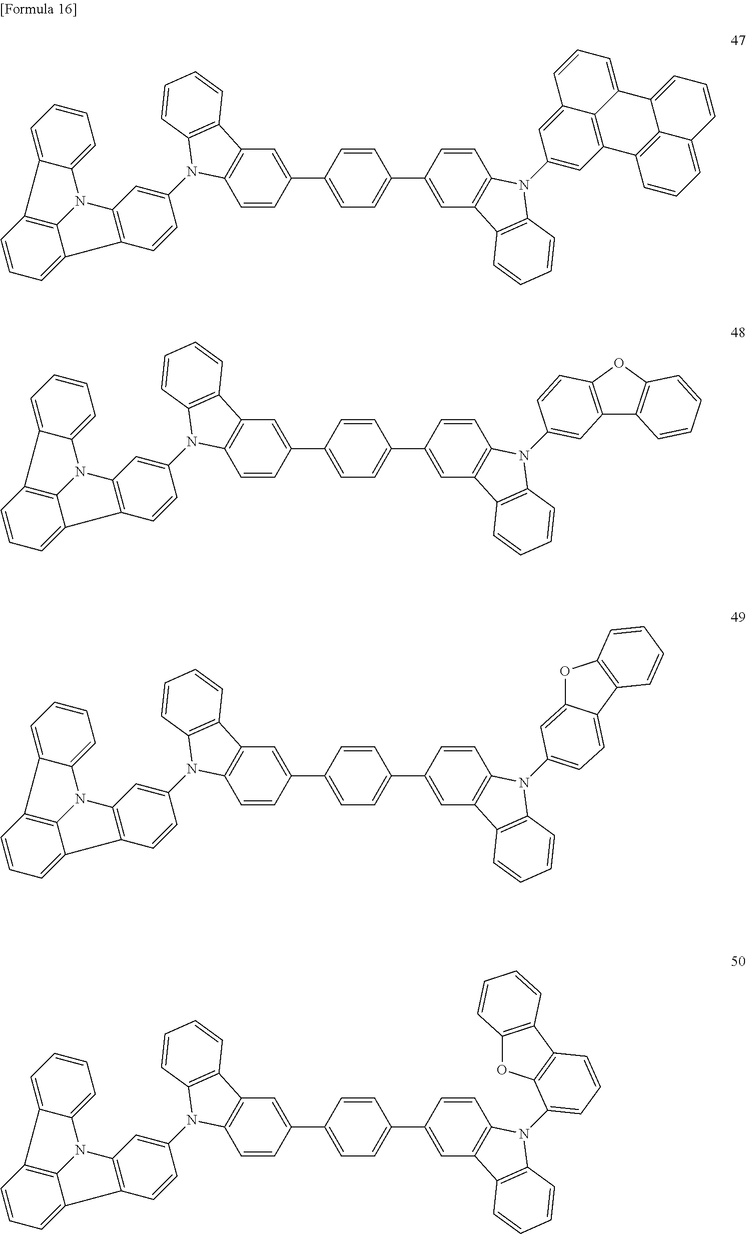 [SMILES: c1cc2cccc3c4cc(-n5c6ccccc6c6cc(-c7ccc(-c8ccc9c(c8)c8ccccc8n9-c8ccc9c%10cccc%11c%12ccccc%12n(c9c8)c%11%10)cc7)ccc65)cc5cccc(c(c1)c23)c54 ; c1ccc2c(c1)oc1ccc(-n3c4ccccc4c4cc(-c5ccc(-c6ccc7c(c6)c6ccccc6n7-c6ccc7c8cccc9c%10ccccc%10n(c7c6)c98)cc5)ccc43)cc12 ; c1ccc2c(c1)oc1cc(-n3c4ccccc4c4cc(-c5ccc(-c6ccc7c(c6)c6ccccc6n7-c6ccc7c8cccc9c%10ccccc%10n(c7c6)c98)cc5)ccc43)ccc12 ; c1ccc2c(c1)oc1c(-n3c4ccccc4c4cc(-c5ccc(-c6ccc7c(c6)c6ccccc6n7-c6ccc7c8cccc9c%10ccccc%10n(c7c6)c98)cc5)ccc43)cccc12]

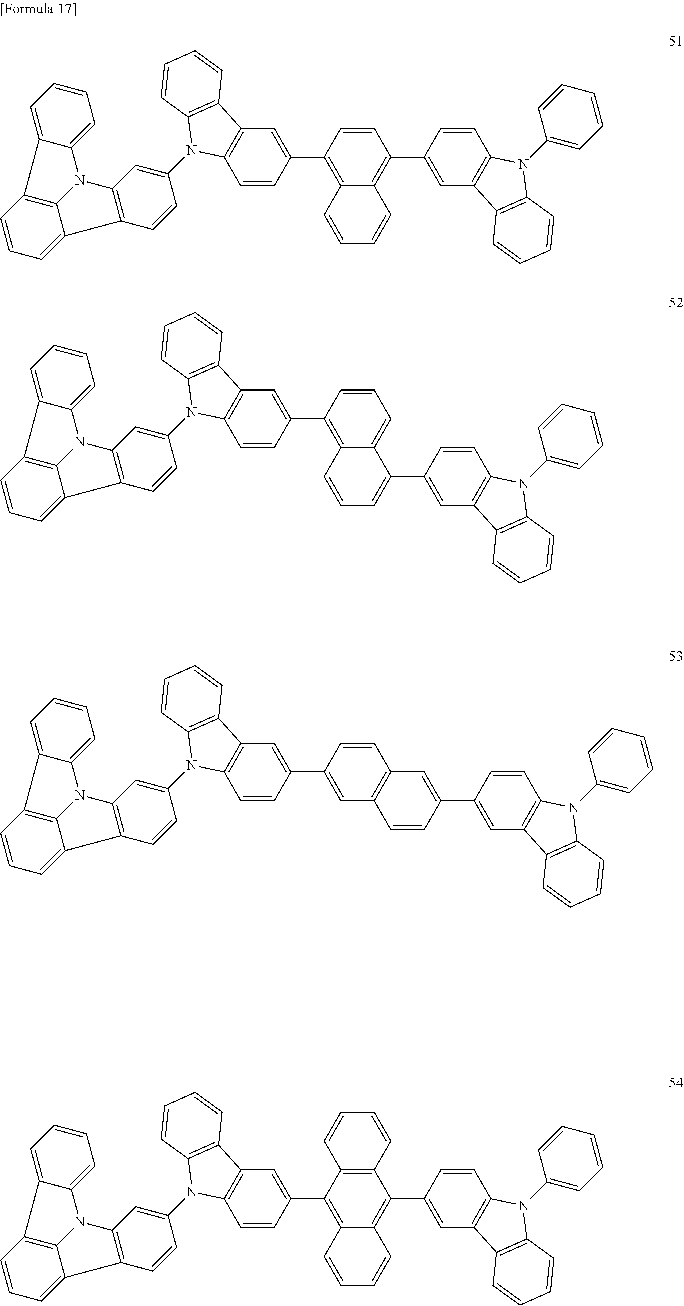 [SMILES: c1ccc(-n2c3ccccc3c3cc(-c4ccc(-c5ccc6c(c5)c5ccccc5n6-c5ccc6c7cccc8c9ccccc9n(c6c5)c87)c5ccccc45)ccc32)cc1 ; c1ccc(-n2c3ccccc3c3cc(-c4cccc5c(-c6ccc7c(c6)c6ccccc6n7-c6ccc7c8cccc9c%10ccccc%10n(c7c6)c98)cccc45)ccc32)cc1 ; c1ccc(-n2c3ccccc3c3cc(-c4ccc5cc(-c6ccc7c(c6)c6ccccc6n7-c6ccc7c8cccc9c%10ccccc%10n(c7c6)c98)ccc5c4)ccc32)cc1 ; c1ccc(-n2c3ccccc3c3cc(-c4c5ccccc5c(-c5ccc6c(c5)c5ccccc5n6-c5ccc6c7cccc8c9ccccc9n(c6c5)c87)c5ccccc45)ccc32)cc1]

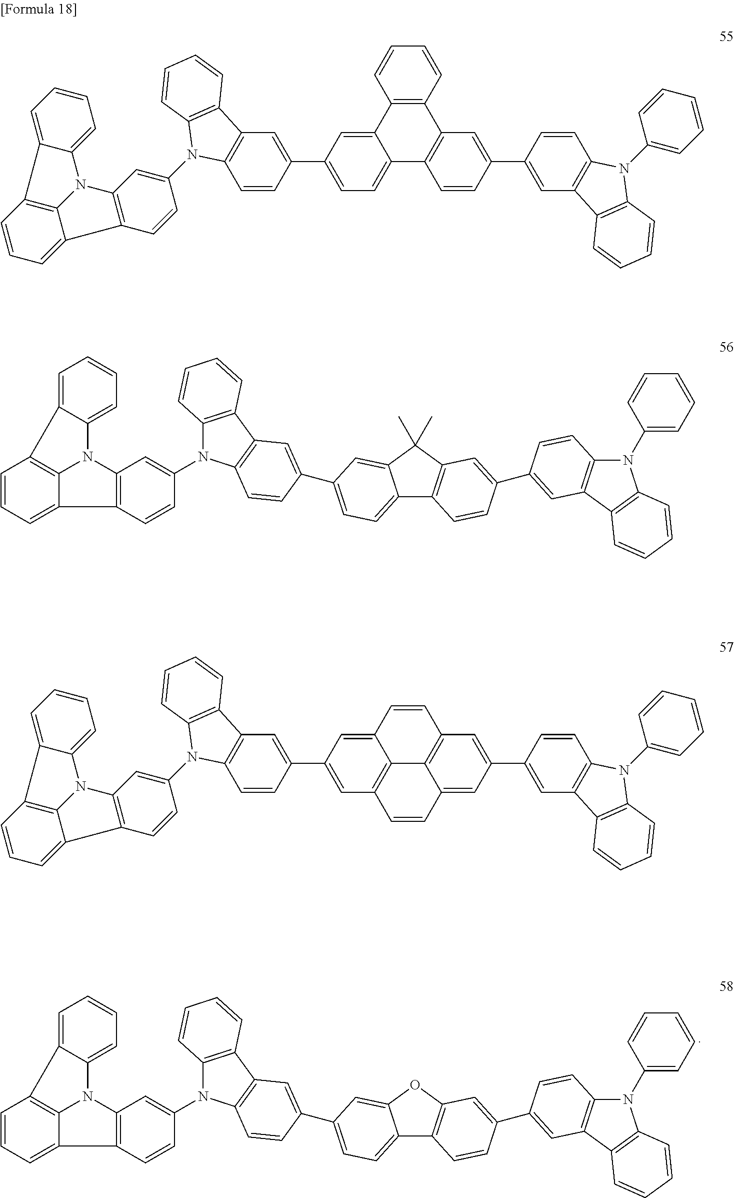 [SMILES: c1ccc(-n2c3ccccc3c3cc(-c4ccc5c6ccc(-c7ccc8c(c7)c7ccccc7n8-c7ccc8c9cccc%10c%11ccccc%11n(c8c7)c%109)cc6c6ccccc6c5c4)ccc32)cc1 ; CC1(C)c2cc(-c3ccc4c(c3)c3ccccc3n4-c3ccccc3)ccc2-c2ccc(-c3ccc4c(c3)c3ccccc3n4-c3ccc4c5cccc6c7ccccc7n(c4c3)c65)cc21 ; c1ccc(-n2c3ccccc3c3cc(-c4cc5ccc6cc(-c7ccc8c(c7)c7ccccc7n8-c7ccc8c9cccc%10c%11ccccc%11n(c8c7)c%109)cc7ccc(c4)c5c67)ccc32)cc1 ; c1ccc(-n2c3ccccc3c3cc(-c4ccc5c(c4)oc4cc(-c6ccc7c(c6)c6ccccc6n7-c6ccc7c8cccc9c%10ccccc%10n(c7c6)c98)ccc45)ccc32)cc1]

17. The organic EL device as claimed in claim 6, wherein the compound represented by Formula 1 includes one or more compounds represented in the following Formula 19, Formula 10, Formula 11, and Formula 12:

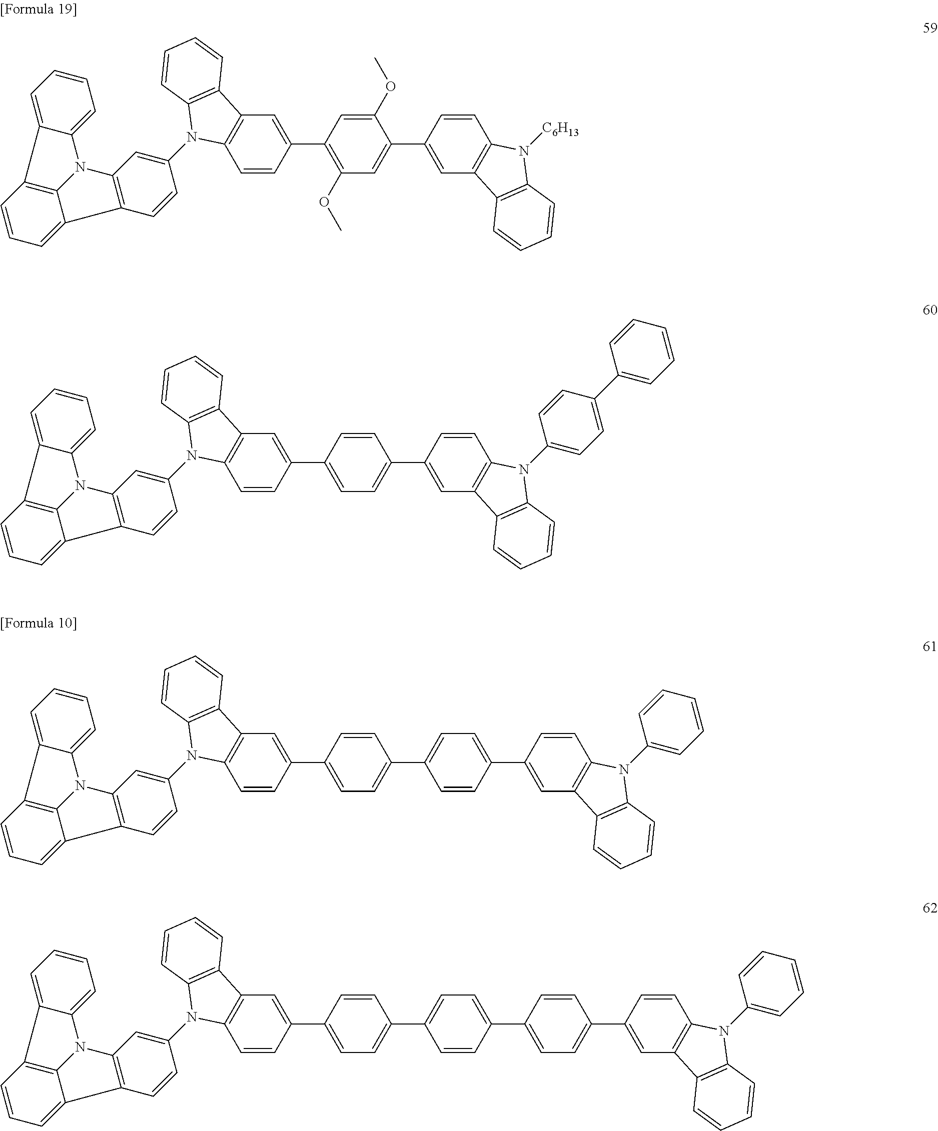

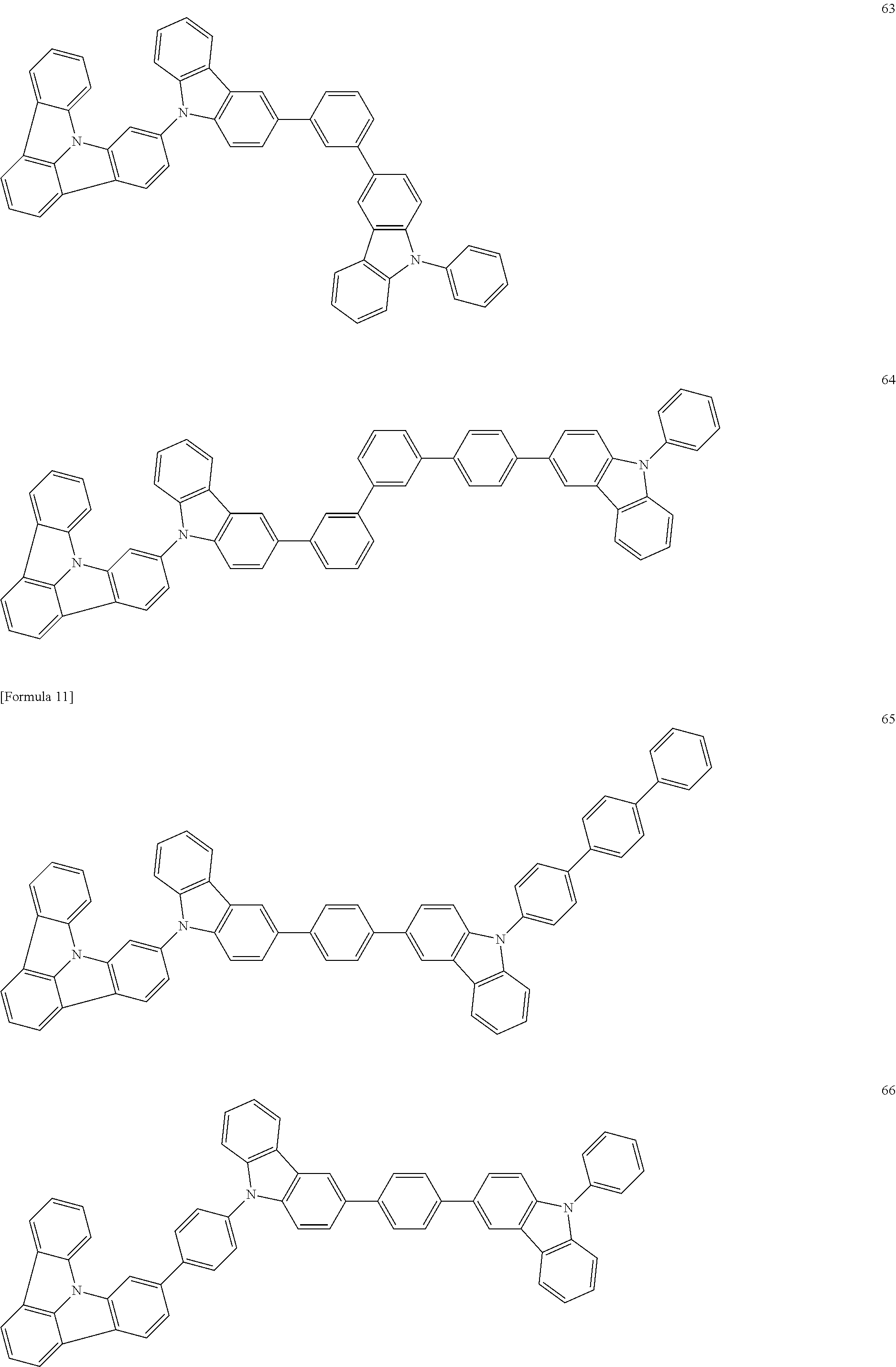 [SMILES: c1ccc(-n2c3ccccc3c3cc(-c4cccc(-c5ccc6c(c5)c5ccccc5n6-c5ccc6c7cccc8c9ccccc9n(c6c5)c87)c4)ccc32)cc1 ; c1ccc(-n2c3ccccc3c3cc(-c4ccc(-c5cccc(-c6cccc(-c7ccc8c(c7)c7ccccc7n8-c7ccc8c9cccc%10c%11ccccc%11n(c8c7)c%109)c6)c5)cc4)ccc32)cc1 ; c1ccc(-c2ccc(-c3ccc(-n4c5ccccc5c5cc(-c6ccc(-c7ccc8c(c7)c7ccccc7n8-c7ccc8c9cccc%10c%11ccccc%11n(c8c7)c%109)cc6)ccc54)cc3)cc2)cc1 ; c1ccc(-n2c3ccccc3c3cc(-c4ccc(-c5ccc6c(c5)c5ccccc5n6-c5ccc(-c6ccc7c8cccc9c%10ccccc%10n(c7c6)c98)cc5)cc4)ccc32)cc1]

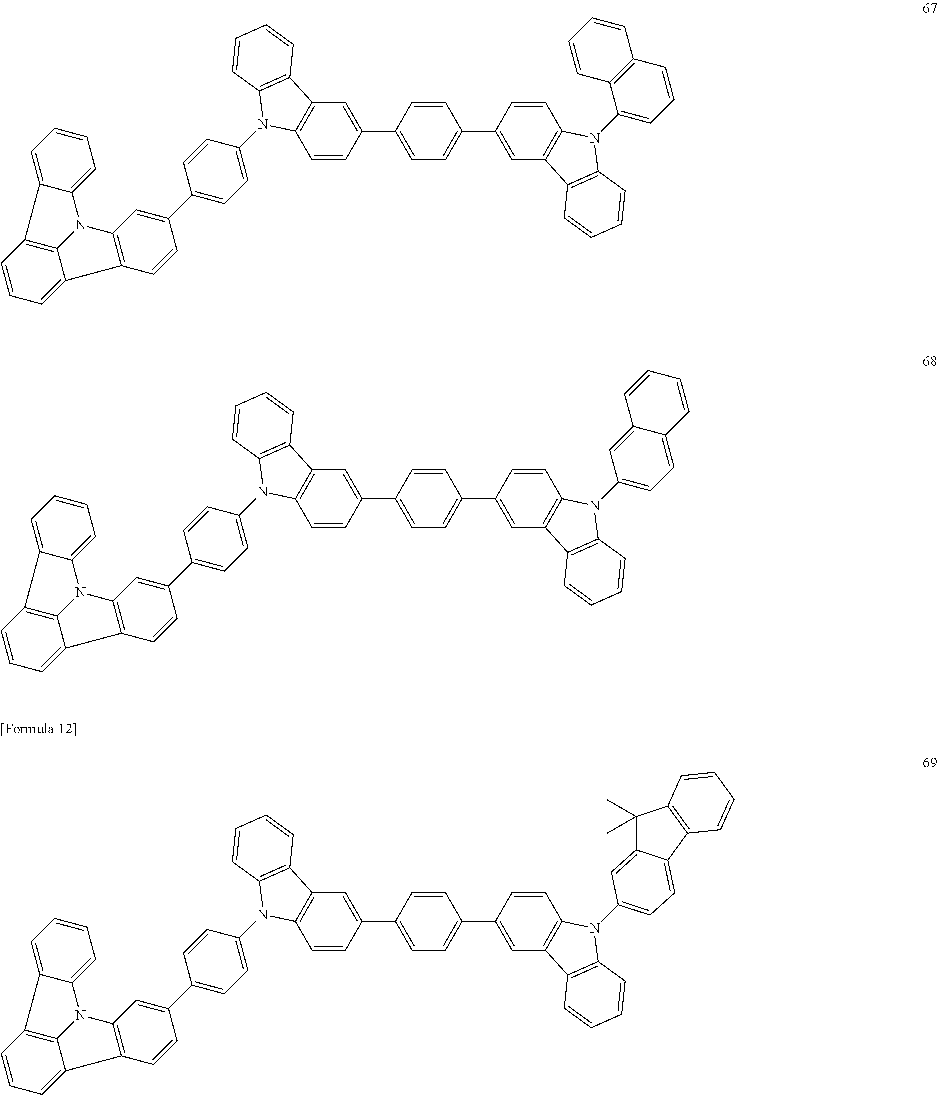 [SMILES: c1ccc2c(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cccc2c1 ; c1ccc2cc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)ccc2c1 ; CC1(C)c2ccccc2-c2ccc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cc21]

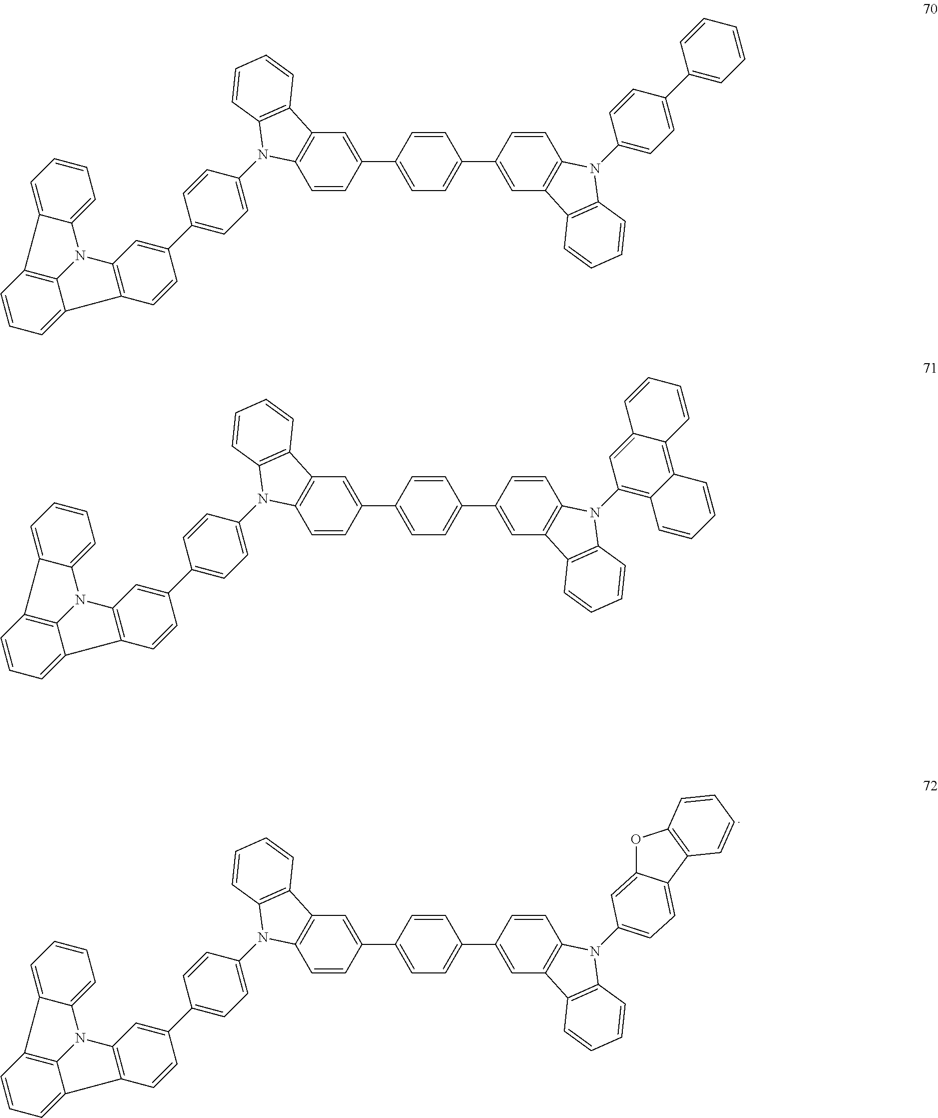 [SMILES: c1ccc(-c2ccc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cc2)cc1 ; c1ccc2c(c1)cc(-n1c3ccccc3c3cc(-c4ccc(-c5ccc6c(c5)c5ccccc5n6-c5ccc(-c6ccc7c8cccc9c%10ccccc%10n(c7c6)c98)cc5)cc4)ccc31)c1ccccc12 ; c1ccc2c(c1)oc1cc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)ccc12]

18. The organic EL device as claimed in claim 6, wherein the compound represented by Formula 1 includes one or more compounds represented in the following Formula 13, Formula 14, Formula 15, and Formula 16:

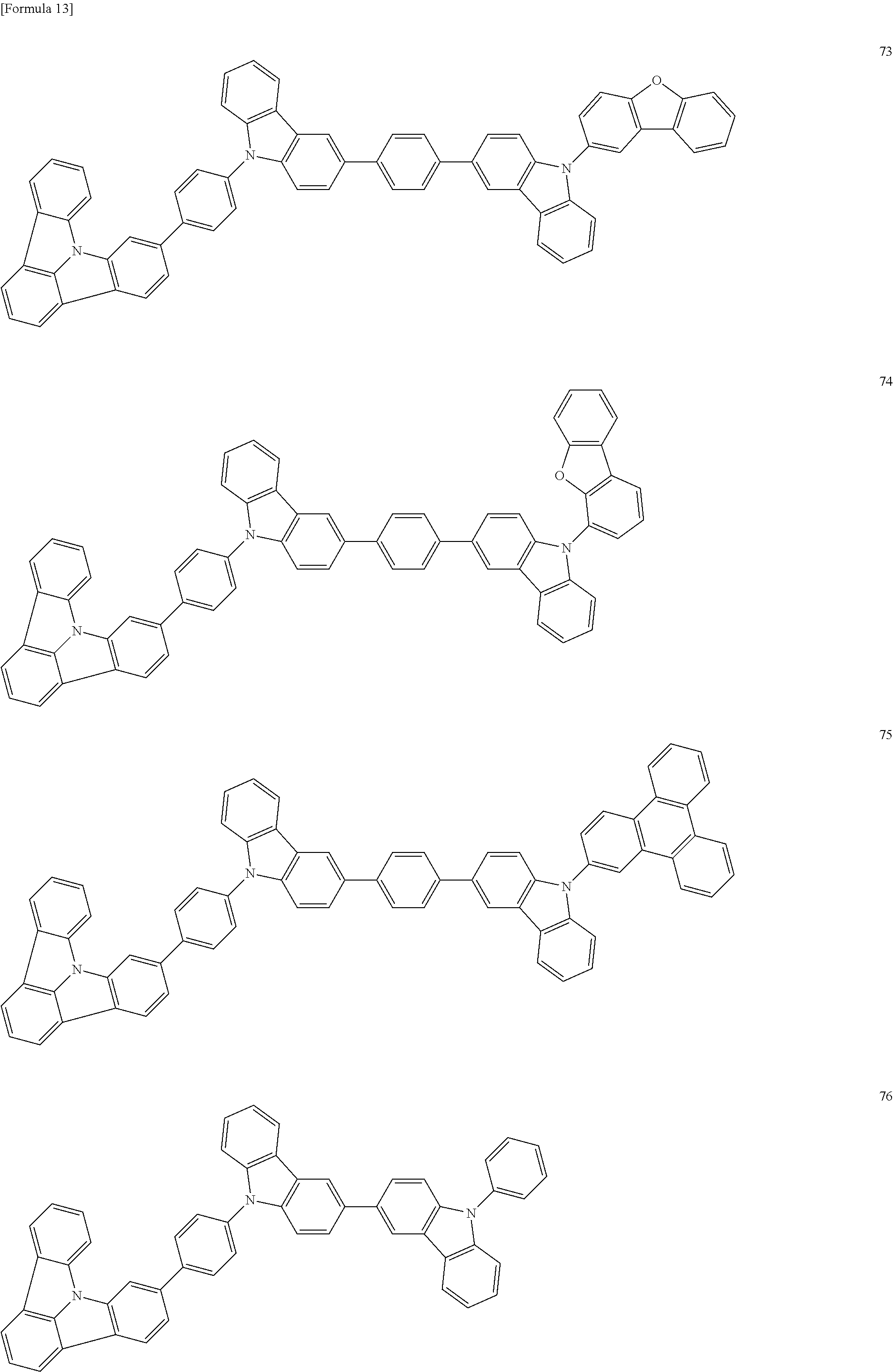 [SMILES: c1ccc2c(c1)oc1ccc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cc12 ; c1ccc2c(c1)oc1c(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)cccc12 ; c1ccc2c(c1)c1ccccc1c1cc(-n3c4ccccc4c4cc(-c5ccc(-c6ccc7c(c6)c6ccccc6n7-c6ccc(-c7ccc8c9cccc%10c%11ccccc%11n(c8c7)c%109)cc6)cc5)ccc43)ccc21 ; c1ccc(-n2c3ccccc3c3cc(-c4ccc5c(c4)c4ccccc4n5-c4ccc(-c5ccc6c7cccc8c9ccccc9n(c6c5)c87)cc4)ccc32)cc1]

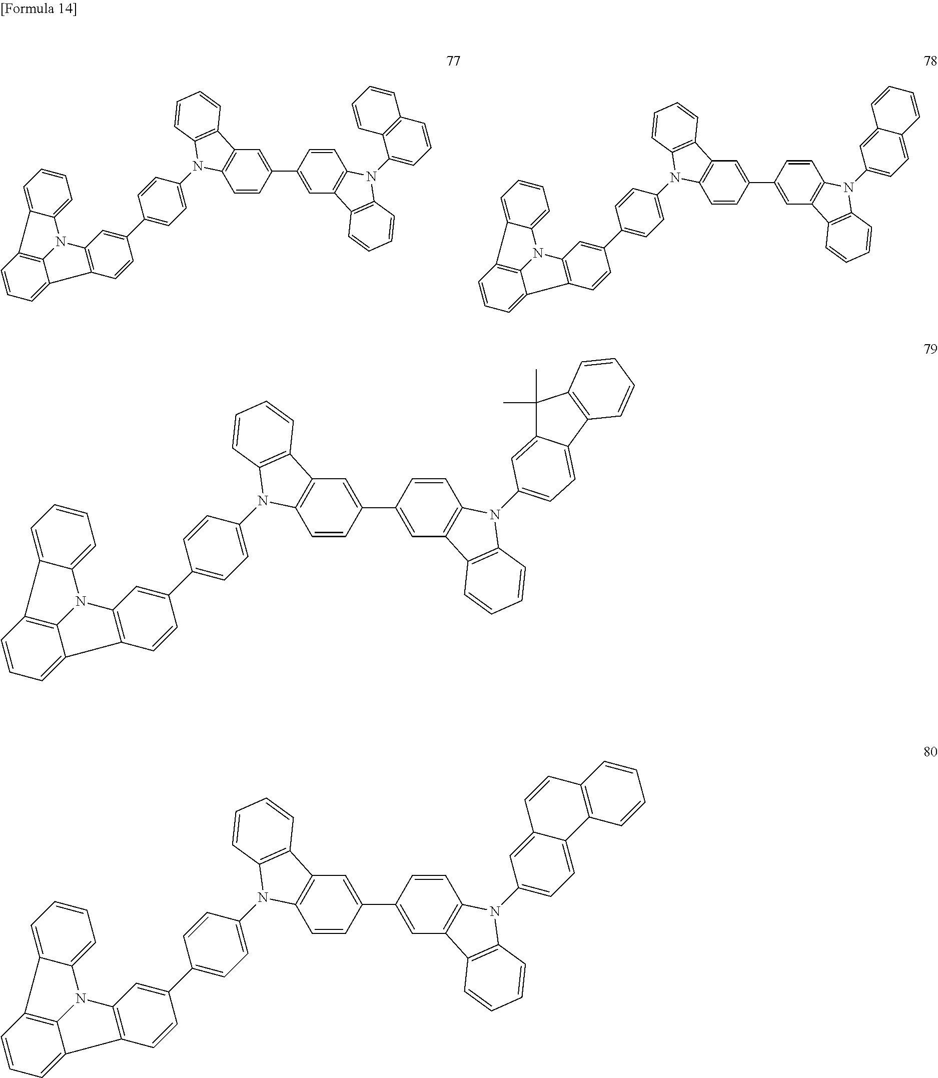 [SMILES: c1ccc2c(-n3c4ccccc4c4cc(-c5ccc6c(c5)c5ccccc5n6-c5ccc(-c6ccc7c8cccc9c%10ccccc%10n(c7c6)c98)cc5)ccc43)cccc2c1 ; c1ccc2cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc2c1 ; CC1(C)c2ccccc2-c2ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc21 ; c1ccc2c(c1)ccc1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc12]

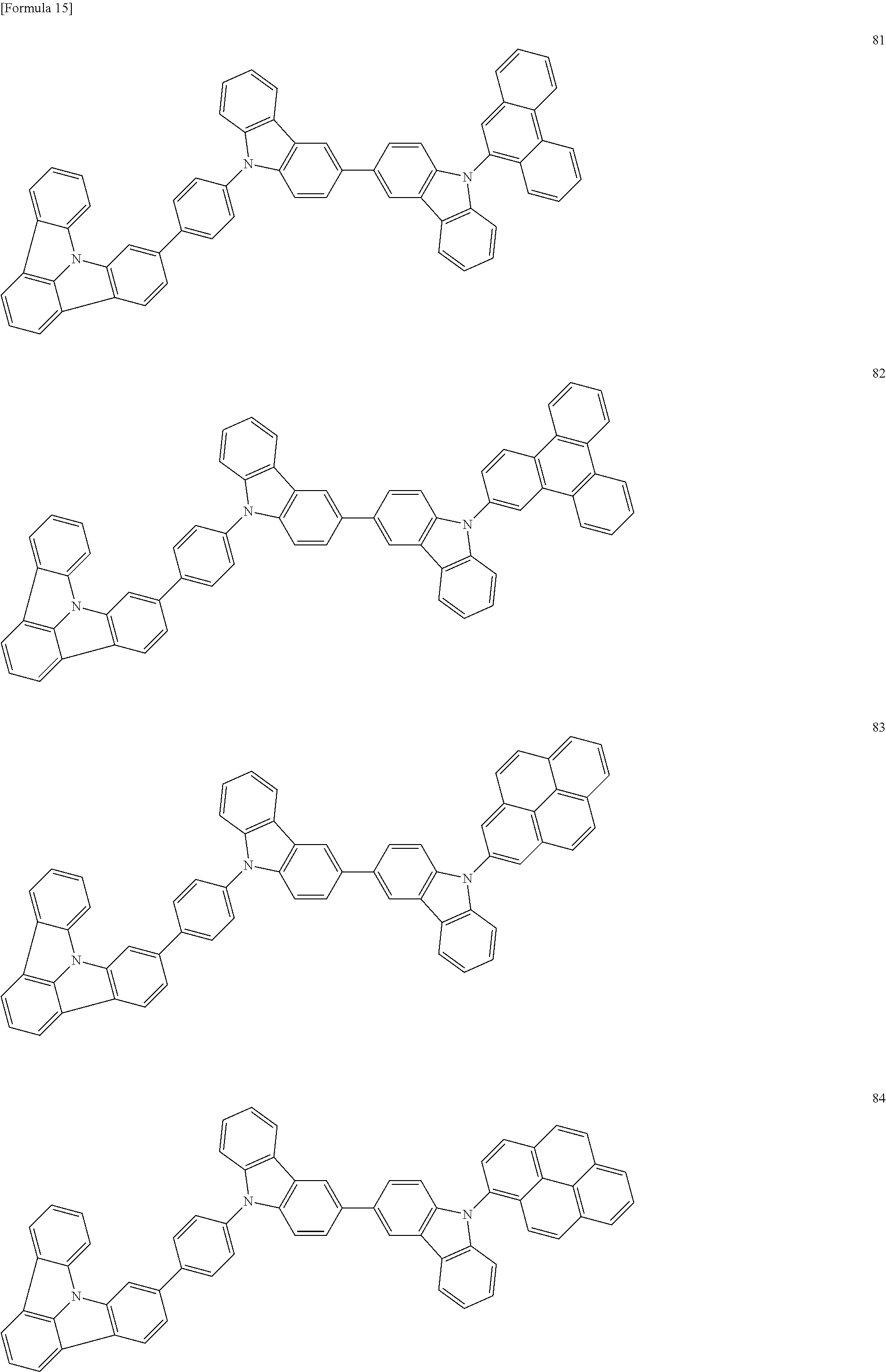 [SMILES: c1ccc2c(c1)cc(-n1c3ccccc3c3cc(-c4ccc5c(c4)c4ccccc4n5-c4ccc(-c5ccc6c7cccc8c9ccccc9n(c6c5)c87)cc4)ccc31)c1ccccc12 ; c1ccc2c(c1)c1ccccc1c1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc21 ; c1cc2ccc3cc(-n4c5ccccc5c5cc(-c6ccc7c(c6)c6ccccc6n7-c6ccc(-c7ccc8c9cccc%10c%11ccccc%11n(c8c7)c%109)cc6)ccc54)cc4ccc(c1)c2c34 ; c1cc2ccc3ccc(-n4c5ccccc5c5cc(-c6ccc7c(c6)c6ccccc6n7-c6ccc(-c7ccc8c9cccc%10c%11ccccc%11n(c8c7)c%109)cc6)ccc54)c4ccc(c1)c2c34]

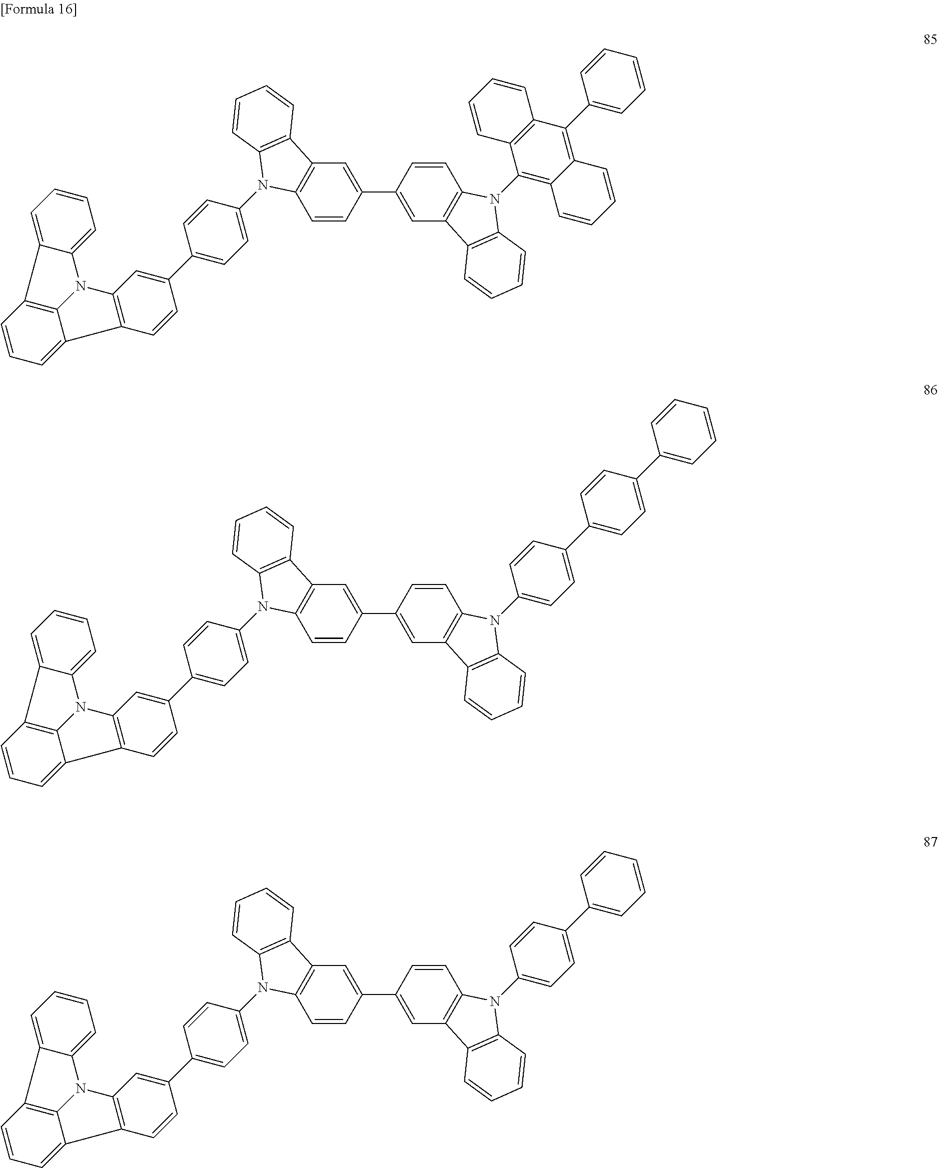 [SMILES: c1ccc(-c2c3ccccc3c(-n3c4ccccc4c4cc(-c5ccc6c(c5)c5ccccc5n6-c5ccc(-c6ccc7c8cccc9c%10ccccc%10n(c7c6)c98)cc5)ccc43)c3ccccc23)cc1 ; c1ccc(-c2ccc(-c3ccc(-n4c5ccccc5c5cc(-c6ccc7c(c6)c6ccccc6n7-c6ccc(-c7ccc8c9cccc%10c%11ccccc%11n(c8c7)c%109)cc6)ccc54)cc3)cc2)cc1 ; c1ccc(-c2ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc2)cc1]

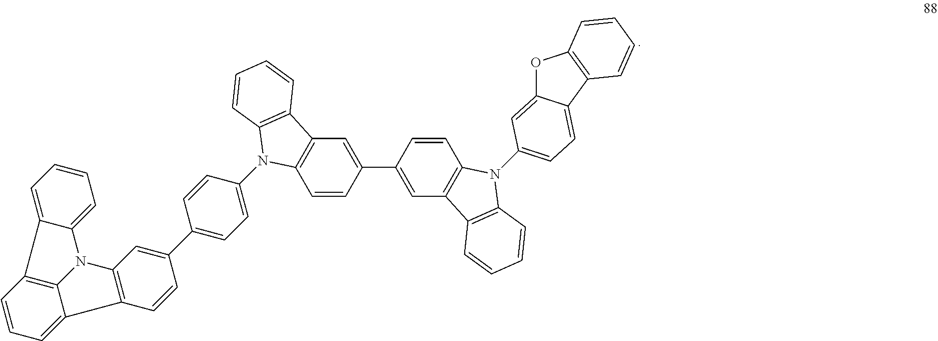 [SMILES: c1ccc2c(c1)oc1cc(-n3c4ccccc4c4cc(-c5ccc6c(c5)c5ccccc5n6-c5ccc(-c6ccc7c8cccc9c%10ccccc%10n(c7c6)c98)cc5)ccc43)ccc12]

19. The organic EL device as claimed in claim 6, wherein the compound represented by Formula 1 includes one or more compounds represented in the following Formula 17, Formula 18, Formula 19, and Formula 30:

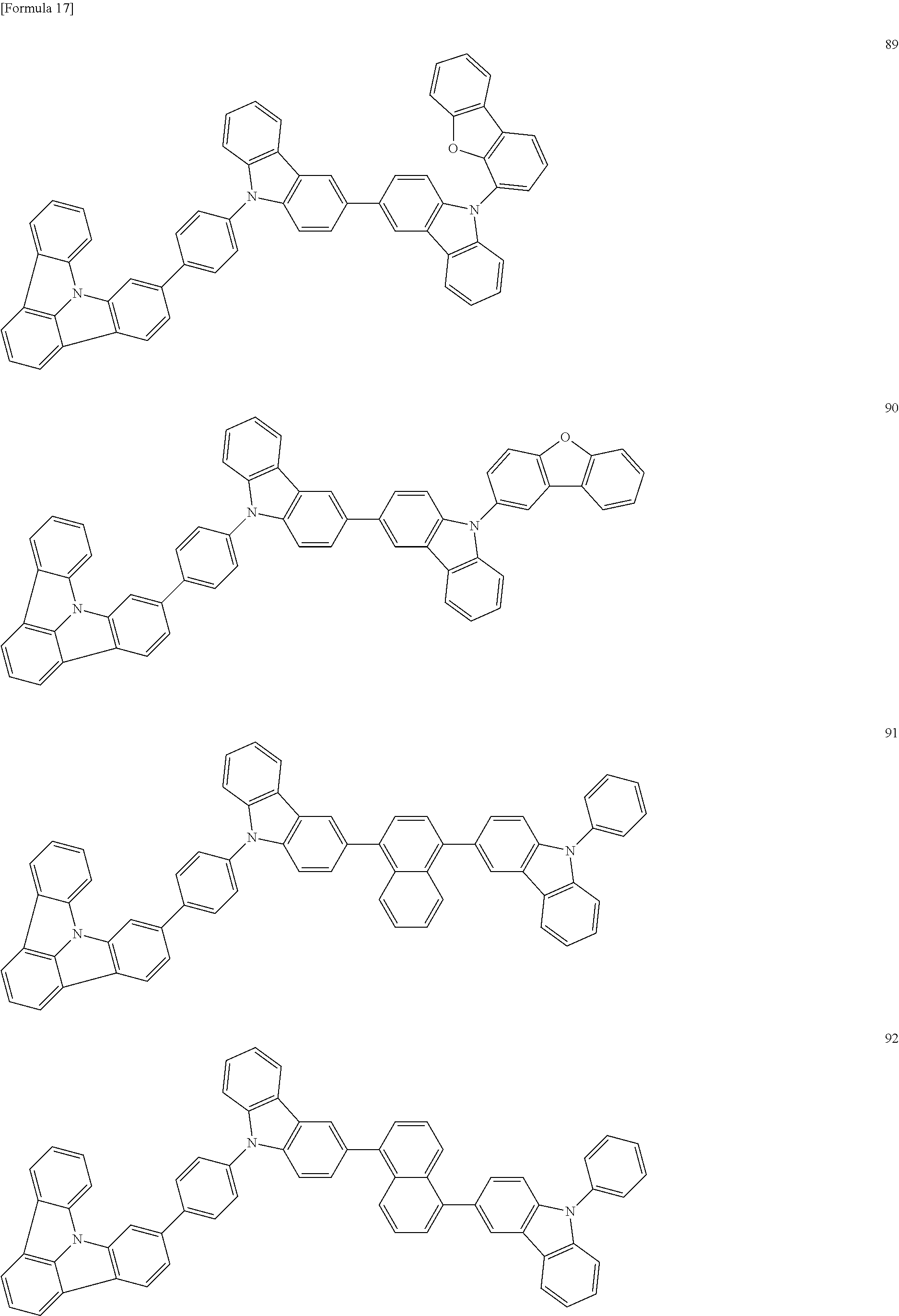 [SMILES: c1ccc2c(c1)oc1c(-n3c4ccccc4c4cc(-c5ccc6c(c5)c5ccccc5n6-c5ccc(-c6ccc7c8cccc9c%10ccccc%10n(c7c6)c98)cc5)ccc43)cccc12 ; c1ccc2c(c1)oc1ccc(-n3c4ccccc4c4cc(-c5ccc6c(c5)c5ccccc5n6-c5ccc(-c6ccc7c8cccc9c%10ccccc%10n(c7c6)c98)cc5)ccc43)cc12 ; c1ccc(-n2c3ccccc3c3cc(-c4ccc(-c5ccc6c(c5)c5ccccc5n6-c5ccc(-c6ccc7c8cccc9c%10ccccc%10n(c7c6)c98)cc5)c5ccccc45)ccc32)cc1 ; c1ccc(-n2c3ccccc3c3cc(-c4cccc5c(-c6ccc7c(c6)c6ccccc6n7-c6ccc(-c7ccc8c9cccc%10c%11ccccc%11n(c8c7)c%109)cc6)cccc45)ccc32)cc1]

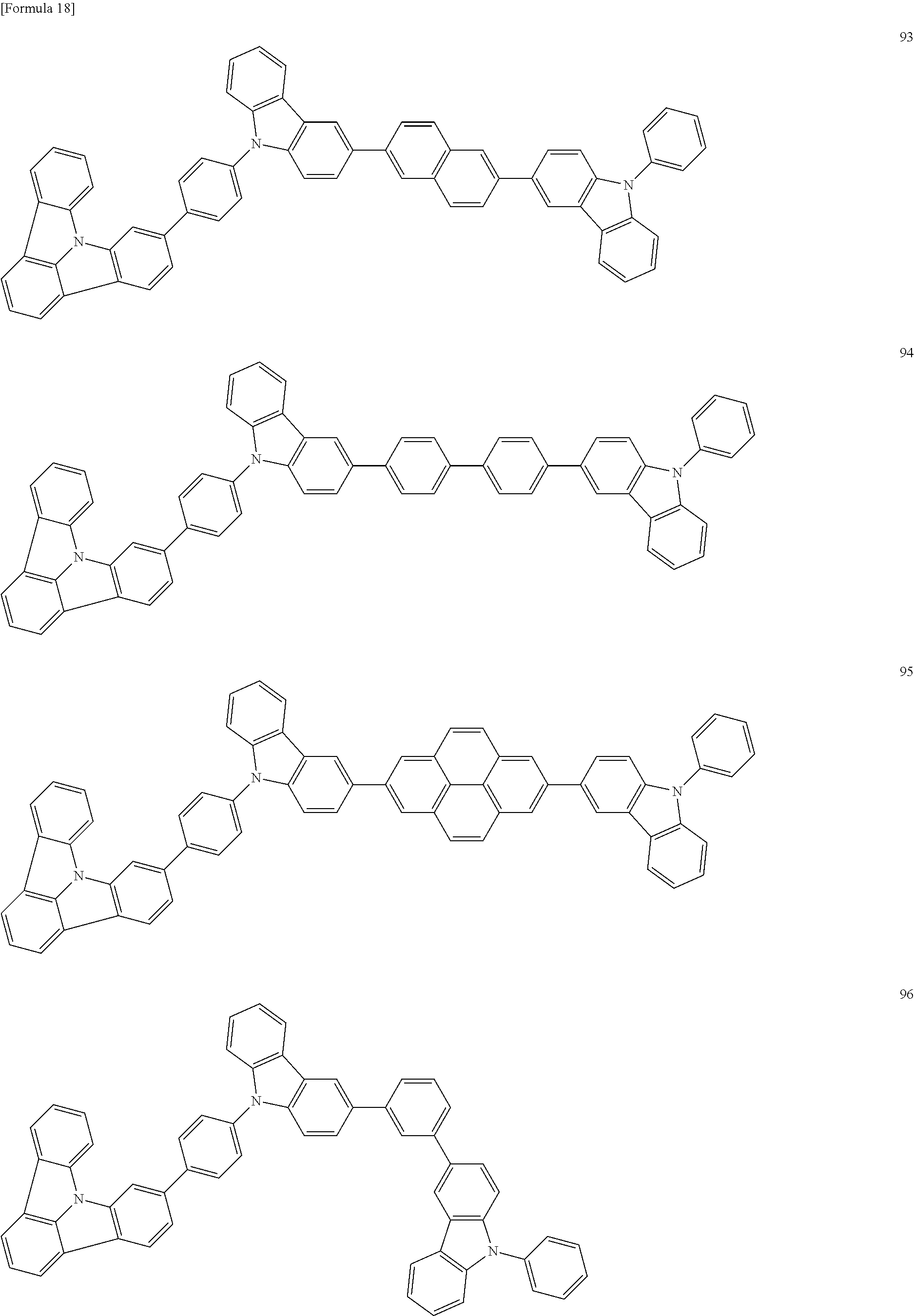

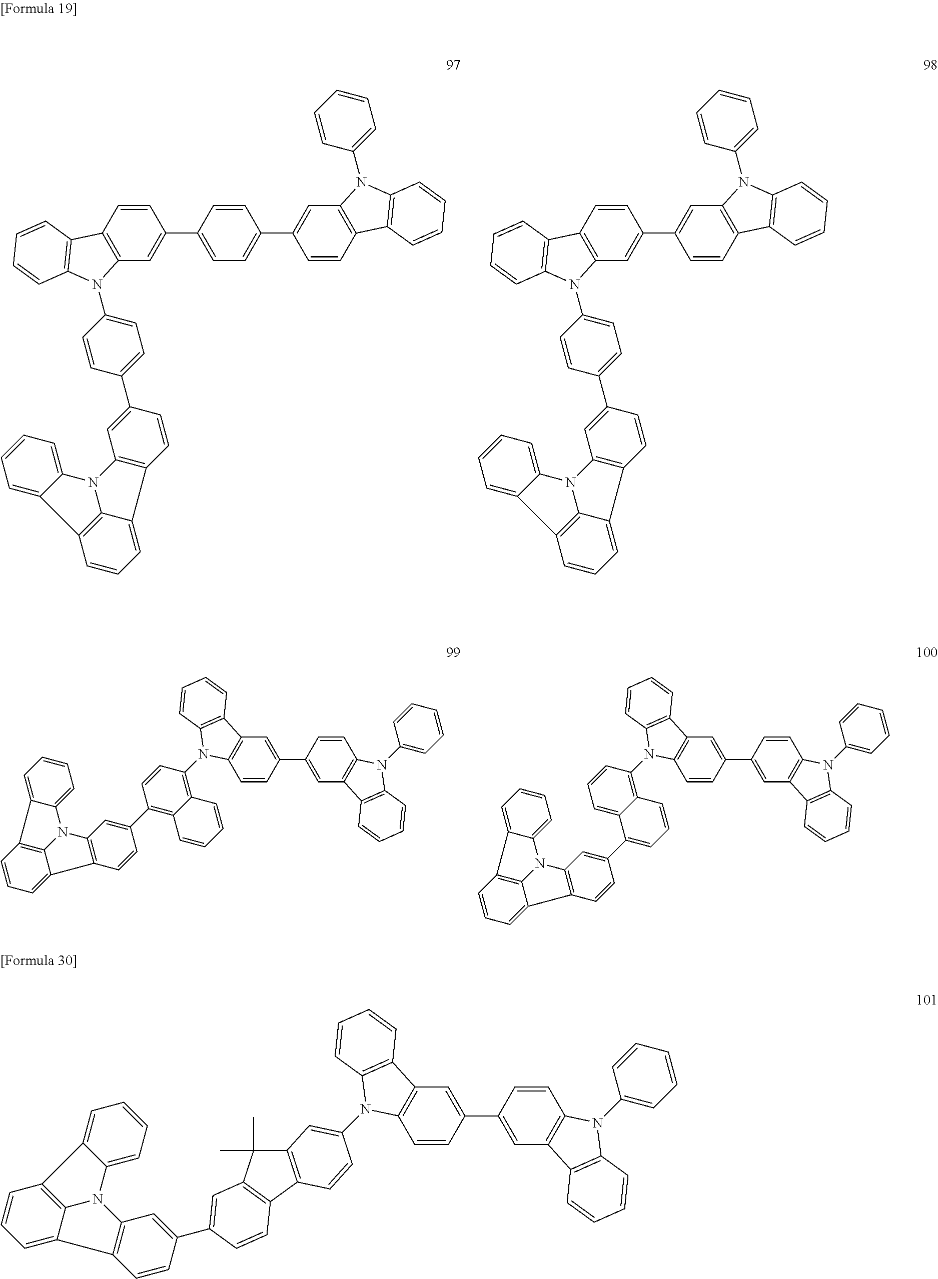

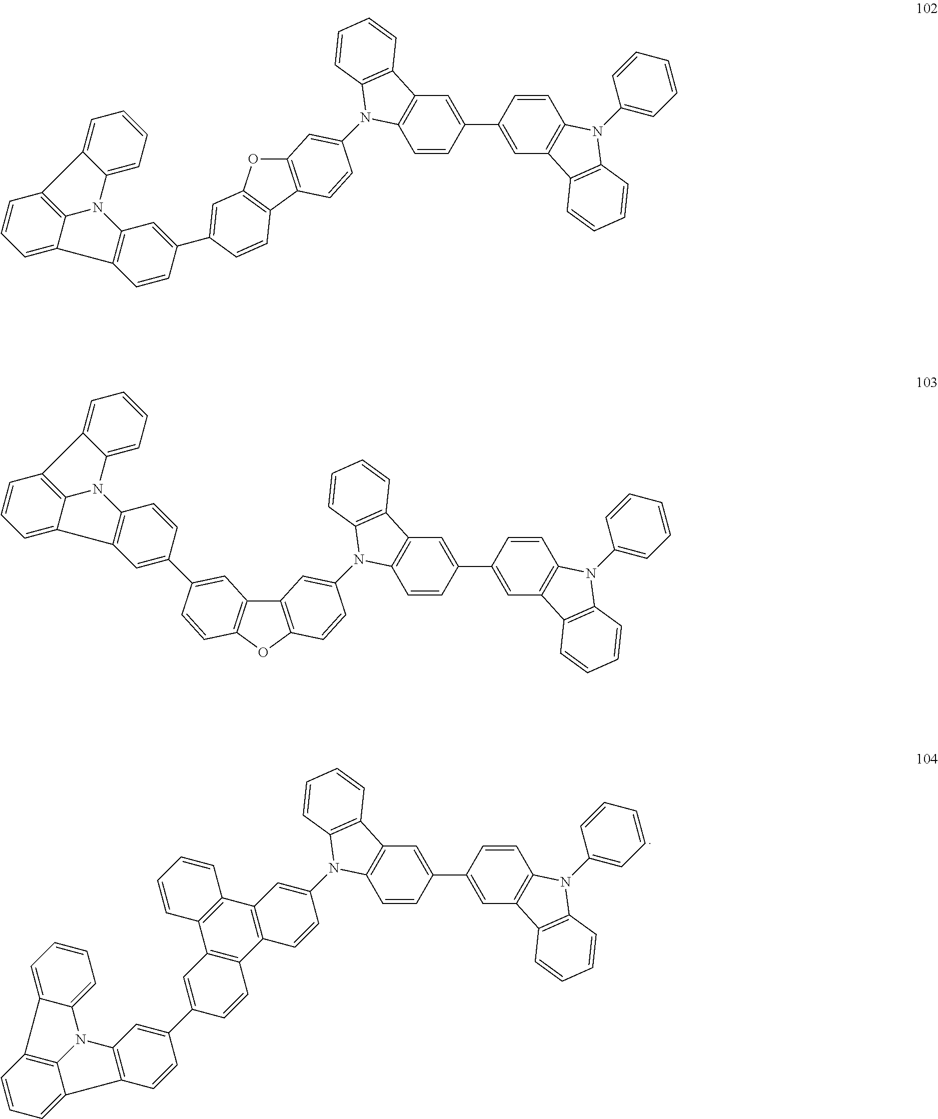 [SMILES: c1ccc(-n2c3ccccc3c3cc(-c4ccc5c(c4)c4ccccc4n5-c4ccc5c(c4)oc4cc(-c6ccc7c8cccc9c%10ccccc%10n(c7c6)c98)ccc45)ccc32)cc1 ; c1ccc(-n2c3ccccc3c3cc(-c4ccc5c(c4)c4ccccc4n5-c4ccc5oc6ccc(-c7ccc8c(c7)c7cccc9c%10ccccc%10n8c97)cc6c5c4)ccc32)cc1 ; c1ccc(-n2c3ccccc3c3cc(-c4ccc5c(c4)c4ccccc4n5-c4ccc5c6ccc(-c7ccc8c9cccc%10c%11ccccc%11n(c8c7)c%109)cc6c6ccccc6c5c4)ccc32)cc1]

20. The organic EL device as claimed in claim 6, wherein the compound represented by Formula 1 includes one or more compounds represented in the following Formula 31, Formula 32, Formula 33, Formula 34, and Formula 35: 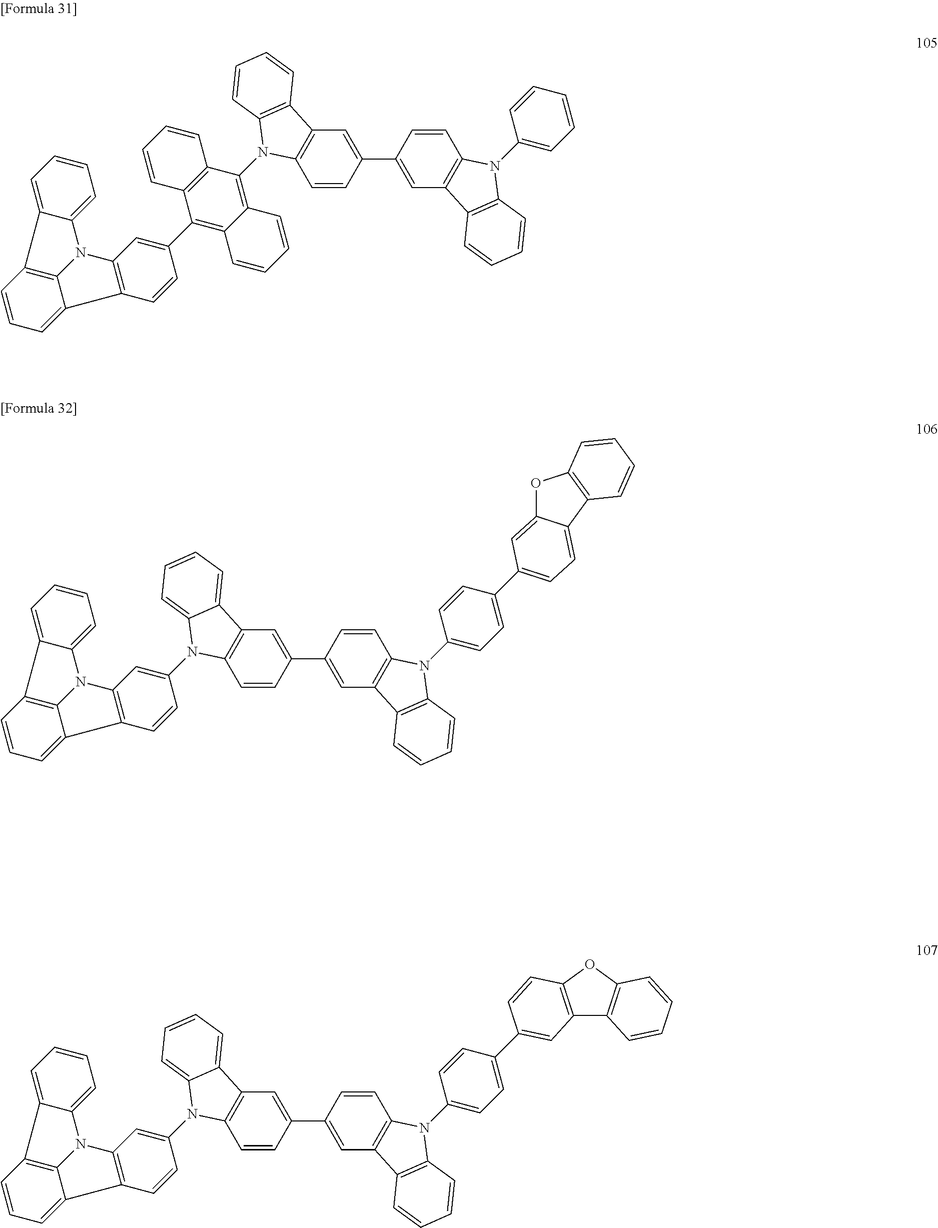 [SMILES: c1ccc(-n2c3ccccc3c3cc(-c4ccc5c(c4)c4ccccc4n5-c4c5ccccc5c(-c5ccc6c7cccc8c9ccccc9n(c6c5)c87)c5ccccc45)ccc32)cc1 ; c1ccc2c(c1)oc1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc12 ; c1ccc2c(c1)oc1ccc(-c3ccc(-n4c5ccccc5c5cc(-c6ccc7c(c6)c6ccccc6n7-c6ccc7c8cccc9c%10ccccc%10n(c7c6)c98)ccc54)cc3)cc12] 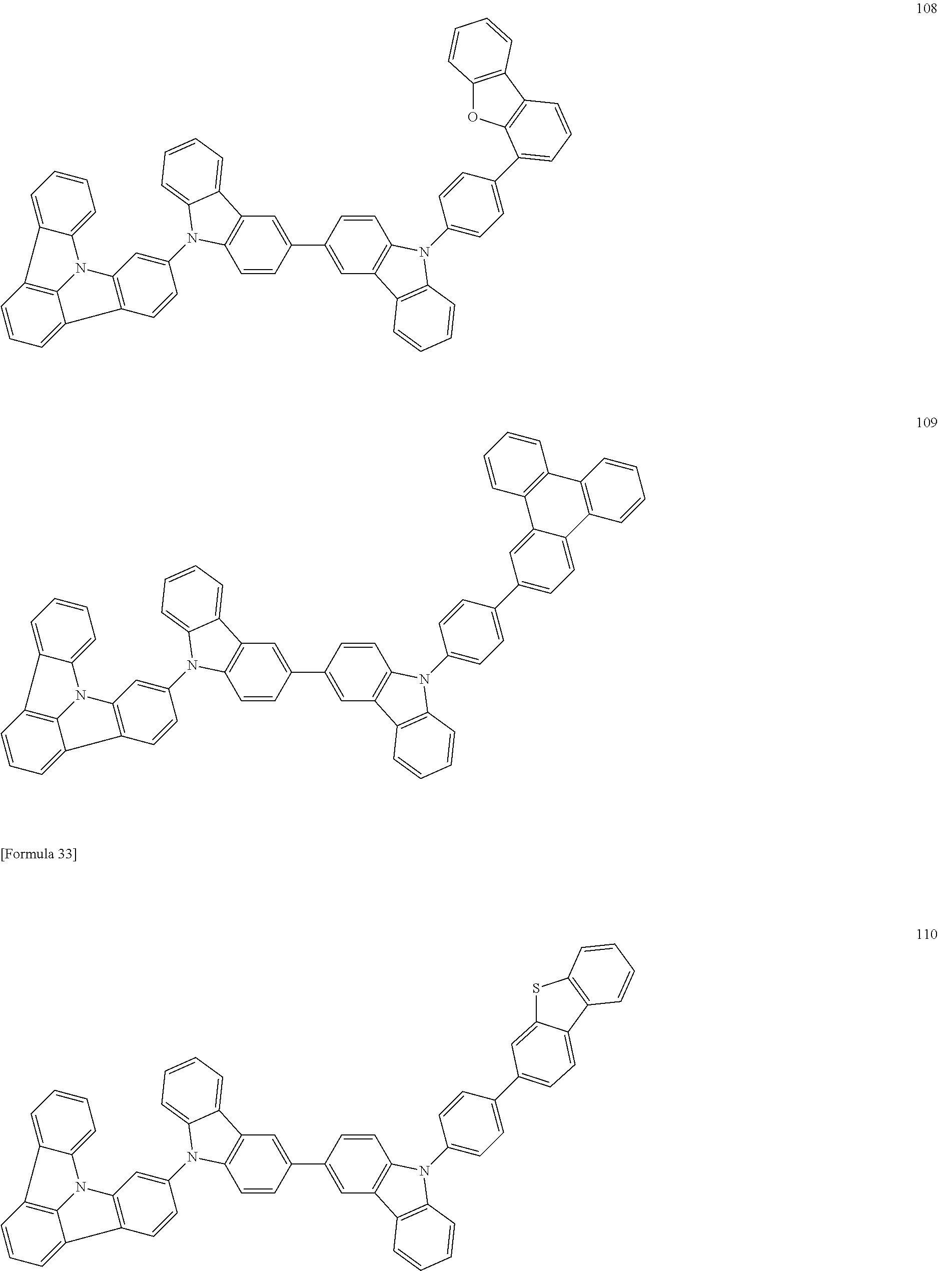 [SMILES: c1ccc2c(c1)oc1c(-c3ccc(-n4c5ccccc5c5cc(-c6ccc7c(c6)c6ccccc6n7-c6ccc7c8cccc9c%10ccccc%10n(c7c6)c98)ccc54)cc3)cccc12 ; c1ccc2c(c1)c1ccccc1c1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc21 ; c1ccc2c(c1)sc1cc(-c3ccc(-n4c5ccccc5c5cc(-c6ccc7c(c6)c6ccccc6n7-c6ccc7c8cccc9c%10ccccc%10n(c7c6)c98)ccc54)cc3)ccc12] 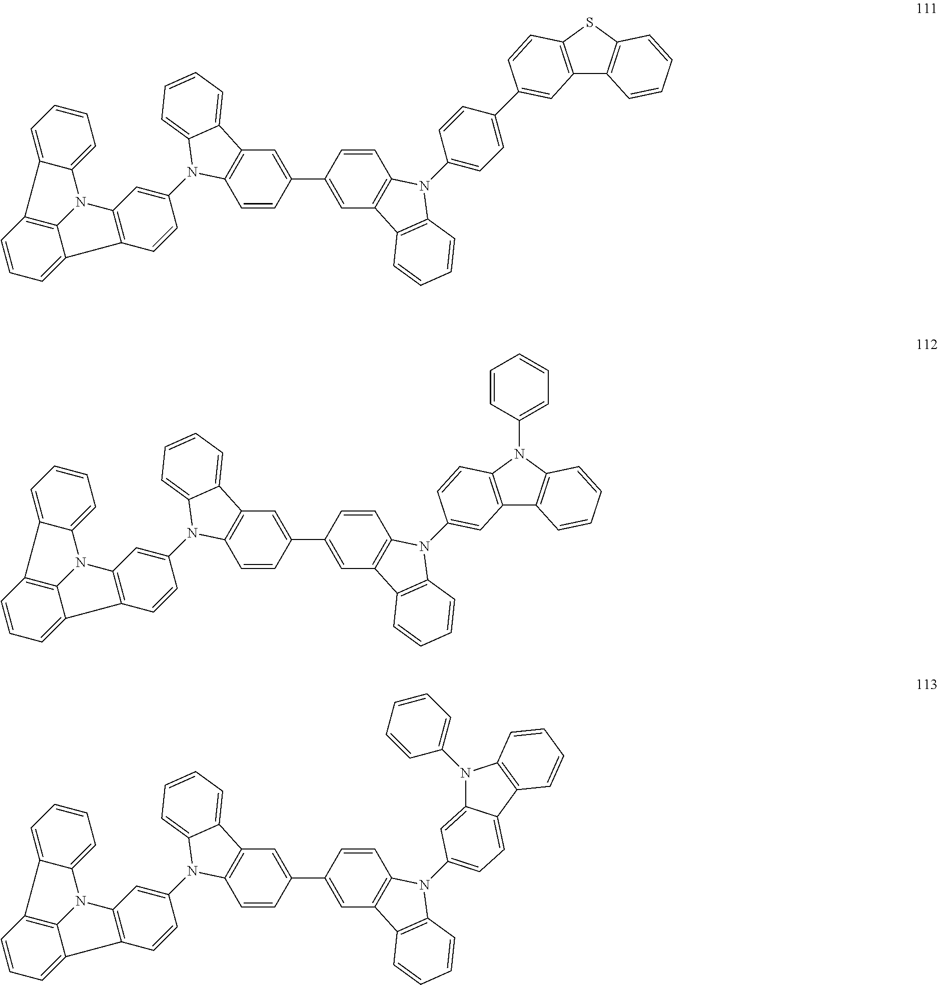 [SMILES: c1ccc2c(c1)sc1ccc(-c3ccc(-n4c5ccccc5c5cc(-c6ccc7c(c6)c6ccccc6n7-c6ccc7c8cccc9c%10ccccc%10n(c7c6)c98)ccc54)cc3)cc12 ; c1ccc(-n2c3ccccc3c3cc(-n4c5ccccc5c5cc(-c6ccc7c(c6)c6ccccc6n7-c6ccc7c8cccc9c%10ccccc%10n(c7c6)c98)ccc54)ccc32)cc1 ; c1ccc(-n2c3ccccc3c3ccc(-n4c5ccccc5c5cc(-c6ccc7c(c6)c6ccccc6n7-c6ccc7c8cccc9c%10ccccc%10n(c7c6)c98)ccc54)cc32)cc1] 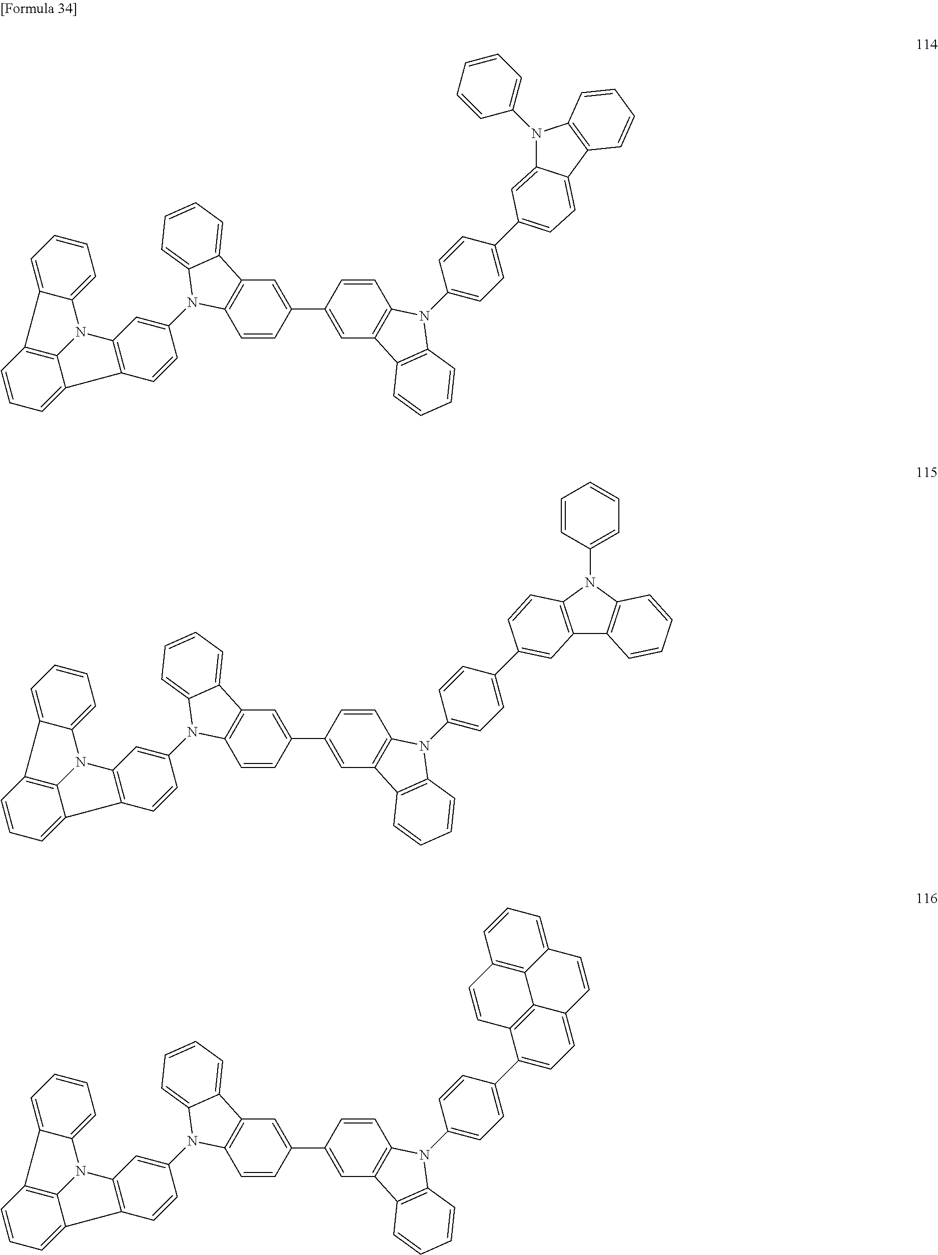 [SMILES: c1ccc(-n2c3ccccc3c3ccc(-c4ccc(-n5c6ccccc6c6cc(-c7ccc8c(c7)c7ccccc7n8-c7ccc8c9cccc%10c%11ccccc%11n(c8c7)c%109)ccc65)cc4)cc32)cc1 ; c1ccc(-n2c3ccccc3c3cc(-c4ccc(-n5c6ccccc6c6cc(-c7ccc8c(c7)c7ccccc7n8-c7ccc8c9cccc%10c%11ccccc%11n(c8c7)c%109)ccc65)cc4)ccc32)cc1 ; c1cc2ccc3ccc(-c4ccc(-n5c6ccccc6c6cc(-c7ccc8c(c7)c7ccccc7n8-c7ccc8c9cccc%10c%11ccccc%11n(c8c7)c%109)ccc65)cc4)c4ccc(c1)c2c34] 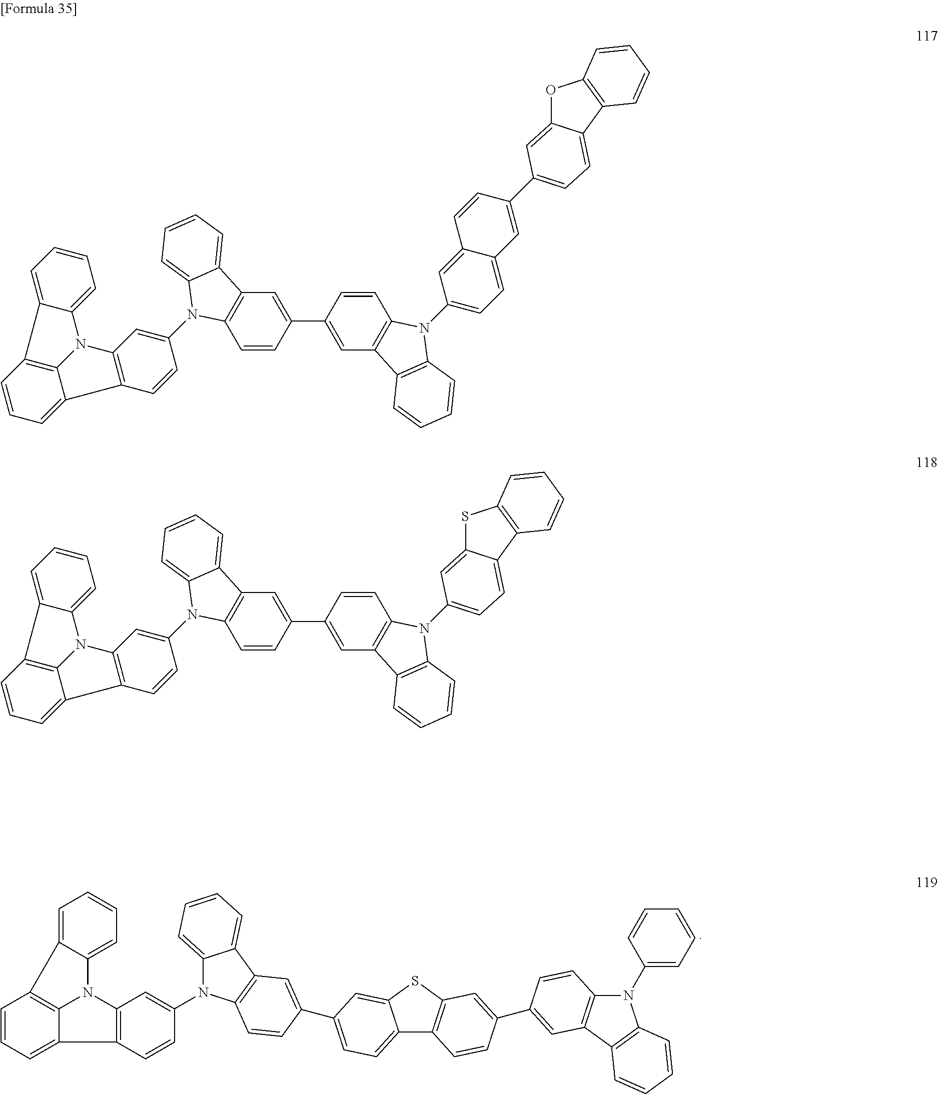 [SMILES: c1ccc2c(c1)oc1cc(-c3ccc4cc(-n5c6ccccc6c6cc(-c7ccc8c(c7)c7ccccc7n8-c7ccc8c9cccc%10c%11ccccc%11n(c8c7)c%109)ccc65)ccc4c3)ccc12 ; c1ccc2c(c1)sc1cc(-n3c4ccccc4c4cc(-c5ccc6c(c5)c5ccccc5n6-c5ccc6c7cccc8c9ccccc9n(c6c5)c87)ccc43)ccc12 ; c1ccc(-n2c3ccccc3c3cc(-c4ccc5c(c4)sc4cc(-c6ccc7c(c6)c6ccccc6n7-c6ccc7c8cccc9c%10ccccc%10n(c7c6)c98)ccc45)ccc32)cc1]
